(19) United States
(12) Patent Application Publication
(10) Pub. No.: US 2022/0407007 A1
(43) Pub. Date: Dec. 22, 2022

(54) LIGHT-EMITTING ELEMENT MATERIAL CONTAINING PYRROMETHENE BORON COMPLEX, LIGHT-EMITTING ELEMENT, DISPLAY DEVICE, AND ILLUMINATION DEVICE

(71) Applicant: Toray Industries, Inc., Tokyo (JP)

(72) Inventors: Kazunari Kawamoto, Otsu-shi, Shiga (JP); Takashi Tokuda, Otsu-shi, Shiga (JP); Kazumasa Nagao, Otsu-shi, Shiga (JP)

(73) Assignee: Toray Industries, Inc., Tokyo (JP)

(21) Appl. No.: 17/761,787

(22) PCT Filed: Oct. 28, 2020
(86) PCT No.: PCT/JP2020/040396

§ 371 Date: Mar. 18, 2022

(30) Foreign Application Priority Data
Oct. 28, 2019 (JP) 2019-194970

(51) Int. Cl. H01L 51/00; C09K 11/06; C09K 11/02; C07F 5/02

(52) U.S. Cl. CPC H01L 51/008; C09K 11/06; C09K 11/02; C07F 5/022; H01L 51/0072; C09K 2211/1018; C09K 2211/1007; C09K 2211/1011; H01L 2251/5315; H01L 51/5044

(57) ABSTRACT

The present invention provides a pyrromethene boron complex represented by the general formula (1), a light emitting element material having high luminance efficiency, and a light emitting element:

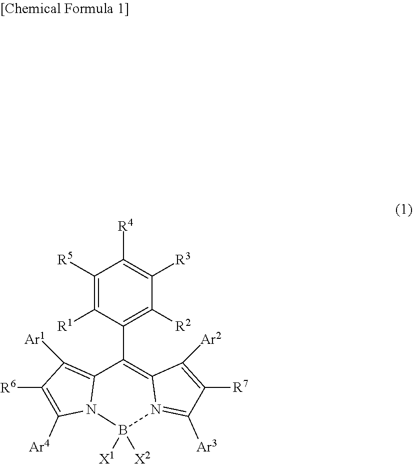

wherein X¹ and X² each may be the same or different, and are selected from the group consisting of an alkyl group, a cycloalkyl group, a heterocyclic group, an alkenyl group, a cycloalkenyl group, an alkynyl group, a hydroxyl group, a thiol group, an alkoxy group, a cycloalkoxy group, an alkylthio group, an aryl ether group, an aryl thioether group, an aryl group, a heteroaryl group, halogen and a cyano group. These functional groups may further have a substituent. Ar¹ to Ar⁴ each may be the same or different, and are a substituted or unsubstituted aryl group, or a substituted or unsubstituted heteroaryl group. The aryl group and the heteroaryl group may be either a monocyclic ring or a fused ring. However, when one or both of Ar¹ and Ar² is/are monocyclic ring(s), the monocyclic ring has one or more secondary alkyl groups, one or more tertiary alkyl groups, one or more aryl groups, or one or more heteroaryl groups as substituents, or has a methyl group and a primary alkyl group as two or more substituents in total. R¹ and R² each may be the same or different, and are a substituted or unsubstituted alkyl group, a substituted or unsubstituted aryl group, or a substituted or unsubstituted heteroaryl group. R³ to R⁵ each may be the same or different, and are selected from the group consisting of a hydrogen atom, an alkyl group, a cycloalkyl group, a heterocyclic group, an alkenyl group, a cycloalkenyl group, an alkynyl group, an aryl group, a heteroaryl group, a hydroxyl group, a thiol group, an alkoxy group, an alkylthio group, an aryl ether group, an aryl thioether group, halogen, a cyano group, an aldehyde group, an acyl group, a carboxyl group, an ester group, an amide group, a sulfonyl group, a sulfonic acid ester group, a sulfonamide group, an amino group, a nitro group, a silyl group, and a ring structure with an adjacent group. These functional groups may further have a substituent. R⁶ and R⁷ each may be the same or different, and are selected from the group consisting of a hydrogen atom, an alkyl group, a cycloalkyl group, a heterocyclic group, an alkenyl group, a cycloalkenyl group, an alkynyl group, an aryl group, a heteroaryl group, a hydroxyl group, a thiol group, an alkoxy group, an alkylthio group, an aryl ether group, an aryl thioether group, halogen, a cyano group, an aldehyde group, an acyl group, a carboxyl group, an ester group, an amide group, a sulfonyl group, a sulfonic acid ester group, a sulfonamide group, an amino group, a nitro group and a silyl group. However, R⁶ may be a bridging structure formed by covalent bond via one or two atoms with Ar⁴, and R⁷ may be a bridging structure formed by covalent bond via one or two atoms with Ar³. These functional groups may further have a substituent.

### CROSS REFERENCE TO RELATED APPLICATIONS

This is the U.S. National Phase application of PCT/JP2020/040396, filed Oct. 28, 2020, which claims priority to Japanese Patent Application No. 2019-194970, filed Oct. 28, 2019, the disclosures of each of these applications being incorporated herein by reference in their entireties for all purposes.

### FIELD OF THE INVENTION

The present invention relates to a light emitting element material containing a pyrromethene boron complex, a light emitting element, a display device, and an illumination device.

### BACKGROUND OF THE INVENTION

The organic thin-film light emitting element, which emits light by recombination of electrons injected from a cathode and holes injected from an anode in a light emitting layer sandwiched between the two electrodes, has a feature that it is thin and can emit light of high luminance emission at a low driving voltage, and is also capable of emitting multicolor light by selecting a light emitting material.

Of these, a red light emitting material has been developed as a material necessary for red emission which is one of the three primary colors of light. There have been known, as a conventional red light emitting material, perylene-based materials such as bis(diisopropylphenyl)perylene, perinone-based materials, tetracene-based materials, porphyrin-based materials, Eu complexes (Chem. Lett., 1267(1991)) and the like.

There has also been studied, as a method for obtaining red emission, a method in which a small amount of a red fluorescent material is mixed as a dopant in a host material. In particular, examples of the dopant material include those containing a pyrromethene metal complex exhibiting high luminance emission (see, for example, Patent Literature 1). In recent years, aiming for high luminance efficiency, there has also been made a study of a light emitting element containing a thermally activated delayed fluorescent (TADF) material and a pyrromethene compound (see, for example, Patent Literature 2).

### PATENT LITERATURE

### Patent Literature 1

JP 2003-12676 A

### Patent Literature 2

WO 2016/056559 A

### SUMMARY OF THE INVENTION

The organic thin-film light emitting element is desired to have high luminance efficiency from the viewpoint of improving the luminance and power saving. Particularly, power saving is a particularly important issue in mobile display devices whose use has been expanding in recent years, and higher luminance efficiency than that of a red-light emitting material used in the prior art is required.

It is known that, when a light emitting material is used as a dopant, the luminance efficiency decreases if the doping concentration is increased, in other words, concentration quenching occurs. However, a conventional material has a large decrease rate of the luminance efficiency with respect to an increase in doping concentration and exhibits large doping concentration dependence, thus causing a problem that it is difficult to control the doping concentration.

It is an object of the present invention to solve the problems of the prior art and to provide a red-light emitting element material having high luminance efficiency and low doping concentration dependence, and a light emitting element using the same.

The present invention is directed to a light emitting element material containing a pyrromethene boron complex represented by the general formula (1):

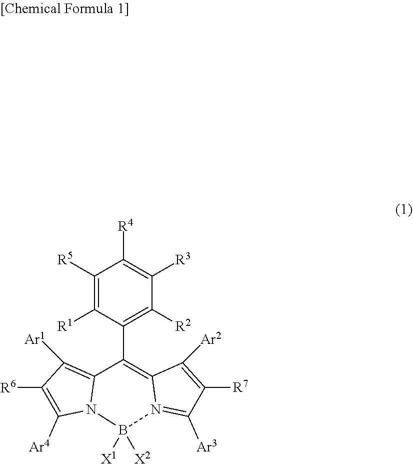

wherein X¹ and X² each may be the same or different, and are selected from the group consisting of an alkyl group, a cycloalkyl group, a heterocyclic group, an alkenyl group, a cycloalkenyl group, an alkynyl group, a hydroxyl group, a thiol group, an alkoxy group, a cycloalkoxy group, an alkylthio group, an aryl ether group, an aryl thioether group, an aryl group, a heteroaryl group, halogen and a cyano group. These functional groups may further have a substituent.

Ar¹ to Ar⁴ each may be the same or different, and are a substituted or unsubstituted aryl group, or a substituted or unsubstituted heteroaryl group. The aryl group and the heteroaryl group may be either a monocyclic ring or a fused ring. However, when one or both of Ar¹ and Ar² is/are monocyclic ring(s), the monocyclic ring has one or more secondary alkyl groups, one or more tertiary alkyl groups, one or more aryl groups, or one or more heteroaryl groups as substituents, or has a methyl group and a primary alkyl group as two or more substituents in total.

R¹ and R² each may be the same or different, and are a substituted or unsubstituted alkyl group, a substituted or unsubstituted aryl group, or a substituted or unsubstituted heteroaryl group.

R³ to R⁵ each may be the same or different, and are selected from the group consisting of a hydrogen atom, an alkyl group, a cycloalkyl group, a heterocyclic group, an alkenyl group, a cycloalkenyl group, an alkynyl group, an aryl group, a heteroaryl group, a hydroxyl group, a thiol group, an alkoxy group, an alkylthio group, an aryl ether group, an aryl thioether group, halogen, a cyano group, an aldehyde group, an acyl group, a carboxyl group, an ester group, an amide group, a sulfonyl group, a sulfonic acid ester group, a sulfonamide group, an amino group, a nitro group, a silyl group, and a ring structure with an adjacent group. These functional groups may further have a substituent.

R⁶ and R⁷ each may be the same or different, and are selected from the group consisting of a hydrogen atom, an alkyl group, a cycloalkyl group, a heterocyclic group, an alkenyl group, a cycloalkenyl group, an alkynyl group, an aryl group, a heteroaryl group, a hydroxyl group, a thiol group, an alkoxy group, an alkylthio group, an aryl ether group, an aryl thioether group, halogen, a cyano group, an aldehyde group, an acyl group, a carboxyl group, an ester group, an amide group, a sulfonyl group, a sulfonic acid ester group, a sulfonamide group, an amino group, a nitro group and a silyl group. However, R⁶ may be a bridging structure formed by covalent bond via one or two atoms with Ar⁴, and R⁷ may be a bridging structure formed by covalent bond of one or two atoms with Ar³. These functional groups may further have a substituent.

According to the present invention, it becomes possible to obtain a red-light emitting element having high luminance efficiency and low doping concentration dependence.

### DETAILED DESCRIPTION OF EMBODIMENTS OF THE INVENTION

Hereinafter, preferred embodiments of a pyrromethene boron complex, a light emitting element material containing the same, a light emitting element, a display device and a lighting device according to embodiments of the present invention will be described in detail. However, the present invention is not limited to the following embodiments, but can be implemented with various modifications according to purposes and applications.

### Pyrromethene Boron Complex

The pyrromethene boron complex according to embodiments of the present invention is represented by the general formula (1):

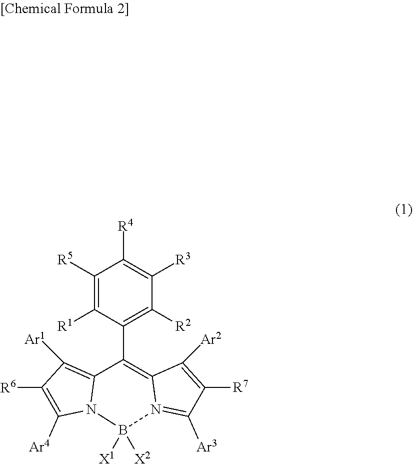

wherein X¹ and X² each may be the same or different, and are selected from the group consisting of an alkyl group, a cycloalkyl group, a heterocyclic group, an alkenyl group, a cycloalkenyl group, an alkynyl group, a hydroxyl group, a thiol group, an alkoxy group, a cycloalkoxy group, an alkylthio group, an aryl ether group, an aryl thioether group, an aryl group, a heteroaryl group, halogen and a cyano group. These functional groups may further have a substituent.

Ar¹ to Ar⁴ each may be the same or different, and are a substituted or unsubstituted aryl group, or a substituted or unsubstituted heteroaryl group. The aryl group and the heteroaryl group may be either a monocyclic ring or a fused ring. However, when one or both of Ar¹ and Ar² is/are monocyclic ring(s), the monocyclic ring has one or more secondary alkyl groups, one or more tertiary alkyl groups, one or more aryl groups, or one or more heteroaryl groups as substituents, or has a methyl group and a primary alkyl group as two or more substituents in total.

R¹ and R² each may be the same or different, and are a substituted or unsubstituted alkyl group, a substituted or unsubstituted aryl group, or a substituted or unsubstituted heteroaryl group.

R³ to R⁵ each may be the same or different, and are selected from the group consisting of a hydrogen atom, an alkyl group, a cycloalkyl group, a heterocyclic group, an alkenyl group, a cycloalkenyl group, an alkynyl group, an aryl group, a heteroaryl group, a hydroxyl group, a thiol group, an alkoxy group, an alkylthio group, an aryl ether group, an aryl thioether group, halogen, a cyano group, an aldehyde group, an acyl group, a carboxyl group, an ester group, an amide group, a sulfonyl group, a sulfonic acid ester group, a sulfonamide group, an amino group, a nitro group, a silyl group, and a ring structure with an adjacent group. These functional groups may further have a substituent.

R⁶ and R⁷ each may be the same or different, and are selected from the group consisting of a hydrogen atom, an alkyl group, a cycloalkyl group, a heterocyclic group, an alkenyl group, a cycloalkenyl group, an alkynyl group, an aryl group, a heteroaryl group, a hydroxyl group, a thiol group, an alkoxy group, an alkylthio group, an aryl ether group, an aryl thioether group, halogen, a cyano group, an aldehyde group, an acyl group, a carboxyl group, an ester group, an amide group, a sulfonyl group, a sulfonic acid ester group, a sulfonamide group, an amino group, a nitro group and a silyl group. However, R⁶ may be a bridging structure formed by covalent bond of one or two atoms with Ar⁴, and R⁷ may be a bridging structure formed by covalent bond via one or two atoms with Ar³. These functional groups may further have a substituent.

In embodiments of the present invention, those having a pyrromethene skeleton represented by the general formula (2), and those having a fused ring structure at a part of a pyrromethene skeleton, the ring structure being expanded, are collectively referred to as “pyrromethene”.

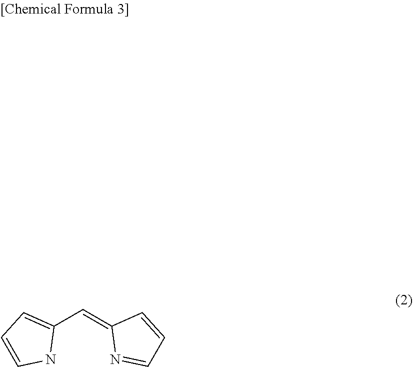

In all the groups of the present invention, hydrogen may be deuterium. The same applies to the compounds and partial structures thereof which will be described hereinafter.

In the description of the present invention, the term “unsubstituted” means that atoms bonded to the basic skeleton or functional group of interest are only hydrogen atoms or deuterium atoms.

The substituent in the case of “substitution” in the description of the present invention is preferably a group selected from an alkyl group, a cycloalkyl group, a heterocyclic group, an alkenyl group, a cycloalkenyl group, an alkynyl group, an aryl group, a heteroaryl group, a hydroxyl group, a thiol group, an alkoxy group, an alkylthio group, an aryl ether group, an aryl thioether group, halogen, a cyano group, an aldehyde group, an acyl group, a carboxyl group, an ester group, an amide group, a sulfonyl group, a sulfonic acid ester group, a sulfonamide group, an amino group, a nitro group, a silyl group and an oxo group. A specific substituent, which is preferable in the description of the following respective functional groups, is preferable. These substituents may be further substituted with the above-mentioned substituents.

In the description of the present invention, for example, a substituted or unsubstituted aryl group having 6 to 40 carbon atoms means that 6 to 40 carbon atoms also include the number of carbon atoms included in the substituent bonded to the aryl group. The same applies to other substituents with a defined number of carbon atoms.

The alkyl group means, for example, a saturated aliphatic hydrocarbon group such as a methyl group, an ethyl group, an n-propyl group, an isopropyl group, an n-butyl group, a sec-butyl group or a tert-butyl group, which may be substituted or unsubstituted. The additional substituent when substituted is not particularly limited, and examples thereof include an alkyl group, halogen, an aryl group, a heteroaryl group and the like, and this point is also common to the following description. The number of carbon atoms of the alkyl group is not particularly limited, but is preferably 1 or more and 20 or less, and more preferably 1 or more and 8 or less, from the viewpoint of the availability and cost.

The cycloalkyl group means, for example, a saturated alicyclic hydrocarbon group such as a cyclopropyl group, a cyclohexyl group, a norbornyl group or an adamantyl group, which may be substituted or unsubstituted. The number of carbon atoms of the cycloalkyl group is not particularly limited, but is preferably in the range of 3 or more and 20 or less.

The heterocyclic group means, for example, an aliphatic ring having an atom other than carbon, such as a pyran ring, a piperidine ring or a cyclic amide in the ring, which may be substituted or unsubstituted. The number of carbon atoms of the heterocyclic group is not particularly limited, but is preferably in the range of 2 or more and 20 or less.

The alkenyl group means, for example, an unsaturated aliphatic hydrocarbon group having a double bond, such as a vinyl group, an allyl group or a butadienyl group, which may be substituted or unsubstituted. The number of carbon atoms of the alkenyl group is not particularly limited, but is preferably in the range of 2 or more and 20 or less.

The cycloalkenyl group means, for example, an unsaturated alicyclic hydrocarbon group having a double bond, such as a cyclopentenyl group, a cyclopentadienyl group or a cyclohexenyl group, which may be substituted or unsubstituted. The number of carbon atoms of the cycloalkenyl group is not particularly limited, but is preferably in the range of 3 or more and 20 or less.

The alkynyl group means, for example, an unsaturated aliphatic hydrocarbon group having a triple bond, such as an ethynyl group, which may be substituted or unsubstituted. The number of carbon atoms of the alkynyl group is not particularly limited, but is preferably in the range of 2 or more and 20 or less.

The aryl group may be either a monocyclic ring or a fused ring, and means, for example, an aromatic hydrocarbon group such as a phenyl group, a naphthyl group, a fluorenyl group, a benzofluorenyl group, a dibenzofluorenyl group, a phenanthryl group, an anthracenyl group, a benzophenanthryl group, a benzoanthracenyl group, a chrysenyl group, a pyrenyl group, a fluoranthenyl group, a triphenylenyl group, a benzofluoranthenyl group, a dibenzoanthracenyl group, a peryleneyl group or a helicenyl group. Of these, a phenyl group, a naphthyl group, a fluorenyl group, a phenanthryl group, an anthracenyl group, a pyrenyl group, a fluoranthenyl group and a triphenylenyl group are preferable. The aryl group may be substituted or unsubstituted. Here, in embodiments of the present invention, a functional group in which a plurality of phenyl groups such as a biphenyl group and a terphenyl group are bonded via a single bond is treated as a phenyl group having an aryl group as a substituent. The number of carbon atoms of the aryl group is not particularly limited, but is preferably in the range of 6 or more and 40 or less, and more preferably 6 or more and 30 or less. In the case of a phenyl group, when there is a substituent on each of two adjacent carbon atoms in the phenyl group, the substituents may form a ring structure with each other. The resulting group can correspond to any one of “substituted phenyl group”, “aryl group having a structure in which two or more rings are fused” and “heteroaryl group having a structure in which two or more rings are fused” depending on the structure.

The heteroaryl group may be either a monocyclic ring or a fused ring, and means, for example, a cyclic aromatic group having an atom other than carbon and hydrogen, that is, a hetero atom in one or plural rings, such as a pyridyl group, a furanyl group, a thienyl group, a quinolinyl group, an isoquinolinyl group, a pyrazinyl group, a pyrimidyl group, a pyridadinyl group, a triazinyl group, a naphthyldinyl group, a cinnolinyl group, a phtalazinyl group, a quinoxalinyl group, a quinazolinyl group, a benzofuranyl group, a benzothienyl group, an indolyl group, a dibenzofuranyl group, a dibenzothienyl group, a carbazolyl group, a benzocarbazolyl group, a carbolinyl group, an indolocarbazolyl group, a benzofurocarbazolyl group, a benzothienocarbazolyl group, a dihydroindenocarbazolyl group, a benzoquinolinyl group, an acridinyl group, a dibenzoacrydinyl group, a benzoimidazolyl group, an imidazopyridyl group, a benzoxazolyl group, a benzothiazolyl group or a phenanthrolinyl group. The heteroatom is preferably a nitrogen atom, an oxygen atom or a sulfur atom. The heteroaryl group may be substituted or unsubstituted. The number of carbon atoms of the heteroaryl group is not particularly limited, but is preferably in the range of 2 or more and 40 or less, and more preferably 2 or more and 30 or less.

The alkoxy group means, for example, a functional group in which an aliphatic hydrocarbon group is bonded via an ether bond, such as a methoxy group, an ethoxy group or a propoxy group. The alkoxy group may be substituted or unsubstituted. The number of carbon atoms of the alkoxy group is not particularly limited, but is preferably in the range of 1 or more and 20 or less.

The alkylthio group is a group in which the oxygen atom of the ether bond of the alkoxy group is substituted with a sulfur atom. The alkylthio group may be substituted or unsubstituted. The number of carbon atoms of the alkylthio group is not particularly limited, but is preferably in the range of 1 or more and 20 or less.

The aryl ether group means, for example, a functional group in which an aromatic hydrocarbon group is bonded via an ether bond, such as a phenoxy group, which may be substituted or unsubstituted. The number of carbon atoms of the aryl ether group is not particularly limited, but is preferably in the range of 6 or more and 40 or less.

The aryl thioether group is a group in which the oxygen atom of the ether bond of the aryl ether group is substituted with a sulfur atom. This aryl thioether group may be further substituted. The number of carbon atoms of the aryl thioether group is not particularly limited, but is preferably in the range of 6 or more and 40 or less.

The halogen means an atom selected from fluorine, chlorine, bromine and iodine.

The cyano group is a functional group whose structure is represented by —C≡N. Here, it is the carbon atom which is bonded to other functional groups.

The aldehyde group is a functional group whose structure is represented by —C(═O)H. Here, it is the carbon atom which is bonded to other functional groups.

The acyl group means, for example, a functional group in which an alkyl group, a cycloalkyl group, an alkenyl group, an alkynyl group, an aryl group or a heteroaryl group is bonded via a carbonyl bond, for example, an acetyl group, a propionyl group, a benzoyl group, an acryloyl group or the like, which may be further substituted. The number of carbon atoms of the acyl group is not particularly limited, but is preferably in the range of 2 or more and 40 or less, and more preferably 2 or more and 30 or less.

The ester group means, for example, a functional group in which an alkyl group, a cycloalkyl group, an aryl group, a heteroaryl group or the like is bonded via an ester bond, which may be further substituted. The number of carbon atoms of the ester group is not particularly limited, but is preferably in the range of 1 or more and 20 or less. More specifically, examples thereof include methyl ester groups such as a methoxycarbonyl group, ethyl ester groups such as an ethoxycarbonyl group, propyl ester groups such as a propoxycarbonyl group, butyl ester groups such as a butoxycarbonyl group, isopropyl ester groups such as an isopropoxymethoxycarbonyl group, hexyl ester groups such as a hexyloxycarbonyl group, and phenyl ester groups such as a phenoxycarbonyl group.

The amide group means, for example, a functional group in which an alkyl group, a cycloalkyl group, an aryl group, a heteroaryl group or the like is bonded via an amide bond, which may be further substituted. The number of carbon atoms of the amide group is not particularly limited, but is preferably in the range of 1 or more and 20 or less. More specifically, examples thereof include a methylamide group, an ethylamide group, a propylamide group, a butyramide group, an isopropylamide group, a hexylamide group, a phenylamide group and the like.

The sulfonyl group means, for example, a functional group in which an alkyl group, a cycloalkyl group, an aryl group, a heteroaryl group or the like is bound via a —S(═O)₂— bond, which may be further substituted. The number of carbon atoms of the sulfonyl group is not particularly limited, but is preferably in the range of 1 or more and 20 or less. The sulfonic acid ester group means, for example, a functional group in which an alkyl group, a cycloalkyl group, an aryl group, a heteroaryl group or the like is bonded via a sulfonic acid ester bond. Here, the sulfonic acid ester bond means a carbonyl moiety of the ester bond, that is, —C(═O)— replaced with a sulfonyl moiety, that is, those in which —C(═O)— is substituted with a sulfonyl moiety, that is, —S(═O)₂—. The sulfonic acid ester group may be further substituted. The number of carbon atoms of the sulfonic acid ester group is not particularly limited, but is preferably in the range of 1 or more and 20 or less.

The sulfonamide group means, for example, a functional group in which an alkyl group, a cycloalkyl group, an aryl group, a heteroaryl group or the like is bonded via a sulfonamide bond. Here, the sulfonamide bond means a carbonyl moiety of the amide bond, that is, those in which —C(═O)— is substituted with a sulfonyl moiety, that is, —S(═O)₂—. The sulfonamide group may be further substituted. The number of carbon atoms of the sulfonamide group is not particularly limited, but is preferably in the range of 1 or more and 20 or less.

The amino group is a substituted or unsubstituted amino group. Examples of the substituent in the case of substitution include an aryl group, a heteroaryl group, a linear alkyl group and a branched alkyl group. Here, as the aryl group or the heteroaryl group, a phenyl group, a naphthyl group, a pyridyl group or a quinolinyl group is preferable. These substituents may be further substituted. The number of carbon atoms is not particularly limited, but is preferably in the range of 2 or more and 50 or less, more preferably 6 or more and 40 or less, and particularly preferably 6 or more and 30 or less.

The silyl group means a functional group in which a substituted or unsubstituted silicon atom is bonded, and examples thereof include alkylsilyl groups such as a trimethylsilyl group, a triethylsilyl group, a tert-butyldimethylsilyl group, a propyldimethylsilyl group and a vinyldimethylsilyl group, and arylsilyl groups such as a phenyldimethylsilyl group, a tert-butyldiphenylsilyl group, a triphenylsilyl group and trinaphthylsilyl group. These groups may be further substituted. The number of carbon atoms of the silyl group is not particularly limited, but is preferably in the range of 1 or more and 30 or less.

The oxo group is a functional group in which an oxygen atom is bonded to a carbon atom via a double bond, that is, a structure of ═O is formed.

The pyrromethene boron complex represented by the general formula (1) has a strong and highly planar skeleton, thus exhibiting a high fluorescence quantum yield. Because of small half width of the emission spectrum, efficient emission and high color purity can be achieved.

X¹ and X² represent a ligand other than pyrromethene for boron. X¹ and X² are selected from the above, but are preferably an alkyl group, an alkoxy group, an aryl ether group, halogen or a cyano group from the viewpoint of the emission characteristics and thermal stability. From the viewpoint that the excited state is stable and higher fluorescence quantum yield can be obtained, and that the durability can be improved, X¹ and X² are more preferably an electron withdrawing group, and specifically, they are more preferably a fluorine atom, a fluorine-containing alkyl group, a fluorine-containing alkoxy group, a fluorine-containing aryl ether group or a cyano group, still more preferably a fluorine atom or a cyano group, and most preferably a fluorine atom. When X¹ and X² are an electron withdrawing group, the electron density of the pyrromethene skeleton can be lowered to increase the stability of the compound. X¹ and X² may be the same or different from each other, but are preferably the same from the viewpoint of ease of synthesis.

Ar¹ and Ar² are groups contributing to the stability and luminance efficiency of the pyrromethene boron complex compound. Stability means electrical stability and thermal stability. Electrical stability means that deterioration of the compound such as decomposition is unlikely to occur when the light emitting element is continuously energized. Thermal stability means that deterioration of the compound is unlikely to occur due to heating processes such as sublimation purification and vapor deposition during production, and the environmental temperature around the light emitting element. Since the luminance efficiency decreases when the compound deteriorates, the stability of the compound is important for improving the durability of the light emitting element. Ar¹ and Ar² are preferably a substituted or unsubstituted aryl group from the viewpoint of the stability and luminance efficiency of the compound.

Ar¹ and Ar² may be either a monocyclic ring or a fused ring. However, one or both of Ar¹ and Ar² is/are monocyclic ring(s), the monocyclic ring has one or more secondary alkyl groups, one or more tertiary alkyl groups, one or more aryl groups, or one or more heteroaryl groups as substituents, or has a methyl group and a primary alkyl group as two or more substituents in total. Ar¹ and Ar² having these substituents can suppress rotation and vibration of the substituent at the meso-position mentioned later and improve the fluorescence quantum yield.

Ar¹ and Ar² are preferably a group having a large steric hindrance of the above group in order to prevent aggregation of the pyrromethene boron complexes and avoid concentration quenching. From this point of view, Ar¹ and Ar² are preferably selected from the group consisting of a phenyl group having one or more tertiary alkyl groups as substituents, a phenyl group having one or more aryl groups as substituents, a phenyl group having one or more heteroaryl groups as substituents, a phenyl group having a methyl group and a primary alkyl group as two or more substituents in total, at least one of which is substituted at the 2-position with respect to a bonding site to a pyrrole ring, and a fused-ring aromatic hydrocarbon group.

Since the smaller the degree of freedom of rotation or vibration is, the more a reduction in efficiency due to heat deactivation can be suppressed, Ar¹ and Ar² are preferably a functional group having a rigid structure or a highly symmetric structure. From this point of view, Ar¹ and Ar² are more preferably a phenyl group having one or more tert-butyl groups as substituents, a phenyl group having one or more phenyl groups as substituents, a phenyl group which is any of phenyl groups in which a methyl group is substituted at the 2- and 6-positions with respect to the bonding site with at least the pyrrole ring, and which has a substituent in linear symmetry with the bond to the pyrrole as the axis of symmetry, or an unsubstituted fused-ring aromatic hydrocarbon group. From the viewpoint of ease of production, they are still more preferably a 2,6-dimethylphenyl group, a mesityl group, a 4-tert-butylphenyl group, a 3,5-di-tert-butylphenyl group, a 4-biphenyl group or a 1-naphthyl group.

Ar³ and Ar⁴ are groups contributing to the control of the emission wavelength. To make the pyrromethene boron complex emit red light, examples of the method include a method in which an aryl group or a heteroaryl group is directly bonded to the pyrromethene metal complex skeleton to extend the conjugation and achieve emission of longer-wavelength light. For this reason, Ar³ and Ar⁴ are a substituted or unsubstituted alkyl group, a substituted or unsubstituted aryl group, or a substituted or unsubstituted heteroaryl group, and more preferably a substituted or unsubstituted aryl group, from the viewpoint of the stability of the compound.

To improve the luminance efficiency, it is effective that the rotation and vibration of the substituent existing at the meso-position of the pyrromethene boron complex, that is, the substituent bonded to carbon between the two pyrrole rings are suppressed to reduce the energy loss, leading to an improvement in fluorescence quantum yield. In order to suppress the rotation and vibration of the substituent existing at the meso-position, R¹ and R² of the substituent existing at the meso-position are selected from a substituted or unsubstituted alkyl group, a substituted or unsubstituted aryl group, or a substituted or unsubstituted heteroaryl group. Of these, at least one is preferably a substituted or unsubstituted aryl group, or a substituted or unsubstituted heteroaryl group. Meanwhile, from the viewpoint of ease of production, one of R¹ and R² is preferably a substituted or unsubstituted alkyl group, and more preferably a methyl group.

R³ to R⁵ are selected from the above-mentioned group of functional groups and used to adjust the peak wavelength, crystallinity, sublimation temperature and the like. It is the substituent at the 4-position with respect to the bond to the pyrromethene skeleton, that is, R⁴ which particularly affects the peak wavelength. If R⁴ is an electron donating group, the emission peak wavelength shifts to the short wavelength side. Specific examples of the electron donating group include a methyl group, an ethyl group, a tert-butyl group, a cyclohexyl group, a methoxy group, an ethoxy group, a phenyl group, a tolyl group, a naphthyl group, a furanyl group, a dibenzofuranyl group and the like. In particular, when R⁴ is an alkoxy group having strong electron donating properties, such as a methoxy group or an ethoxy group, it is useful to adjust the wavelength because of large short wavelength shift. Meanwhile, if R⁴ is an electron withdrawing group, the emission peak shifts to the long wavelength side. Specific examples of the electron withdrawing group include a fluorine atom, a trifluoromethyl group, a cyano group, a pyridyl group, a pyrimidyl group and the like. In particular, when R⁴ is a group selected from a fluorine atom, a trifluoromethyl group and a cyano group each having strong electron withdrawing properties, it is useful to adjust the wavelength because of large short wavelength shift. However, the electron donating group and the electron withdrawing group are not limited thereto.

R⁶ and R⁷ are selected from the above-mentioned group of functional groups and mainly affect the peak wavelength, half width of emission spectrum, stability or crystallinity.

The case where “R⁶ is a bridging structure formed by covalent bond via one or two atoms with Ar⁴” means that the group represented by R⁶ is bonded to Ar⁴ to form a bridging structure between Ar⁴ and the pyrrole ring in the pyrromethene skeleton. The bonding site to R⁶ in Ar⁴ is any site excluding the site bonded directly to the pyrrole ring in the pyrromethene skeleton, and the shortest bonding site from the bonding site with R⁶ in Ar⁴ to the pyrrole ring via R⁶ is composed of one or two atoms, and each bond in the shortest bonding site is a covalent bond. The atoms constituting the bridging structure are not particularly limited as long as they can form two or more covalent bonds. ″R⁷ is a bridging structure formed by covalent bond via one or two atoms with Ar³″ is described in the same way.

From the viewpoint of narrowing the half width of the emission spectrum, stability affecting device durability, and ease of production including recrystallization purification, at least one of R⁶ and R⁷, more preferably both of them, is preferably a hydrogen atom, or an unsubstituted alkyl group. For the same reason, the pyrromethene boron complex represented by the general formula (1) is preferably a pyrromethene boron complex represented by any one of the general formulas (3) to (5).

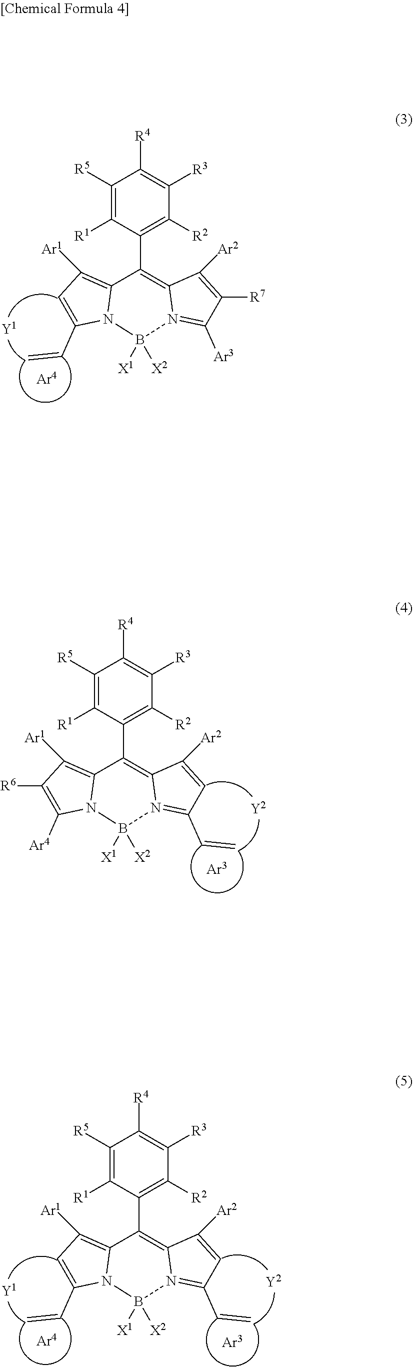

X¹ and X², Ar¹ to Ar⁴ and R¹ to R⁷ are as mentioned above. Y¹ and Y² are a bridging structure composed of one atom or two atoms arranged in series, and the atom is selected from the group consisting of a substituted or unsubstituted carbon atom, a substituted or unsubstituted silicon atom, a substituted or unsubstituted nitrogen atom, a substituted or unsubstituted phosphorus atom, an oxygen atom and a sulfur atom. When the bridging structure is composed of two atoms arranged in series, two atoms may be connected by a double bond. Here, the bridging structure composed of one atom or two atoms arranged in series means that the number of atoms forming the main chain of the bridging portion is one or two. Examples of such bridging structure include, but are not limited to, the structures represented by the general formulas (6) to (14).

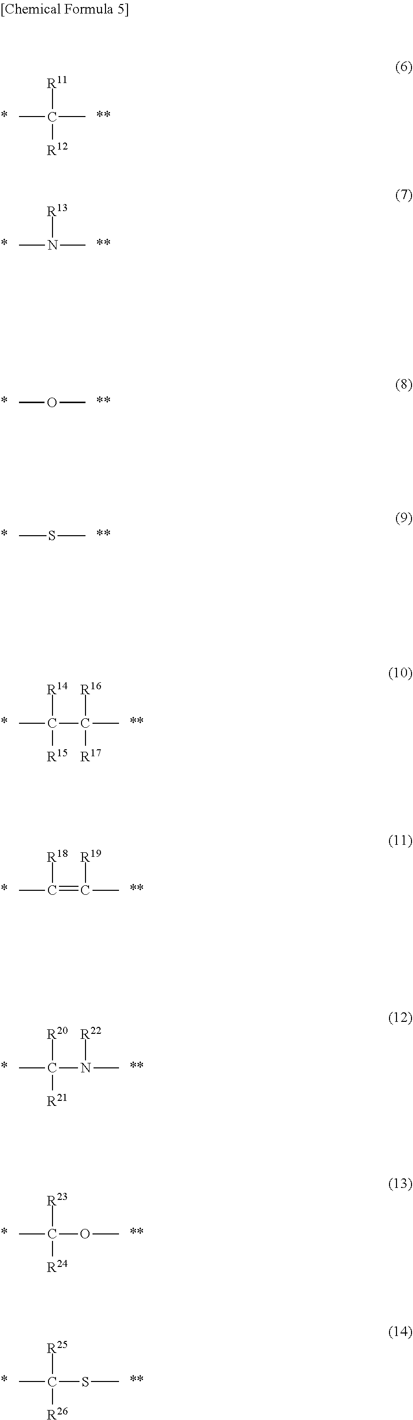

* represents a connection with the pyrrole ring, and ** represents a connection with Ar³ or Ar⁴. R¹¹ to R²⁶ are selected from the same group of functional groups as in R³ to R⁵. From the viewpoint of the stability of the compound and ease of production, R¹¹ to R²⁶ are preferably anyone selected from a hydrogen atom, an alkyl group, a cycloalkyl group and an aryl group, more preferably a hydrogen atom or an alkyl group, and still more preferably a hydrogen atom.

From the viewpoint of ease of synthesis and purification, the pyrromethene boron complex of the present invention preferably satisfies Ar¹=Ar², Ar³=Ar⁴ and R⁶=R⁷, simultaneously. When this relationship is satisfied, one type of a pyrrole derivative as a raw material is required, and the introduction into the meso-position can be performed in one step, which is synthetically superior. Since the molecular symmetry is improved, the crystallinity is improved and purification by recrystallization becomes easier.

The molecular weight of the pyrromethene boron complex represented by the general formula (1) is not particularly limited, but is preferably in the range which facilitates the vapor deposition step. Specifically, from the viewpoint of obtaining a stable vapor deposition rate, the molecular weight of the pyrromethene boron complex of the general formula (1) is preferably 500 or more, more preferably 600 or more, and still more preferably 700 or more. From the viewpoint of preventing the vapor deposition temperature from becoming too high leading to decomposition, the molecular weight is preferably 1,200 or less, and more preferably 1,000 or less.

An example of the pyrromethene boron complex represented by the general formula (1) is shown below, but the present invention is not limited thereto.

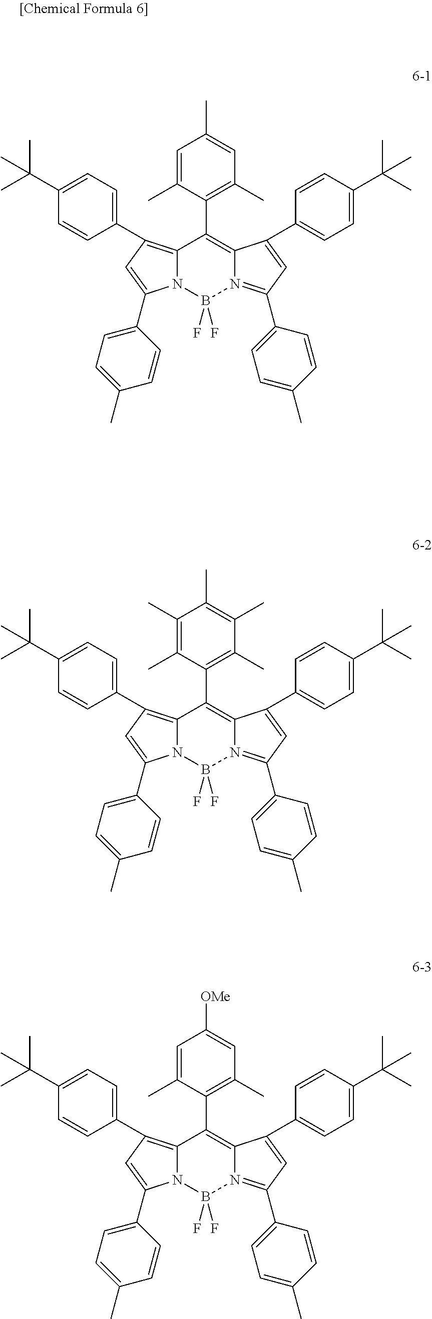

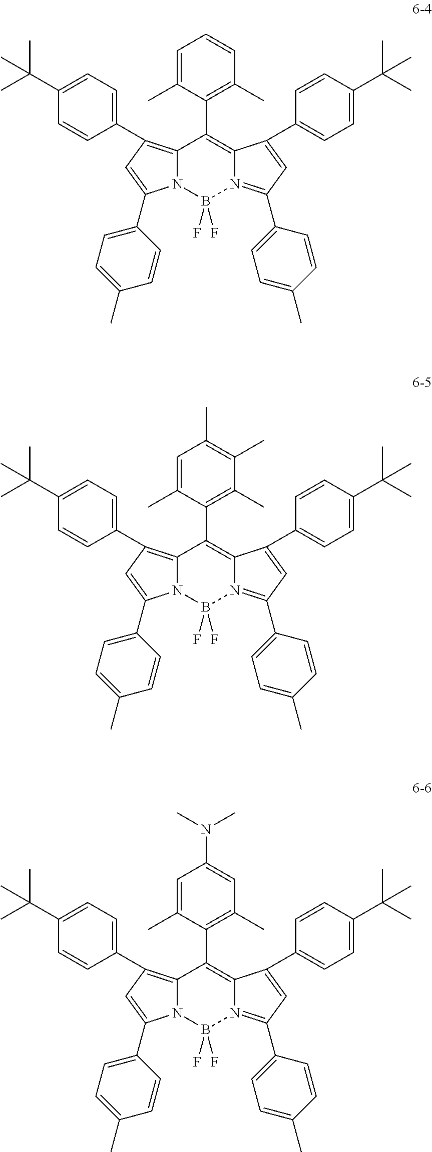

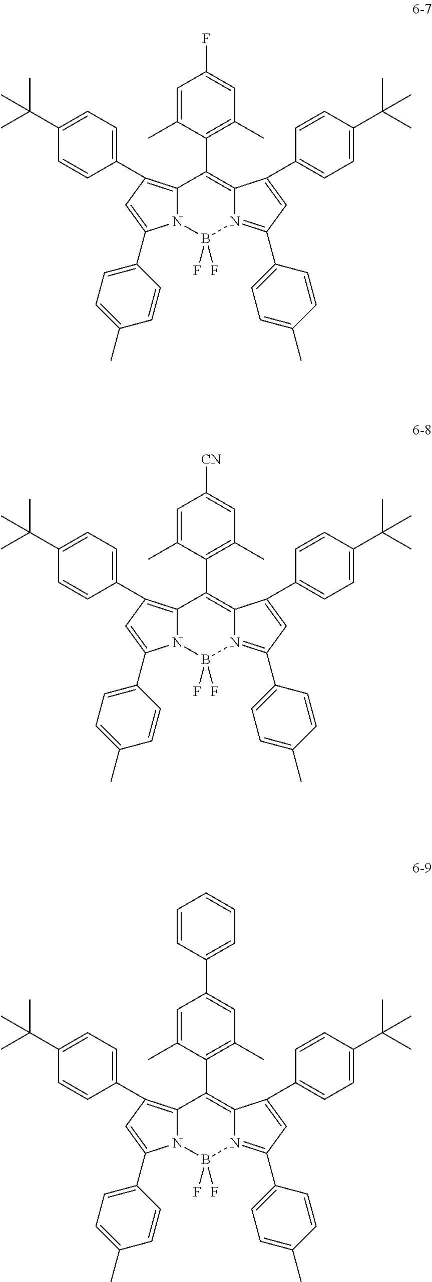

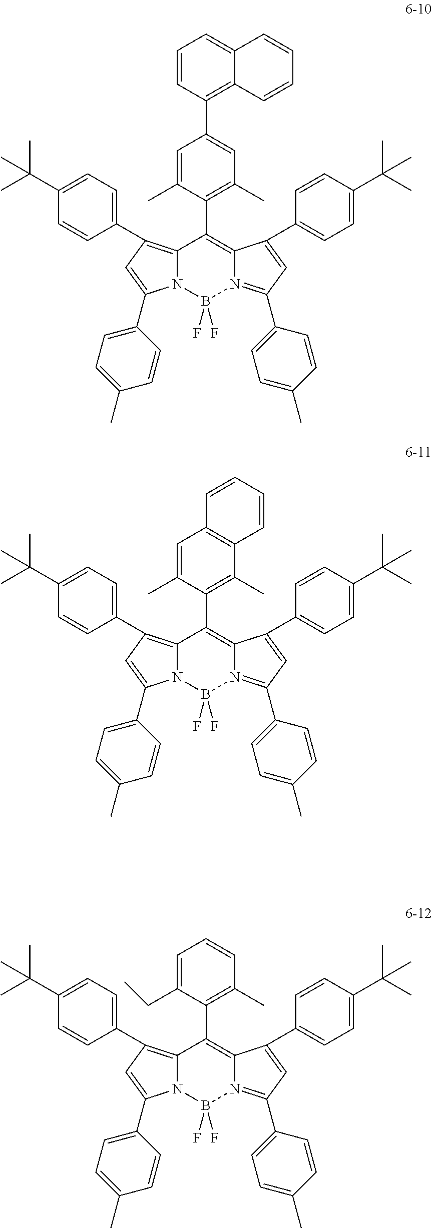

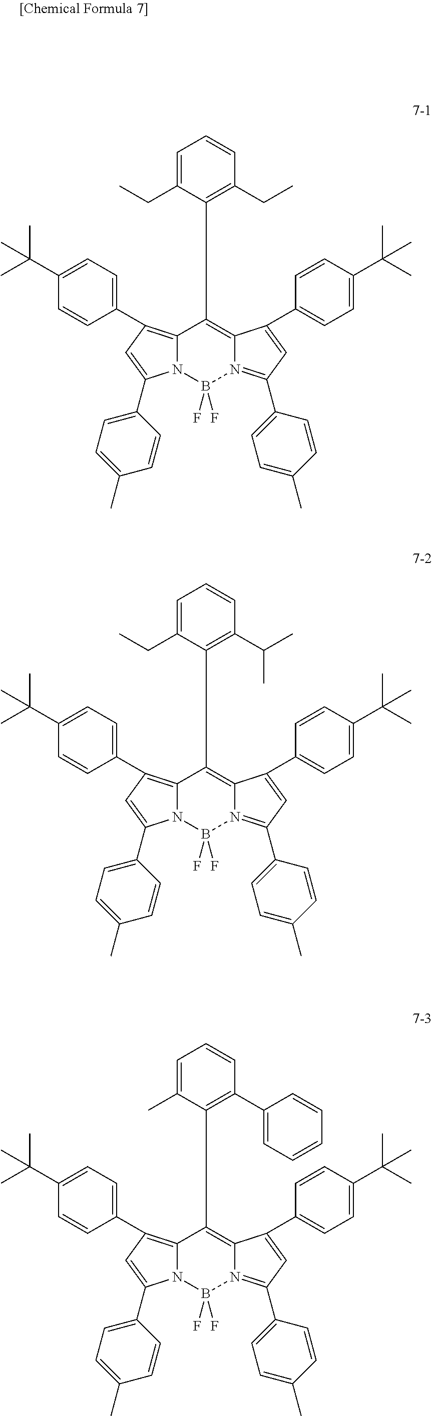

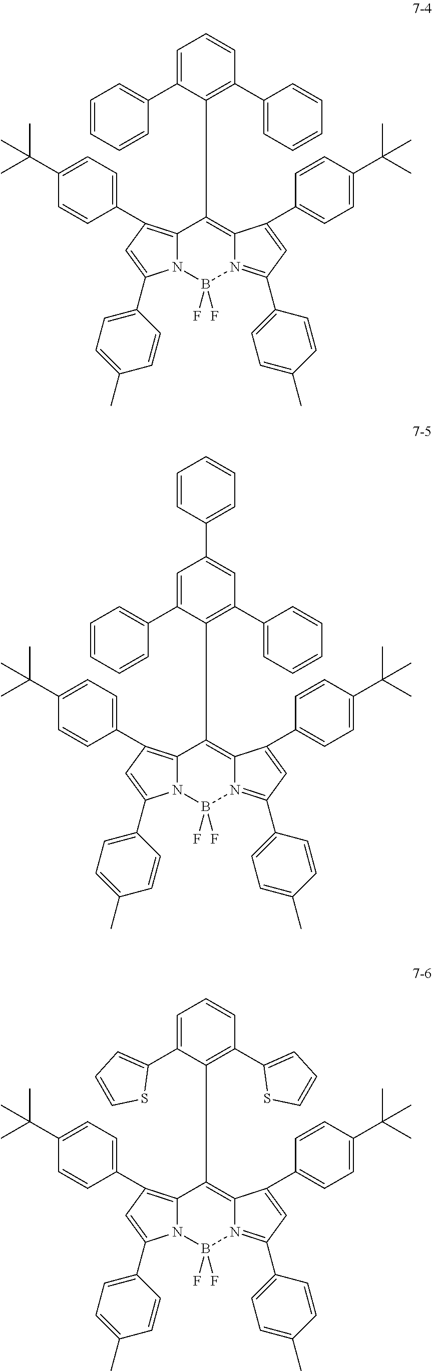

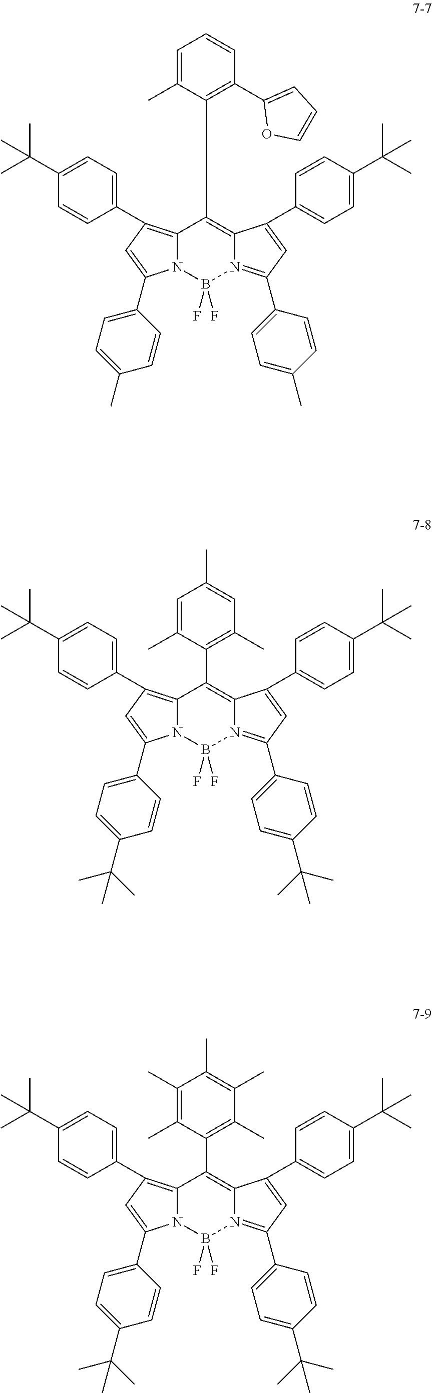

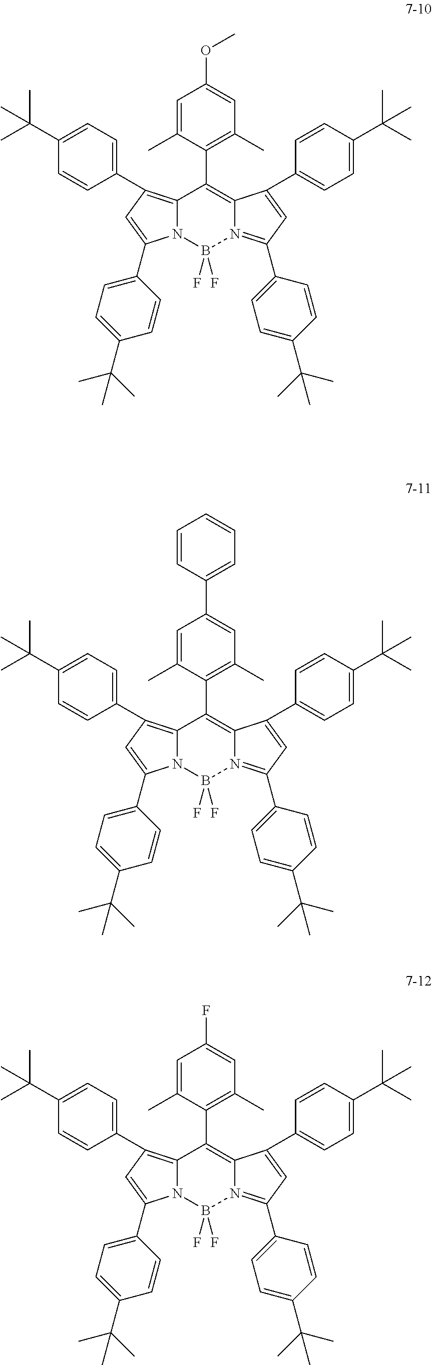

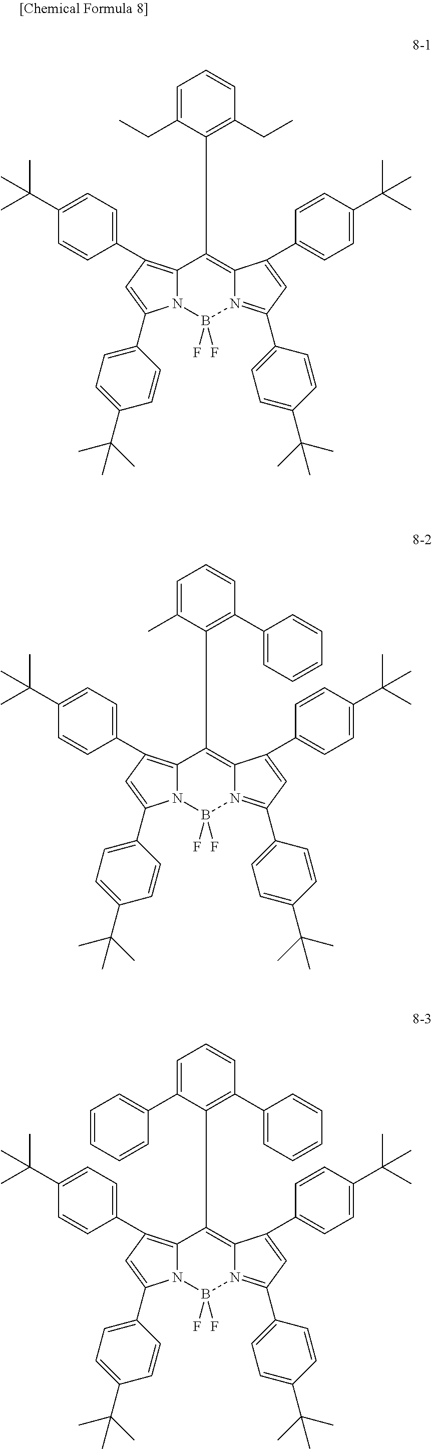

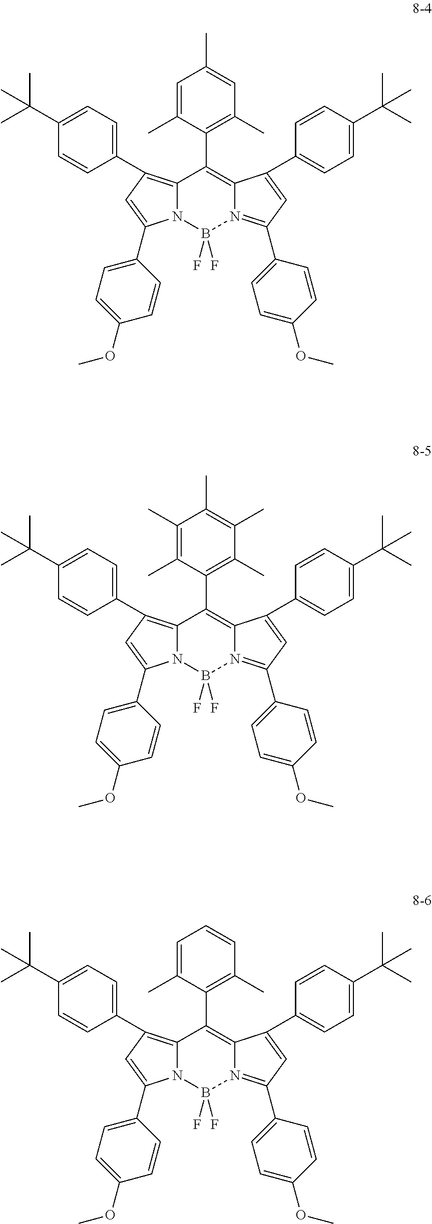

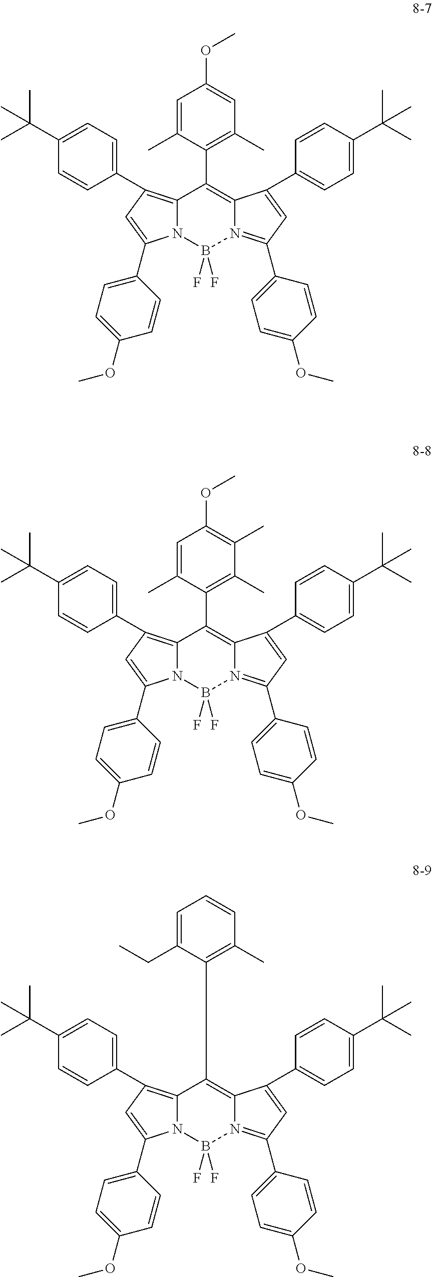

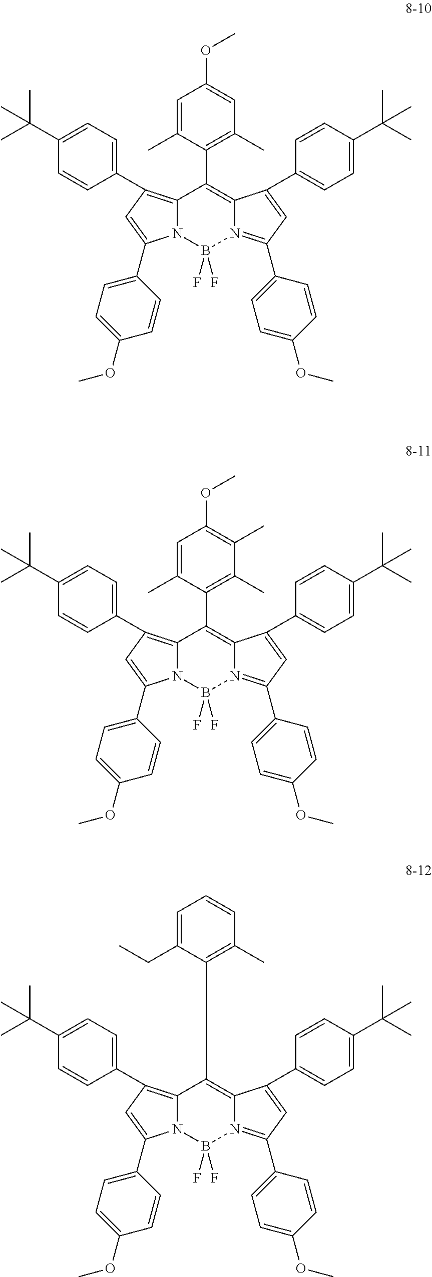

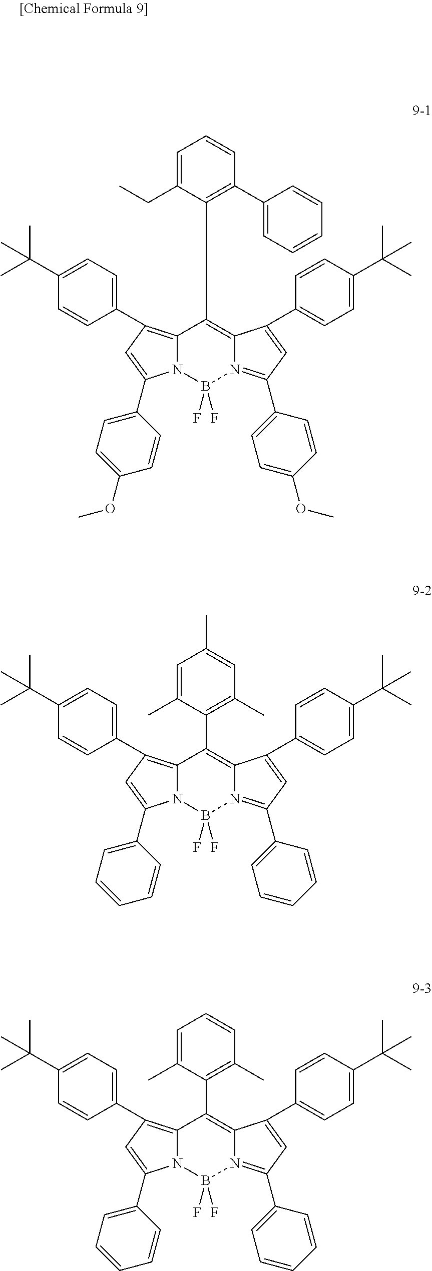

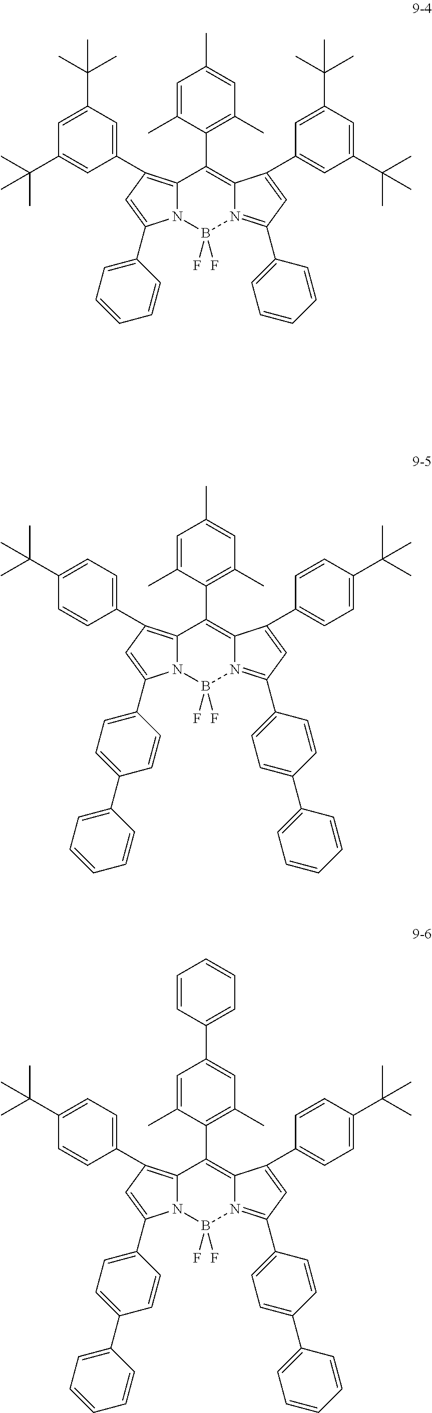

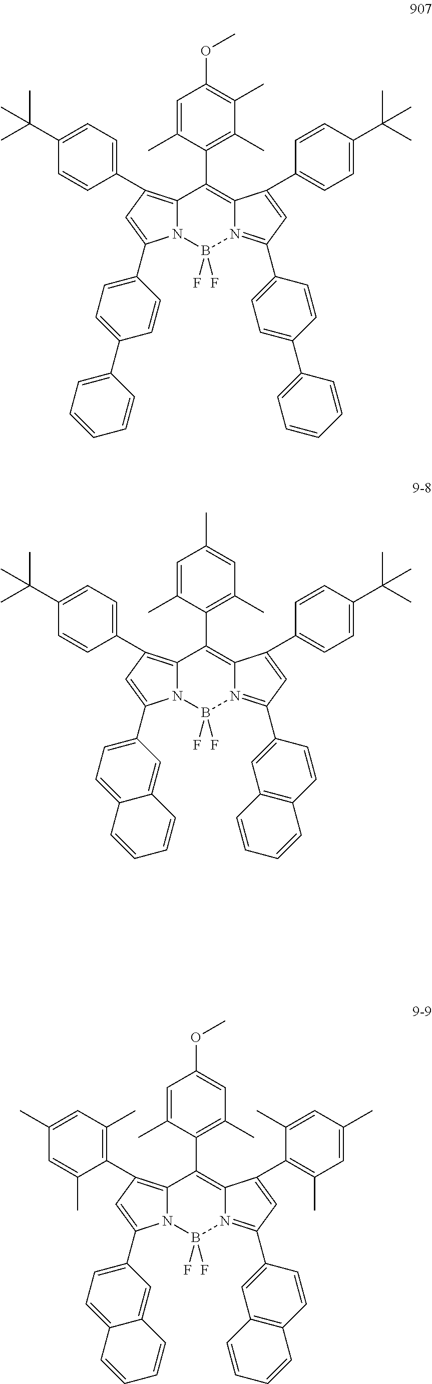

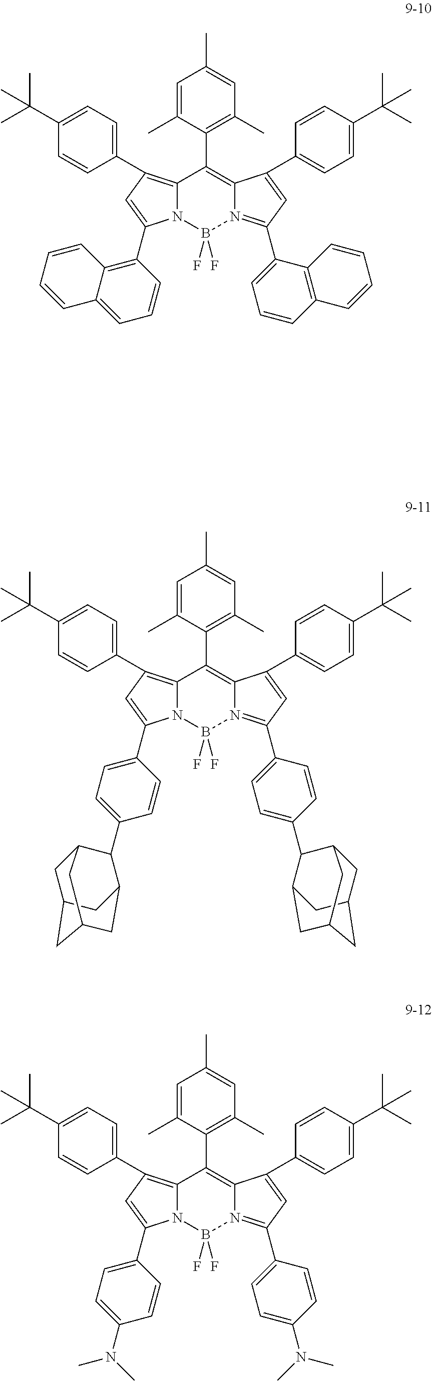

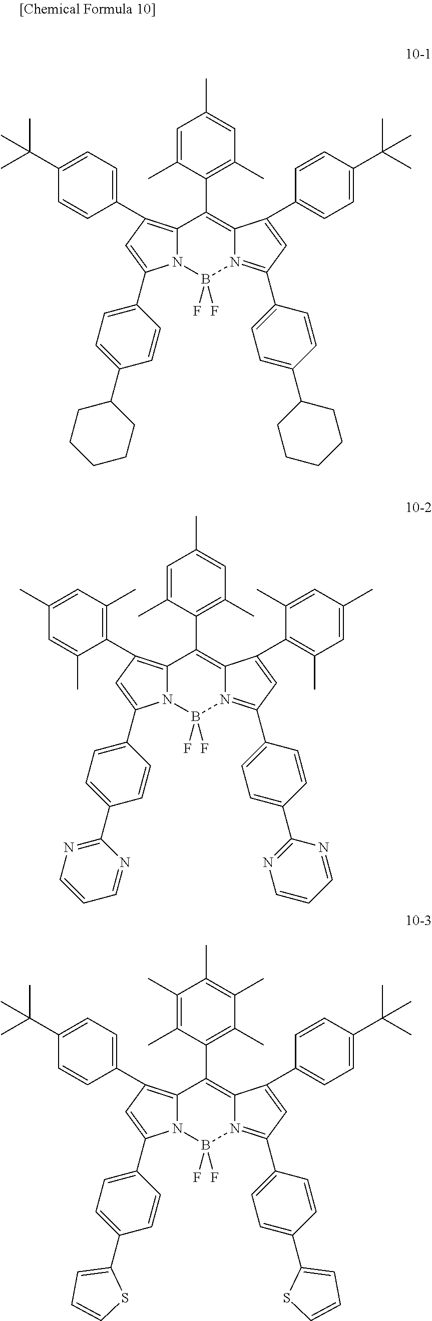

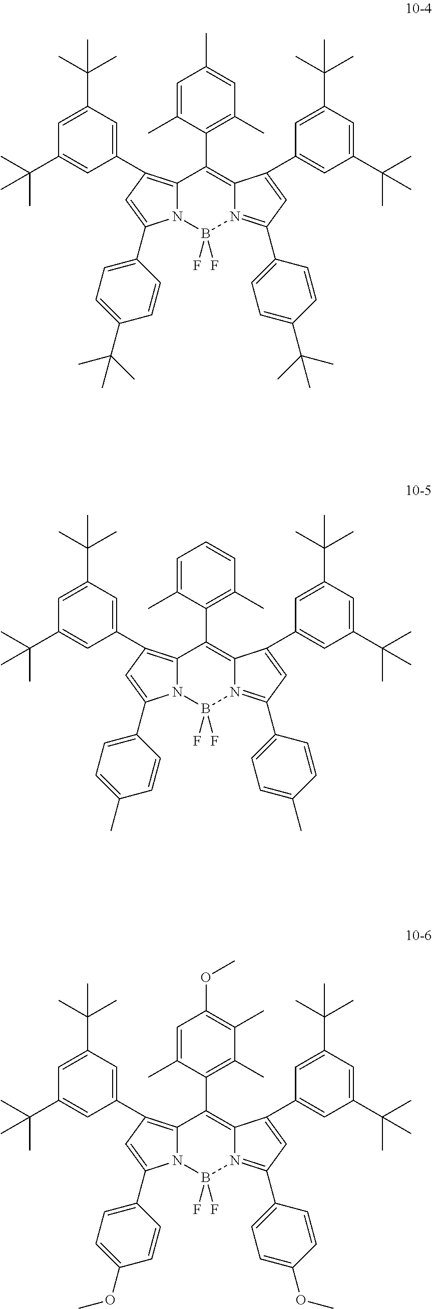

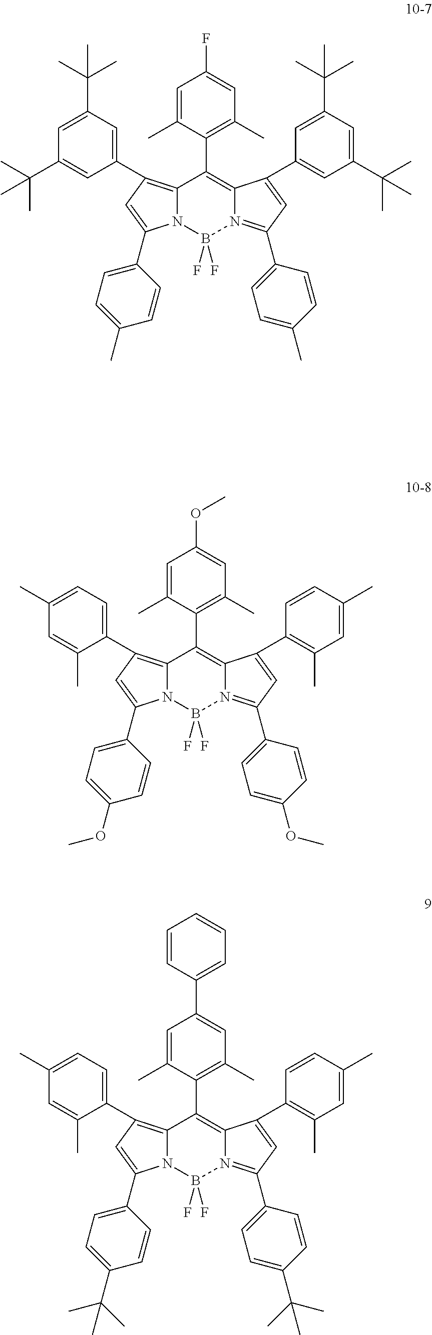

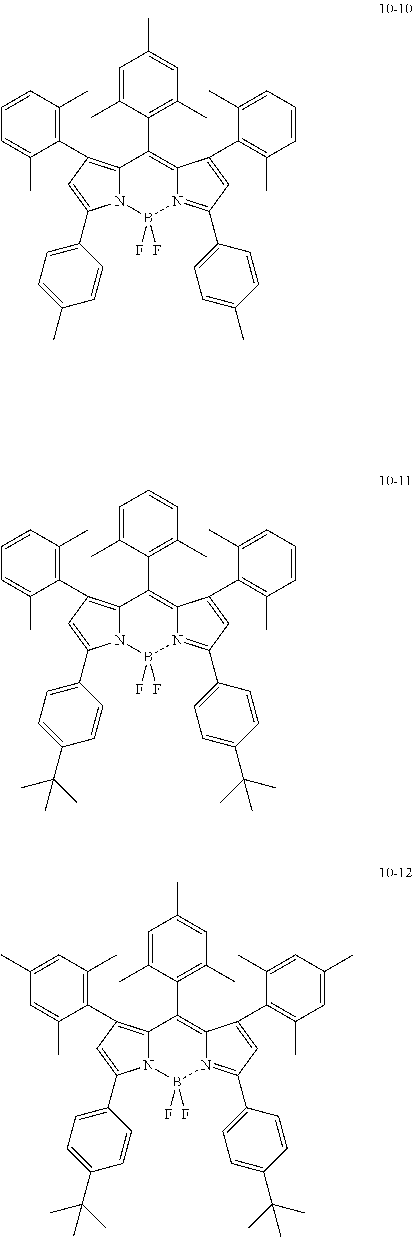

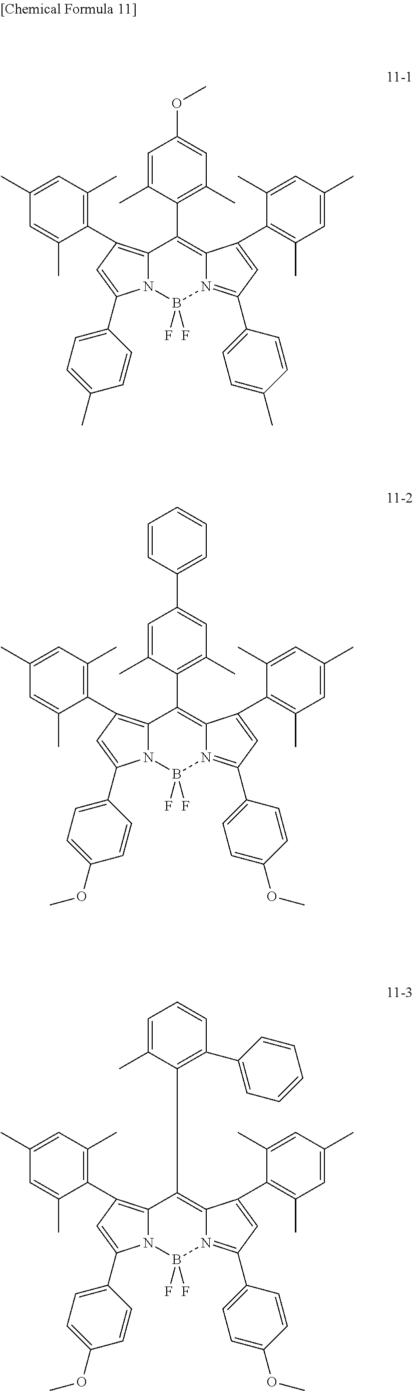

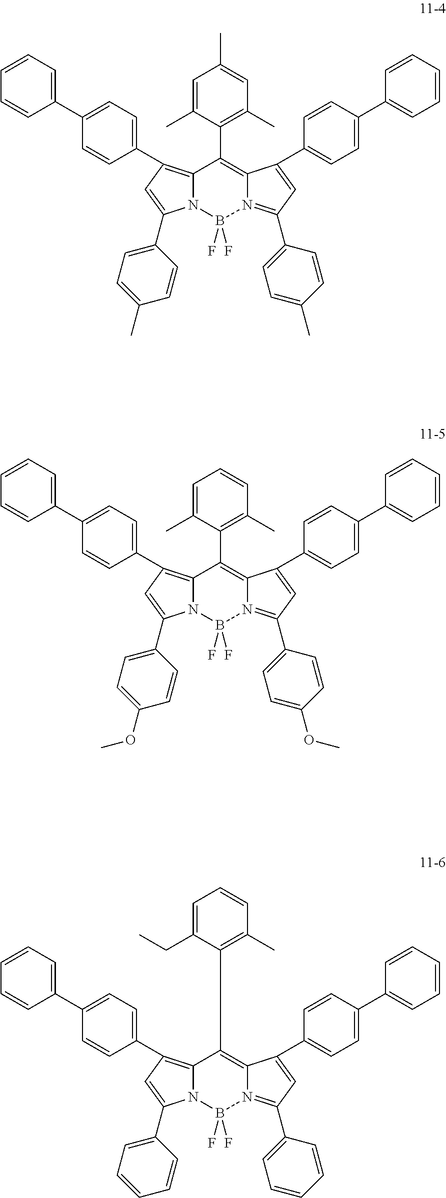

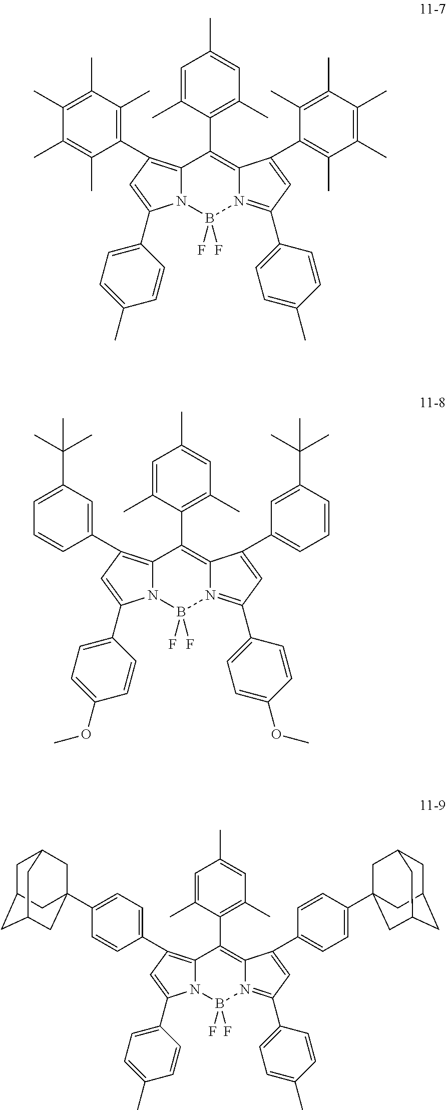

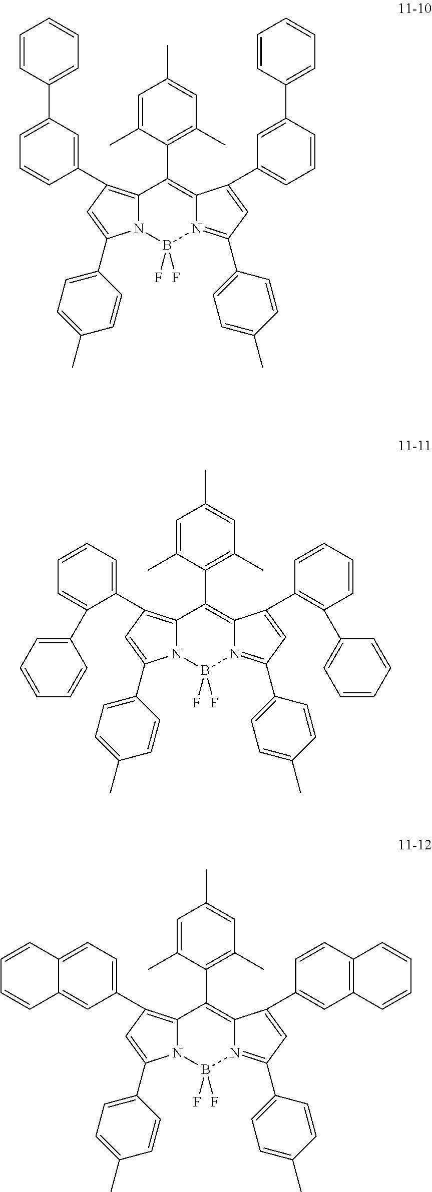

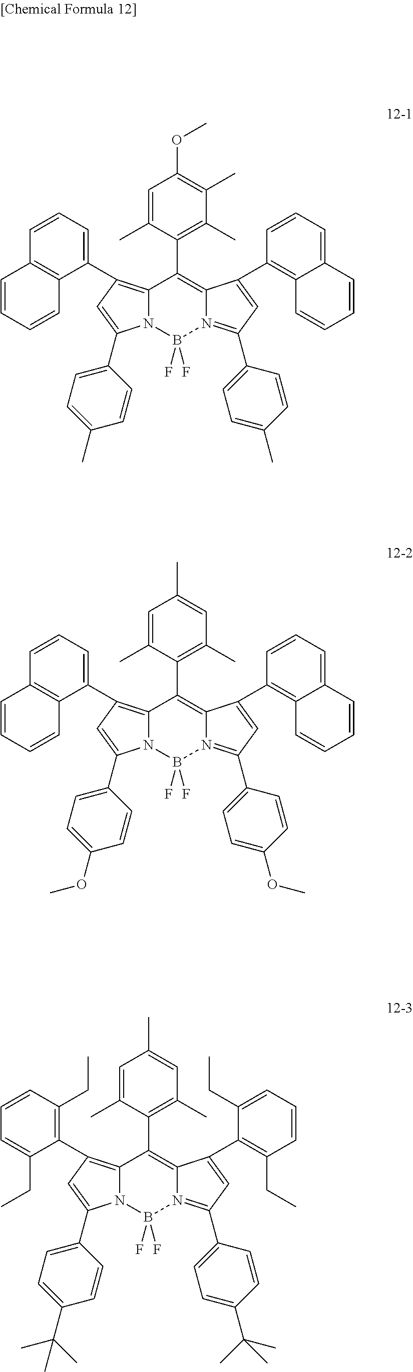

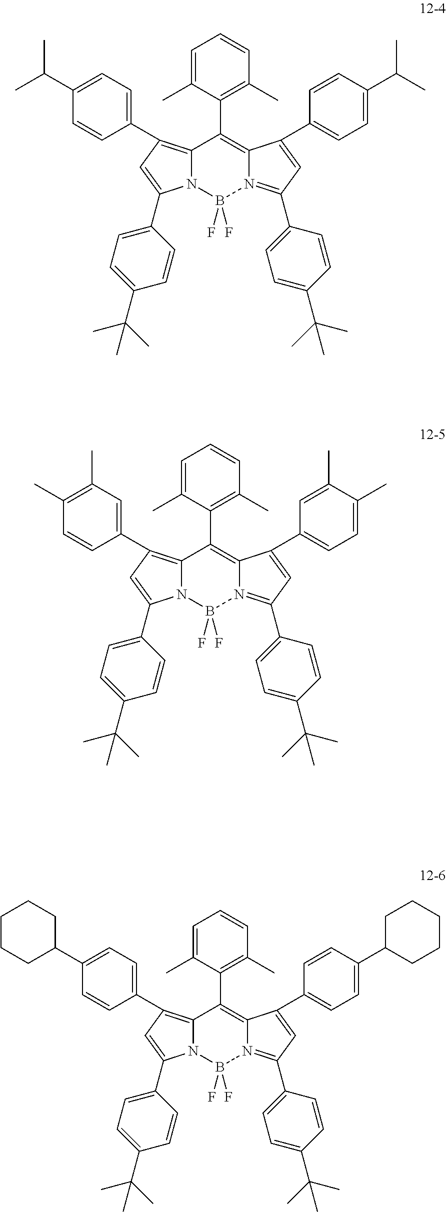

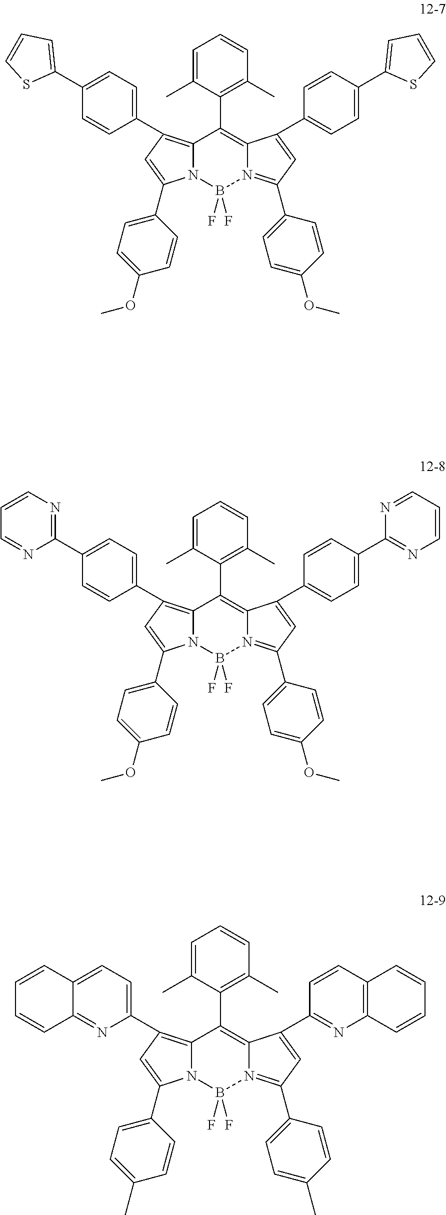

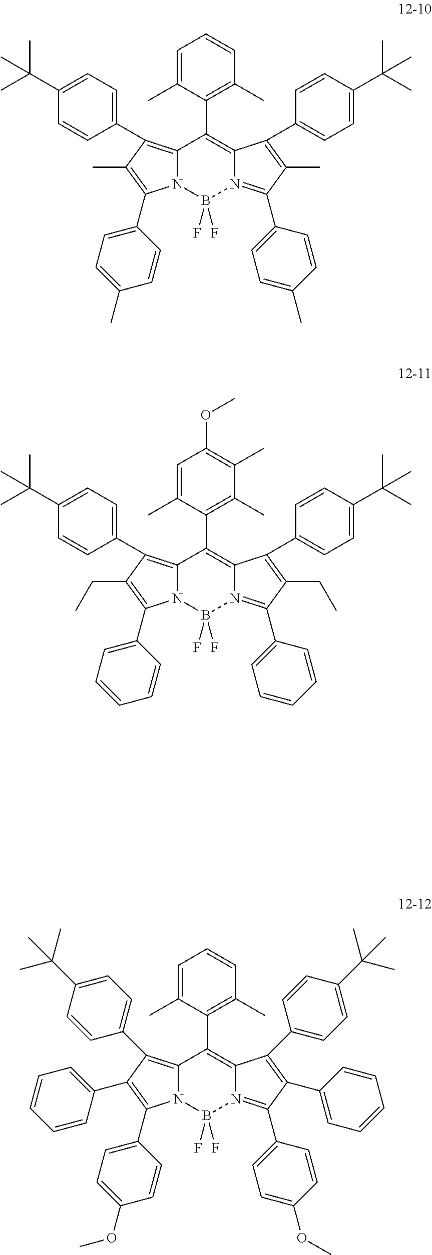

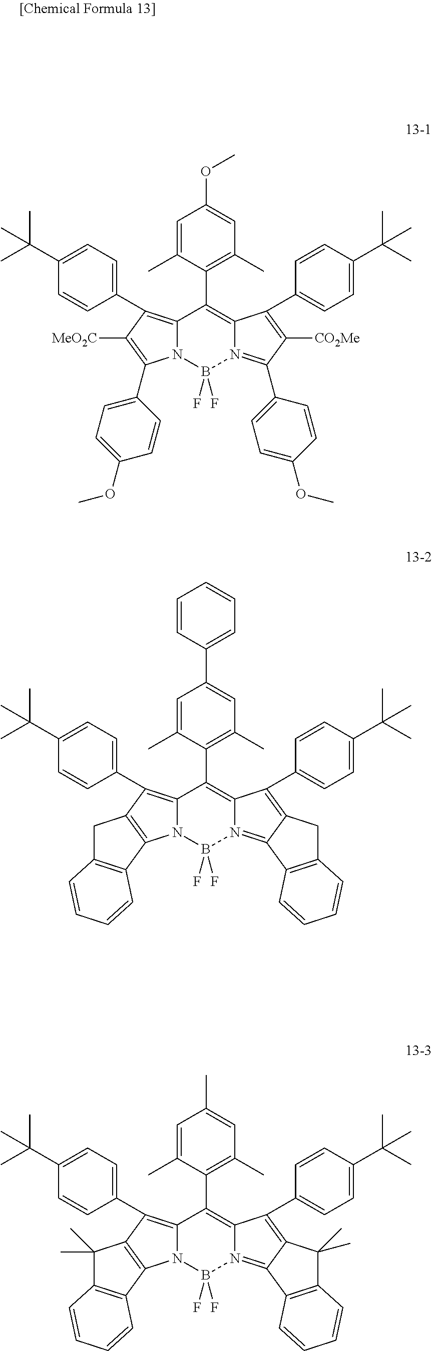

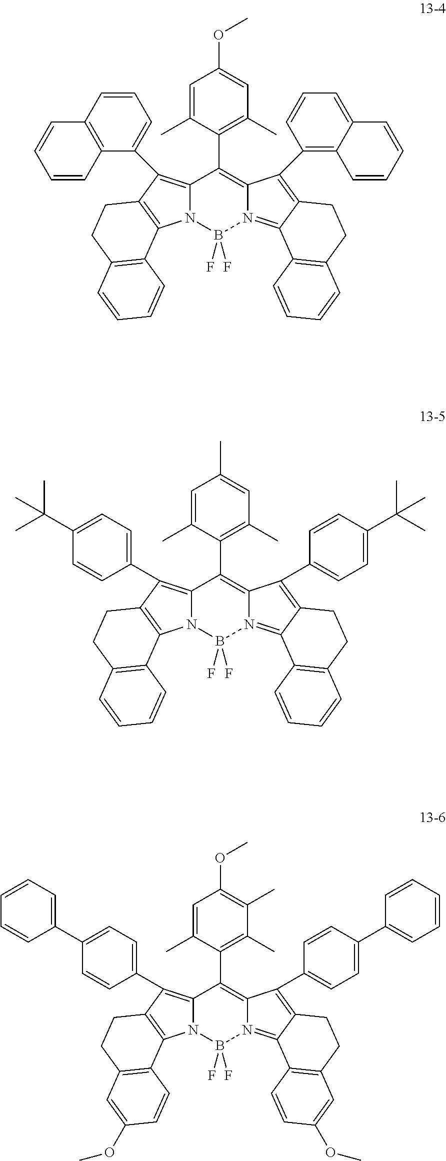

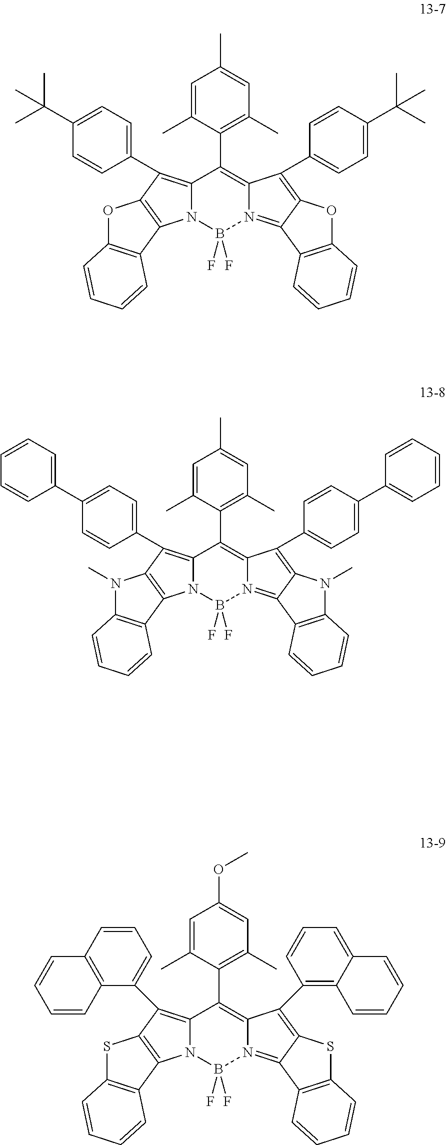

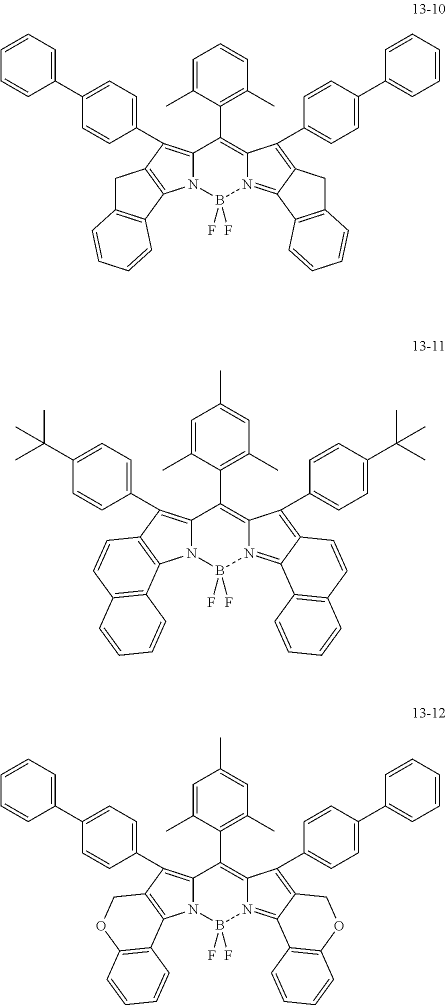

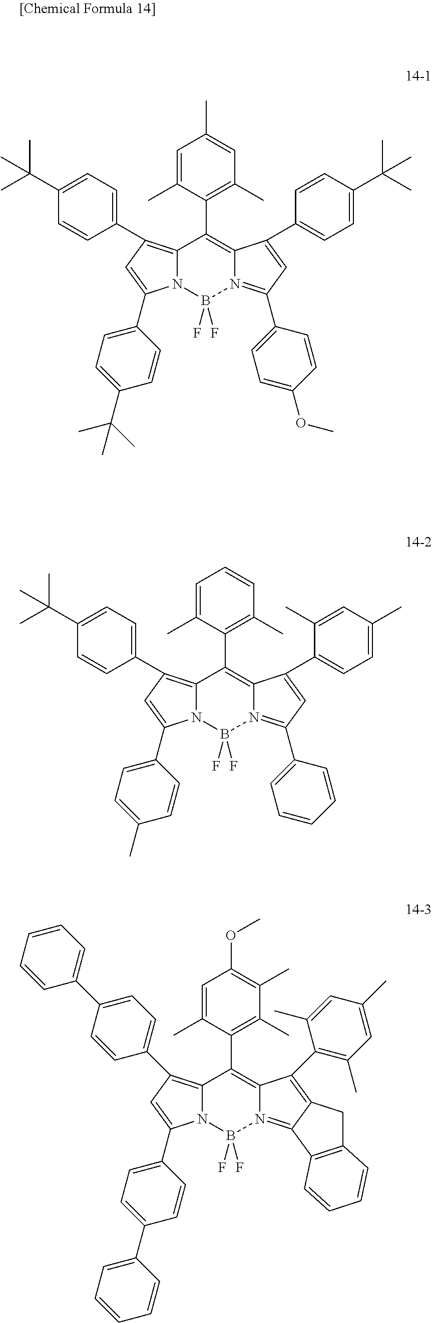

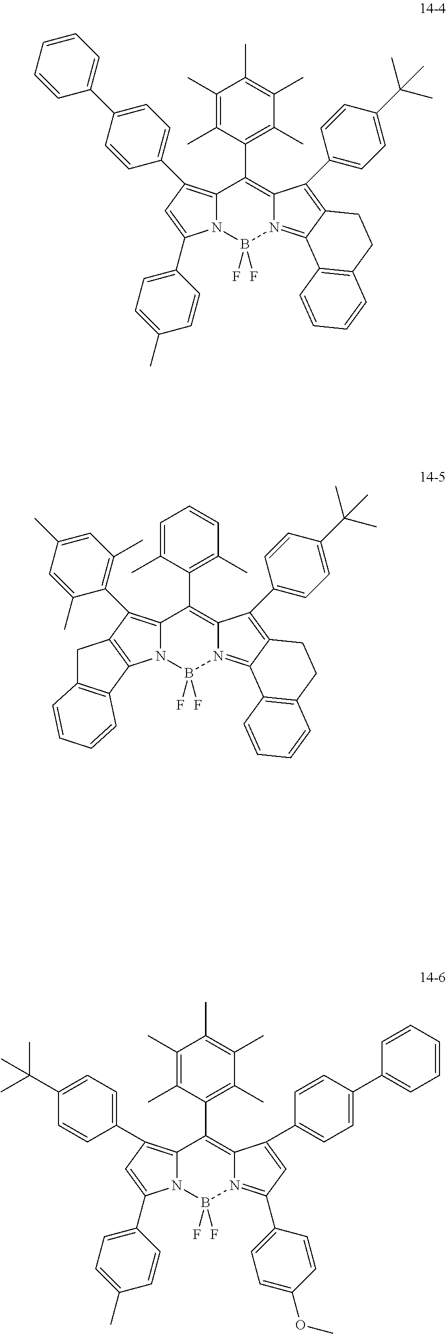

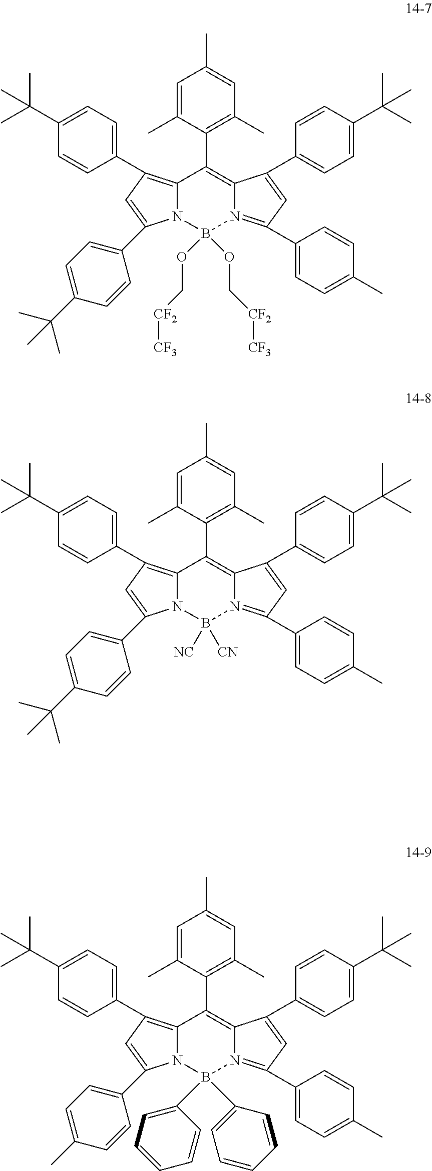

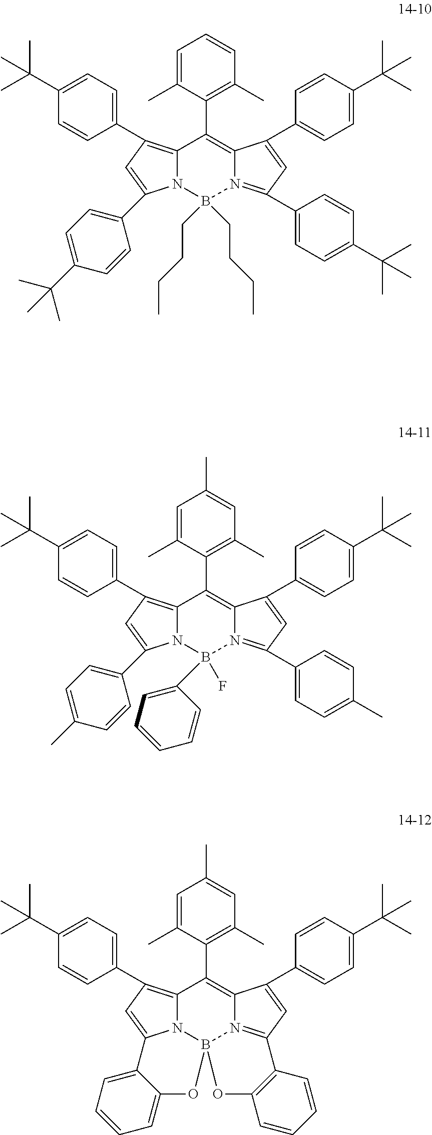

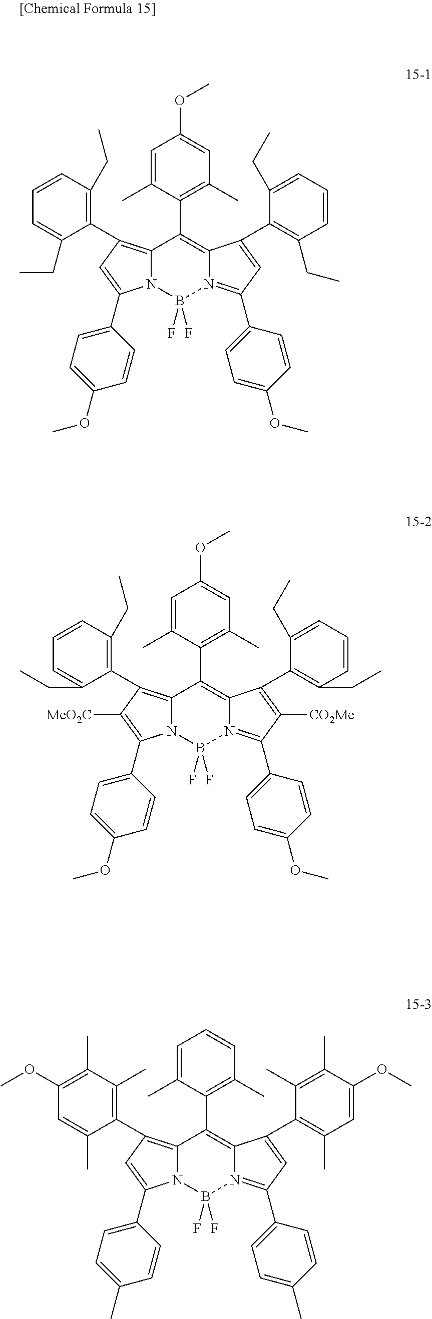

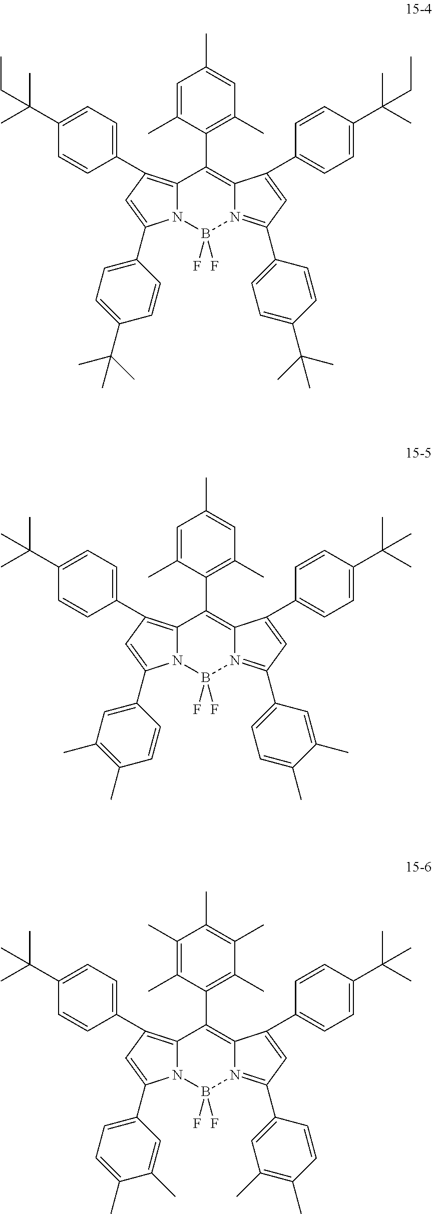

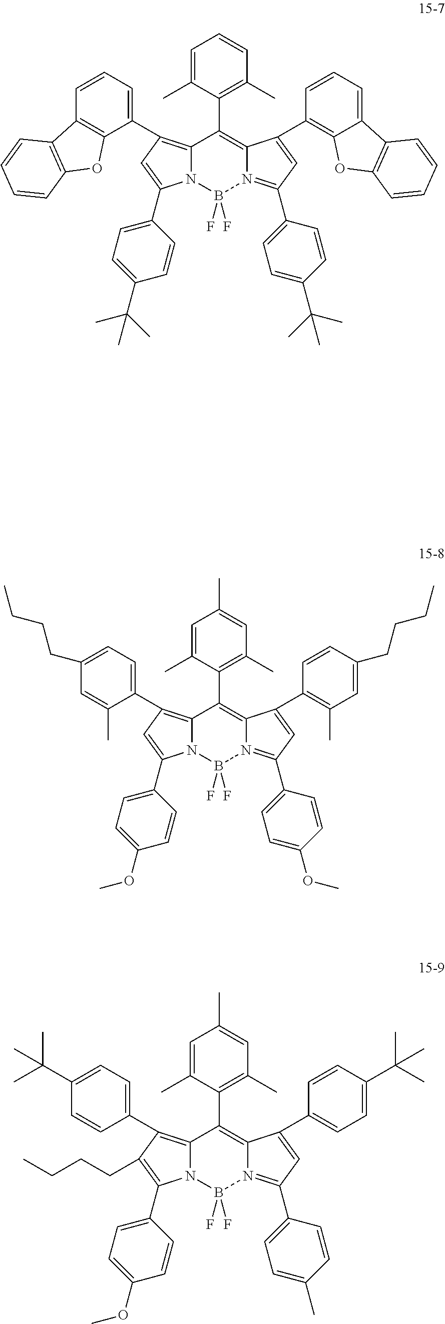

The pyrromethene boron complex represented by the general formula (1) can be produced by reference to methods mentioned in J. Org. Chem., vol.64, No. 21, pp. 7813-7819 (1999), Angew. Chem., Int. Ed. Engl., vol.36, pp.1333-1335 (1997), Org. Lett., vol.12, pp.296 (2010) and the like.

When introducing an aryl group or a heteroaryl group into the pyrromethene skeleton, examples of the method include, but are not limited to, a method in which a carbon-carbon bond is formed by a coupling reaction between a halogenated derivative of a pyrromethene compound and boronic acid or a boronic acid ester derivative in the presence of a catalyst of metal such as palladium. Similarly, when introducing an amino group or a carbazolyl group into the pyrromethene skeleton, examples of the method include, but are not limited to, a method in which a carbon-nitrogen bond is formed by a coupling reaction between a halogenated derivative of a pyrromethene compound and an amine or a carbazole derivative in the presence of a catalyst of metal such as palladium.

It is preferable that the pyrromethene boron complex thus obtained is subjected to organic synthetic purification such as recrystallization or column chromatography, and then purified by heating under reduced pressure, which is generally called sublimation purification, to remove low boiling point components and improve the purity. The heating temperature in the sublimation purification is not particularly limited, but is preferably 330° C. or lower, and more preferably 300° C. or lower, from the viewpoint of preventing thermal decomposition of the pyrromethene boron complex. From the viewpoint of facilitating the control of the vapor deposition rate during vapor deposition, the heating temperature is preferably 230° C. or higher, and more preferably 250° C. or higher.

The purity of the pyrromethene boron complex thus produced is preferably 99% by weight or more from the viewpoint of enabling the light emitting element to exhibit stable characteristics.

The optical properties of the pyrromethene boron complex represented by the general formula (1) can be obtained by measuring the absorption spectrum, emission spectrum and fluorescence quantum yield of the diluted solution. The solvent is not particularly limited as long as it dissolves the pyrromethene boron complex, and also has the absorption spectrum which does not overlap with that of the pyrromethene boron complex and is transparent, and specific examples thereof include toluene. The concentration of the solution is not particularly limited as long as it has sufficient absorbance and no concentration quenching occurs, but it is preferably in the range of 1×10⁻⁴ mol/L to 1×10⁻⁷ mol/L, and more preferably 1×10⁻³ mol/L to 1×10⁻⁶mol/L. The absorption spectrum can be measured by a common ultraviolet-visible spectrophotometer. The emission spectrum can be measured by a common fluorescence spectrophotometer. It is preferable to use an absolute quantum yield measuring device using an integrating sphere for the measurement of the fluorescence quantum yield.

The pyrromethene boron complex represented by the general formula (1) preferably emits light observed in the region having a peak wavelength of 580 nm or more and 750 nm or less when irradiated with excitation light. Hereinafter, the emission observed in the region where the peak wavelength is 580 nm or more and 750 nm or less is referred to as “red emission”. From the viewpoint of expanding the color gamut and improving the color reproducibility, the peak wavelength of emission is preferably in the region of 600 nm or more and 650 nm or less, and more preferably 600 nm or more and 640 nm or less.

The pyrromethene boron complex represented by the general formula (1) preferably emits red light when irradiated with excitation light having a wavelength in the range of 430 nm or more and 600 nm or less. When the pyrromethene boron complex represented by the general formula (1) is used as a dopant material for a light emitting element, the pyrromethene boron complex exhibits red emission by absorbing light emitted from the host material. Since a common host material emits light having a wavelength in the range of 430 nm or more and 600 nm or less, if this excitation light can induce red emission, this contributes to high efficiency of the light emitting element.

The light emitted by the pyrromethene boron complex represented by the general formula (1) by irradiation with excitation light preferably has a sharp emission spectrum in order to achieve high color purity. High luminance and high color purity can be achieved by the resonance effect of the microcavity structure in the top-emission type element, which is the mainstream in display devices and illumination devices. However, the sharper the emission spectrum of the light emitting material, the stronger the resonance effect, and the higher the efficiency. From this viewpoint, the half width of the emission spectrum is preferably 60 nm or less, more preferably 50 nm or less, and still more preferably 45 nm or less.

The luminance efficiency of the light emitting element depends on the fluorescence quantum yield of the light emitting material. Therefore, it is desirable that the fluorescence quantum yield may be as close to 100% as possible when measured in a diluted solution. Since R¹, R², Ar¹ and Ar² are as mentioned above, the pyrromethene boron complex represented by the general formula (1) can suppress rotation and vibration at the meso-position and reduce heat deactivation, thus obtaining high fluorescence quantum yield. From the above viewpoint, the fluorescence quantum yield of the pyrromethene boron complex is preferably 90% or more, and more preferably 95% or more. However, the fluorescence quantum yield shown here is determined by measuring a diluted solution prepared by using toluene as a solvent using an absolute quantum yield measuring device.

The pyrromethene boron complex represented by the general formula (1) is used in a thin film form in the light emitting element, and is expected to be used particularly as a dopant. Therefore, it is preferable to evaluate optical properties of the thin film doped with the pyrromethene boron complex of the general formula (1) (hereinafter referred to as doped thin film).

A method for forming a doped thin film will be described. The doped thin film is formed on a transparent substrate with no absorption in the visible region. Examples of the transparent substrate include a quartz glass plate. A thin film is formed by co-depositing a matrix material and the pyrromethene boron complex represented by the general formula (1) on this substrate. Here, as the matrix material, a wide bandgap material with no absorption of excitation light is used, and specific examples thereof include 3,3′-di(N-carbazolyl)biphenyl (mCBP). At this time, the doping concentration of the pyrromethene boron complex represented by the general formula (1) is preferably the same as the doping concentration when the light emitting element is actually used, and is preferably selected from a range of 0.1 to 20% by weight. The thickness of the doped thin film is not particularly limited as long as it sufficiently absorbs excitation light and is easy to produce, but is preferably in the range of 100 to 1,000 nm. The doped thin film may be sealed with a transparent sealing resin after formation.

The emission wavelength from the doped thin film generally tends to be the same or longer than that of the solution state. Therefore, the emission peak wavelength of the doped thin film containing the pyrromethene boron complex represented by the general formula (1) is preferably in the region of 580 nm or more and 750 nm or less, more preferably 600 nm or more and 660 nm or less, and still more preferably 600 nm or more and 650 nm or less.

The half width of the emission spectrum of the doped thin film generally tends to be equal to or larger than that of the solution state. Therefore, the half width of the emission spectrum of the doped thin film containing the pyrromethene boron complex represented by the general formula (1) is preferably 70 nm or less, more preferably 60 nm or less, and still more preferably 50 nm or less.

Since the fluorescence quantum yield of the doped thin film fluctuates affected by the formation state of the doped thin film, combination with the matrix material, and excitation light wavelength, it is difficult to perform absolute value comparison. Therefore, it is preferable that the fluorescence quantum yield of the doped thin film of each material is measured under certain conditions and is evaluated by relative comparison between them. When the doping concentration is kept constant and compared using this evaluation method, it is possible for the doped thin film containing the pyrromethene boron complex represented by the general formula (1) to obtain a higher fluorescence quantum yield than that of the doped thin film containing a conventional pyrromethene boron complex.

It is generally known that, when the concentration of the dopant increases, concentration quenching occurs due to intramolecular interaction. Therefore, even in the doped thin film, there is observed a negative correlation in which the fluorescence quantum yield decreases as the doping concentration increases. If the negative correlation between the fluorescence quantum yield and the doping concentration is large, it is disadvantageous since the allowable range of the doping concentration decreases in the production of the light emitting element. Regarding the pyrromethene boron complex represented by the general formula (1), the aggregation of molecules is suppressed due to the steric hindrance caused by the substituent at the meso-position and Ar¹ and Ar², and high fluorescence quantum yield of the pyrromethene boron complex itself leads to small nonradiation deactivation even if self-absorption of emission occurs. Therefore, concentration quenching is unlikely to occur in doped thin film containing this pyrromethene boron complex, and thus the negative correlation between the fluorescence quantum yield and the doping concentration can be reduced, in other words, the doped concentration dependence can be decreased.

The molecular orientation property can be measured by examining the angle dependence of the emission spectrum of the doped thin film. Because of angular dependence of the emission from the dopant molecules themselves, the radiant intensity of light to a certain angle increases in the case where the dopant molecules are aligned, that is, oriented in a certain direction, in the doped thin film, as compared with the case where the dopant molecules exist in a random orientation. Considering the light emitting element having such doped thin film, it is possible to increase the amount of light extracted to the outside by matching the angle at which the radiant intensity increases and the light extraction direction, leading to an improvement in luminance efficiency. In particular, since the light extraction direction is limited in the top-emission type element utilizing the resonance effect, it is preferable to enhance the molecular orientation property of the doped thin film from the viewpoint the improvement in luminance efficiency. The pyrromethene boron complex represented by the general formula (1) has a rigid structure since rotation and vibration are suppressed by steric hindrance between the substituent at the meso-position and Ar¹ and Ar² as mentioned above, so that it is easier to align than the molecules of the flexible structure, and the molecular orientation property of the doped thin film can be enhanced.

The heat characteristic of the pyrromethene boron complex represented by the general formula (1) can be measured by a thermogravimetric analyzer (TGA) or a differential scanning calorimeter (DSC). In order to withstand heat load during vacuum heating purification (so-called sublimation purification) and vapor deposition, the decomposition temperature of the pyrromethene boron complex represented by the general formula (1) is preferably 300° C. or higher. When the pyrromethene boron complex has a melting point, the melting point may be higher or lower than the decomposition temperature, but is preferably 250° C. or higher so that vacuum heating purification can be stably performed.

### Light Emitting Element Material

The pyrromethene boron complex represented by the general formula (1) is used as a light emitting element material in the light emitting element since it can achieve high luminance efficiency. Here, the light emitting element material in the present invention means a material used for any layer of the light emitting element, and as mentioned later, includes a material used for a hole injection layer, a hole transporting layer, a light emitting layer and/or an electron transporting layer, and a material used for a capping layer of the electrodes.

Since the pyrromethene boron complex represented by the general formula (1) has high emission performance, it is preferably a material used for the light emitting layer. In particular, since the pyrromethene boron complex exhibits strong emission in the red region, it is suitably used as a red-light emitting material.

The light emitting element material of the present invention may be composed of the pyrromethene boron complex represented by the general formula (1) alone, or as a mixture of the pyrromethene boron complex and a plurality of other compounds. From the viewpoint capable of stably producing the light emitting element, it is preferable that the light emitting element material is composed of the pyrromethene boron complex represented by the general formula (1) alone. Here, the pyrromethene boron complex represented by the general formula (1) alone means that the corresponding compound is contained in an amount of 99% by weight or more.

### Light Emitting Element

Embodiments of the light emitting element of the present invention will be described below. The light emitting element of the present invention comprises an anode and a cathode, and one or more organic layers between the anode and the cathode, and it is preferable that at least one of the organic layers is a light emitting layer, and the light emitting layer is an organic electroluminescent element which emits light by electric energy.

The light emitting element of the present invention may be either a bottom-emission type or a top-emission type.

The layer structure between the anode and the cathode in such light emitting element includes, in addition to the structure composed of a light emitting layer alone, laminated structures such as 1) light emitting layer/electron transporting layer, 2) hole transporting layer/light emitting layer, 3) hole transporting layer/light emitting layer/electron transporting layer, 4) hole injection layer/hole transporting layer/light emitting layer/electron transporting layer, 5) hole transporting layer/light emitting layer/electron transporting layer/electron injection layer, 6) hole injection layer/hole transporting layer/light emitting layer/electron transporting layer/electron injection layer, 7) hole injection layer/hole transporting layer/light emitting layer/hole blocking layer/electron transporting layer/electron injection layer, and 8) hole injection layer/hole transporting layer/electron blocking layer/light emitting layer/hole blocking layer/electron transporting layer/electron injection layer.

A plurality of the above laminated structures may be laminated via an intermediate layer to form a tandem-type light emitting element. The tandem-type light emitting element is a light emitting element having at least two light emitting layers between the anode and the cathode. It is preferable to have at least one charge generation layer between two or more light emitting layers. When the light emitting element has two or more light emitting layers, the pyrromethene boron complex represented by the general formula (1) is contained in at least one light emitting layer. In other words, the pyrromethene boron complex represented by the general formula (1) may be contained in all the light emitting layers, or may be contained in only a part of the light emitting layers. Since the tandem-type light emitting element can achieve high luminance at a low current by having a plurality of light emitting layers, it is characterized by high efficiency and long life. The tandem-type light emitting element composed of light emitting layers of three colors R, G and B becomes a highly efficient white light element and is mainly used in the field of television and lighting. This method has such an advantage that the process can be simplified as compared with the light emitting element of the RGB color-coding method. Examples of the intermediate layer include an intermediate electrode, an intermediate conductive layer, a charge generation layer, an electron extraction layer, a connection layer, an intermediate insulating layer and the like, and known material configurations can be used. It is preferable to have at least one charge generation layer as the intermediate layer. Specific examples of the tandem-type include laminated structures having a charge generation layer as an intermediate layer, such as 9) hole injection layer/hole transporting layer/light emitting layer/electron transporting layer/electron injection layer/charge generation layer/hole injection layer/hole transporting layer/light emitting layer/electron transporting layer/electron injection layer. Specifically, a pyridine derivative and a phenanthroline derivative are preferably used as the material constituting the intermediate layer.

Each of the above layers may be either a single layer or a plurality of layers, and may be doped. There is also included an element structure further comprising an anode, one or more organic layers including a light emitting layer, and a cathode, and further a layer using a capping material for improving luminance efficiency by the optical interference effect.

The light emitting element of the present invention is preferably a top-emission type organic electroluminescent element. In the case of the top-emission type organic electroluminescent element, the anode is preferably a metal electrode which reflects light from the light emitting layer, that is, a reflective electrode. The anode may form a laminated structure of a reflective electrode layer and a transparent electrode layer. In the case of the laminated structure of the reflective electrode layer and the transparent electrode layer, the thickness of the transparent electrode layer on the reflective electrode layer may be changed in order to control the emission wavelength taken out from the light emitting element. After appropriately laminating an organic layer on the anode, when a thin-film translucent silver is used, for example, as the translucent electrode in the cathode, it is possible to introduce a microcavity structure, in which a part of the light is reflected and resonated in the organic electroluminescent element, into the element. When the microcavity structure is introduced in the organic electroluminescent element in this way, the spectrum of the light emitted from the organic layer and emitted through the cathode is steeper than when the organic electroluminescent element does not have the microcavity structure due to the resonance effect, and the injection strength to the front is greatly increased. In such top-emission type element, if the emission spectrum of the light emitting material is sharp due to the microcavity effect, the luminance efficiency can be further improved. When such light emitting element is used for a display, it can contribute to an improvement in color gamut and an improvement in luminance.

The pyrromethene boron complex represented by the general formula (1) may be used for any layer in the above element structure, but is preferably used for a light emitting layer because of having high fluorescence quantum yield and thin-film stability.

Specific examples of the configuration of the light emitting element will be shown below, but the configuration of the present invention is not limited thereto.

### (Substrate)

In order to maintain the mechanical strength of the light emitting element and have a barrier property to prevent water vapor and oxygen from entering into the light emitting layer, it is preferable to form the light emitting element on the substrate. Examples of the substrate include, but are not particularly limited to, a glass plate, a ceramic plate, a resin film, a resin thin film, a metal thin plate and the like. Of these, a glass substrate is preferably used from the viewpoint of being transparent and easy to process, and a glass substrate having high transparency is particularly preferable for a bottom emission element which extracts light through the substrate. Flexible displays and foldable displays are increasing mainly in mobile devices such as smartphones, and a resin film and a resin thin film obtained by curing varnish are preferably used for this purpose. A heat-resistant film is used as the resin film, and specific examples thereof include a polyimide film, a polyethylene naphthalate film and the like.

Various wirings, circuits, and TFT switching elements for driving an organic EL may be provided on the surface of the substrate.

### (Anode)

The anode is formed on the substrate. Here, various wirings, circuits and switching elements may be interposed between the substrate and the anode. The material used for the anode is not particularly limited as long as it can efficiently inject holes into the organic layer, but it is preferably a transparent or translucent electrode for a bottom-emission type element, and a reflective electrode is preferable for a top-emission type element.

Examples of the material of the transparent or translucent electrode include conductive metal oxides such as zinc oxide, tin oxide, indium oxide, indium tin oxide (ITO) and indium zinc oxide (IZO); metals such as gold, silver, aluminum and chromium; and conductive polymers such as polythiophene, polypyrrole and polyaniline. However, when using metal, it is preferable to reduce the thickness so that light can be semi-transmitted. Of the above, indium tin oxide (ITO) is more preferable from the viewpoint of the transparency and stability.

The material of the reflective electrode is preferably a material with no absorption of all light and high reflectance, and specific examples thereof include metals such as aluminum, silver and platinum.

As the method for forming an anode, an optimum method can be adopted depending on the forming material, and examples thereof include a sputtering method, a vapor deposition method, an inkjet method and the like. For example, when the anode is formed of metal oxide, a sputtering method is used, and when the anode is formed of metal, a vapor deposition method is used. The thickness of the anode is not particularly limited, but is preferably several nm to several hundred nm.

These electrode materials may be used alone, or may be used by laminating or mixing a plurality of materials.

### (Cathode)

The cathode is formed on the surface opposite to the anode with the organic layer interposed therebetween, and it is particularly preferable that the cathode is formed on the surface of the electron transporting layer or the electron injection layer surface. The material used for the cathode is not particularly limited as long as it can efficiently inject electrons into the light emitting layer, but is preferably a reflective electrode for a bottom-emission type element and a translucent electrode for a top-emission type element.

Generally, preferred are metals such as platinum, gold, silver, copper, iron, tin, aluminum and indium; alloys and multilayered laminated films of these metals with metals of low-work function, such as lithium, sodium, potassium, calcium and magnesium; conductive metal oxides such as zinc oxide, indium tin oxide (ITO) and indium zinc oxide (IZO), and the like. Of these, aluminum, silver or magnesium is preferable as a main component in view of the electrical resistance, ease of film formation, film stability, luminance efficiency and the like. It is preferable that the cathode is composed of magnesium and silver since electron injection into the electron transporting layer and the electron injection layer in the present invention is facilitated, thus enabling low voltage drive. The thickness of the cathode is not particularly limited, but is preferably 50 to 200 nm in the case of the reflective electrode, and preferably 5 to 50 nm in the case of the translucent electrode.

### (Capping Layer)

In order to protect the cathode, it is preferable to laminate a capping layer on the cathode. Examples of the material constituting the capping layer include, but are not particularly limited to, metals such as platinum, gold, silver, copper, iron, tin, aluminum and indium; alloys using these metals; inorganic substances such as silica, titania, niobium oxide, tantalum oxide, zinc oxide, antimony oxide, scandium oxide, zirconium oxide, selenium oxide, indium oxide, tin oxide, hafnium oxide, ytterbium oxide, lanthanum oxide, yttrium oxide, thorium oxide, magnesium oxide, zinc selenide, zinc sulfide, silicon carbide, gallium nitride and silicon nitride; metal fluorides such as lithium fluoride, calcium fluoride, sodium fluoride, aluminum fluoride, magnesium fluoride, barium fluoride, ytterbium fluoride, yttrium fluoride, praseodymium fluoride, gadolinium fluoride, lanthanum fluoride, neodymium fluoride and cerium fluoride; organic polymer compounds such as polyvinyl alcohol, polyvinyl chloride and hydrocarbon-based polymer compounds; low molecular weight organic compounds such as arylamine derivatives, carbazole derivatives, benzimidazole derivatives, triazole derivatives and boron complexes, and the like. However, when the light emitting element has an element structure (top-emission type structure) which extracts light from the cathode side, the material used for the capping layer is selected from materials having light transmittance in the visible light region. At this time, from the viewpoint of improving the light extraction efficiency, the capping layer preferably has a laminated structure of one or more high refractive index layers and one or more low refractive index layers. Here, the high refractive index layer is preferably composed of at least one material selected from the group consisting of low molecular weight organic compounds such as arylamine derivatives, carbazole derivatives, benzimidazole derivatives and triazole derivatives; and inorganic substances such as silica, titania, niobium oxide, tantalum oxide, zinc oxide, antimony oxide, scandium oxide, zirconium oxide, selenium oxide, indium oxide, tin oxide, hafnium oxide, ytterbium oxide, lanthanum oxide, yttrium oxide, thorium oxide, magnesium oxide, zinc selenide, zinc sulfide, silicon carbide, gallium nitride and silicon nitride. The low refractive index layer is preferably composed of at least one material selected from the group consisting of boron complexes; and metal fluorides such as lithium fluoride, calcium fluoride, sodium fluoride, aluminum fluoride, magnesium fluoride, barium fluoride, ytterbium fluoride, yttrium fluoride, praseodymium fluoride, gadolinium fluoride, lanthanum fluoride, neodymium fluoride and cerium fluoride.

### (Hole Injection Layer)

The hole injection layer is inserted between the anode and the hole transport layer to facilitate hole injection. The hole injection layer may be either a single layer or a plurality of laminated layers. The hole injection layer is preferably present between the hole transporting layer and the anode since driving at a lower voltage is possible and the durability life is improved and, furthermore, the carrier balance of the element is also improved, leading to an improvement in luminance efficiency.

A preferable example of the hole injection material includes electron donating hole injection materials (donor materials). These are materials capable of reducing the energy barrier with the anode since the HOMO level is shallower than that of the hole transporting layer and is close to the work function of the anode. Specific examples thereof include group of aromatic amine-based materials, for example, benzidine derivatives, and starburst arylamines such as 4,4′,4″-tris(3-methylphenyl(phenyl)amino)triphenylamine (m-MTDATA) and 4,4′,4″-tris(1-naphthyl(phenyl)amino)triphenylamine (1-TNATA); heterocyclic compounds such as carbazole derivatives, pyrazoline derivatives, stilbene-based compounds, hydrazone-based compounds, benzofuran derivatives, thiophene derivatives, oxadiazole derivatives, phthalocyanine derivatives and porphyrin derivatives; and polymers such as polycarbonate and styrene derivative having the above monomers in the side chain, polythiophenes such as PEDOT/PSS, polyanilines, polyfluorenes, polyvinylcarbazoles and polysilanes. Of these, the benzidine derivatives or the group of starburst arylamine-based materials are more preferably used from the viewpoint that they have a shallower HOMO energy level than that of the compound used for the hole transporting layer and smoothly inject and transport holes from the anode to the hole transporting layer. These materials may be used alone or in combination of two or more types of materials. A plurality of materials may also be laminated to form a hole injection layer.

Another preferable example of the hole injection material includes electron accepting hole injection materials (acceptor materials). Here, the hole injection layer may be composed of the acceptor material alone, or may be used by doping the donor material with the acceptor material. The acceptor material is a material which forms a charge transfer complex with the adjacent hole transporting layer when used alone, or forms a charge transfer complex with the donor material when used by doping the donor material. It is more preferable to use such material since it contributes to an improvement in conductivity of the hole injection layer and reduction in the driving voltage of the element, thus obtaining effects such as an improvement in luminance efficiency and an improvement in durability life. Examples of the acceptor material include metal chlorides such as iron(III) chloride, aluminum chloride, gallium chloride, indium chloride and antimony chloride; metal oxides such as molybdenum oxide, vanadium oxide, tungsten oxide and ruthenium oxide; charge transfer complexes such as tris(4-bromophenyl)aminium hexachloroantimonate (TBPAH); organic compounds having a nitro group, a cyano group, halogen or a trifluoromethyl group in the molecule, such as 1,4,5,8,9,11-hexaazatriphenylene-hexacarbonitrile (HAT-CN6), 2,3,5,6-tetrafluoro-7,7,8,8-tetracyanoquinodimethane (F4-TCNQ), fluorinated copper phthalocyanine, tetracyanoquinodimethane derivatives and radialene derivatives; quinone-based compounds, acid anhydride-based compounds, fullerene, and the like. Of these, metal oxides and cyano group-containing compounds are preferable since it is easy to handle and easy to vaporize so that the above-mentioned effects can be easily obtained, and particularly preferred are 1,4,5,8,9,11-hexaazatriphenylene-hexacarbonitrile (HAT-CN6), or radialene derivatives such as (2E,2′E,2″E)-2,2′,2″-(cyclopropane-1,2,3-triylidene)tris(2-(perfluorophenyl)-acetonitrile) and (2E,2′E,2″E)-2,2′,2″-(cyclopropane-1,2,3-triylidene)tris(2-(4-cyanoperfluorophenyl)-acetonitrile). Whether the hole injection layer is composed of the acceptor compound alone or the hole injection layer is doped with the acceptor compound, the hole injection layer may be a single layer. A plurality of layers may be laminated and configured.

### (Hole Transporting Layer)

The hole transporting layer is a layer which transports holes injected from the anode to the light emitting layer. The hole transporting layer may be a single layer, or a plurality of layers may be laminated to form the structure.

The hole transport layer is formed of the hole transporting material alone, or by laminating or mixing two or more types of hole transport materials. It is preferable that the hole transport material has high hole injection efficiency and efficiently transports the injected holes. For this purpose, the hole transporting material is required to be a substance which has appropriate ionization potential, high hole mobility and excellent stability, and is less likely to generate impurities which become traps.

Examples of the substance satisfying these conditions include, but not particularly limited to, benzidine derivatives; group of aromatic amine-based materials called starburst arylamine; heterocyclic compounds such as carbazole derivatives, pyrazoline derivatives, stilbene-based compounds, hydrazone-based compounds, benzofuran derivatives, dibenzofuran derivatives, thiophene derivatives, benzothiophene derivatives, dibenzothiophene derivatives, fluorene derivatives, spirofluorene derivatives, oxadiazole derivatives, phthalocyanine derivatives and porphyrin derivatives; polymers such as polycarbonate and styrene derivative having the above monomers in the side chain, polythiophenes, polyanilines, polyfluorenes, polyvinylcarbazoles, polysilanes and the like.

The hole transporting layer in embodiments of the present invention also includes an electron blocking layer capable of efficiently blocking the movement of electrons as a synonym. The electron blocking layer is provided between the hole transporting layer and the light emitting layer. The electron blocking layer and the hole transporting layer may be a single layer or may be composed of a plurality of materials laminated.

### (Light Emitting Layer)

The light emitting layer is a layer which emits light by excitation energy generated by the recombination of holes and electrons. The light emitting layer may be composed of a single material, but it is preferable to have a first compound and a second compound which is a dopant exhibiting strong emission from the viewpoint of color purity. Preferred examples of the first compound include a host material responsible for charge transfer and a thermally activated delayed fluorescent material.

It is preferable to use the pyrromethene boron complex represented by the general formula (1) as the second compound which is a dopant of the light emitting layer since it has particularly excellent fluorescence quantum yield, and the half width of the emission spectrum is narrow and high color purity can be achieved. If the doping amount of the second compound is too large, a concentration quenching phenomenon occurs. Therefore, it is preferably used in the amount of 20% by weight or less, more preferably 10% by weight or less, still more preferably 5% by weight or less, and most preferably 2% by weight or less, based on the weight of the entire light emitting layer. If the doping concentration is too low, sufficient energy transfer is unlikely to occur. Therefore, it is preferably used in the amount of 0.1% by weight or more, and more preferably 0.5% by weight or more, based on the weight of the entire light emitting layer.

The light emitting layer may contain a compound other than the first compound and the second compound as the light emitting material (host material or dopant material). Such compounds are referred to as other light emitting materials.

As the host material, a compound may be used alone, or two or more thereof may be mixed and used. Examples of the usable host material include, but are not particularly limited to, compounds having a fused aryl ring, such as naphthacene, pyrene, anthracene and fluoranthene, and derivatives thereof; aromatic amine derivatives such as N,N′-dinaphthyl-N,N′-diphenyl-4,4′-diphenyl-1,1′-diamine; metal chelated oxynoid compounds such as tris(8-quinolinate)aluminum(III); bisstyryl derivatives such as distyrylbenzene derivatives, tetraphenylbutadiene derivatives, indene derivatives, coumarin derivatives, oxadiazole derivatives, pyrrolopyridine derivatives, perinone derivative, pyrrolopyrrole derivatives, thiadiazolopyridine derivatives, dibenzofuran derivative, carbazole derivatives, indolocarbazole derivatives, triazine derivatives, and polymers such as polyphenylene vinylene derivatives, polyparaphenylene derivatives, polyfluorene derivatives, polyvinylcarbazole derivatives and polythiophene derivatives. Particularly preferred as the host material are anthracene derivatives or naphthacene derivatives.

As the dopant material, the pyrromethene boron complex represented by the general formula (1) is preferable, but other fluorescent light emitting materials may be contained. Specific examples of other dopant materials include compounds having a fused aryl ring, such as naphthacene, pyrene, anthracene and fluoranthene, and derivatives thereof; compounds having a heteroaryl ring and derivatives thereof; distyrylbenzene derivatives, aminostyryl derivatives, tetraphenylbutadiene derivatives, stylben derivatives, aldazine derivatives, pyrromethene derivatives, diketopyrrolo[3,4-c]pyrrole derivatives, coumarin derivatives, azole derivatives, and metal complexes thereof, and aromatic amine derivatives.

The phosphorescent light emitting material may be contained as the dopant material. The dopant which exhibits phosphorescent emission is preferably a metal complex compound containing at least one metal selected from the group consisting of iridium (Ir), ruthenium (Ru), palladium (Pd), platinum (Pt), osmium (Os) and rhenium (Re), and more preferably an iridium complex or a platinum complex from the viewpoint of high efficiency emission. The ligand preferably has, but is not limited to, a nitrogen-containing aromatic heteroaryl group such as a phenylpyridine skeleton or a phenylquinoline skeleton or a carbene skeleton.

However, from the viewpoint of enhancing the color purity, the dopant material is preferably composed of one type of the pyrromethene boron complex represented by the general formula (1).

In addition to the above host materials or dopant materials, the light emitting layer may further contain a third component for adjusting the carrier balance in the light emitting layer or stabilizing the layer structure of the light emitting layer. However, it is preferable to select, as the third component, a material which does not cause an interaction between the host material and the dopant material.

Description will be made in detail of the case where a thermally activated delayed fluorescent material is used as the first compound. The thermally activated delayed fluorescent material is also commonly called a TADF material, which is a material in which the energy gap between the energy level of the lowest excited singlet state and the energy level of the lowest excited triplet state is reduced to promote the inverse intersystem crossing from the lowest excited triplet state to the lowest excited singlet state, leading to an improvement in singlet exciton generation probability. The difference between the lowest excited singlet energy level and the lowest excited triplet energy level (referred to as ΔEST) in the TADF material is preferably 0.3 eV or less. With this TADF mechanism, the theoretical internal efficiency can be increased to 100%. Further, when Forster-type energy transfer occurs from the singlet excitons of the thermally activated delayed fluorescent material, which is the first compound, to the singlet excitons of the second compound, fluorescent emission from the singlet excitons of the second compound is observed. In order for such energy transfer to occur, it is preferable that the lowest excited singlet energy level of the first compound is larger than the lowest excited singlet energy level of the second compound. Here, when the second compound is a fluorescent light emitting material having a sharp emission spectrum, a light emitting element having high efficiency and high color purity can be obtained. As mentioned above, when the light emitting layer contains the thermally activated delayed fluorescent material, higher efficiency emission is possible, which contributes to lower power consumption of the display. The thermally activated delayed fluorescent material may be a single material which exhibits thermally activated delayed fluorescence, or may be a plurality of materials that exhibit thermally activated delayed fluorescence, like the case where an exciplex complex is formed.

The thermally activated delayed fluorescent material to be used may be a single material or a plurality of materials after mixing, and known materials can be used. Specific examples thereof include benzonitrile derivatives, triazine derivatives, disulfoxide derivatives, carbazole derivatives, indolocarbazole derivatives, dihydrophenazine derivatives, thiazole derivatives, oxadiazole derivatives and the like. In particular, a compound having an electron donating moiety (donor moiety) and an electron attracting moiety (acceptor moiety) in the same molecule is preferable.

Here, examples of the electron donating moiety (donor moiety) include an aromatic amino group and a Π-electron excess heterocyclic functional group. Specific examples thereof include a diarylamino group, a carbazolyl group, a benzocarbazolyl group, a dibenzocarbazolyl group, an indolocarbazolyl group, a dihydroacrydinyl group, a phenoxadinyl group and a dihydrophenazinyl group. Examples of the electron withdrawing moiety (acceptor moiety) include a phenyl group having an electron withdrawing group as a substituent and a Π-electron deficient heterocyclic functional group. Specific examples thereof include a phenyl group and a triazinyl group having an electron-attracting group selected from a carbonyl group, a sulfonyl group and a cyano group as a substituent. Each of these functional groups may or may not be substituted.

Examples of such thermally activated delayed fluorescent material include, but are not particularly limited to, the following examples.

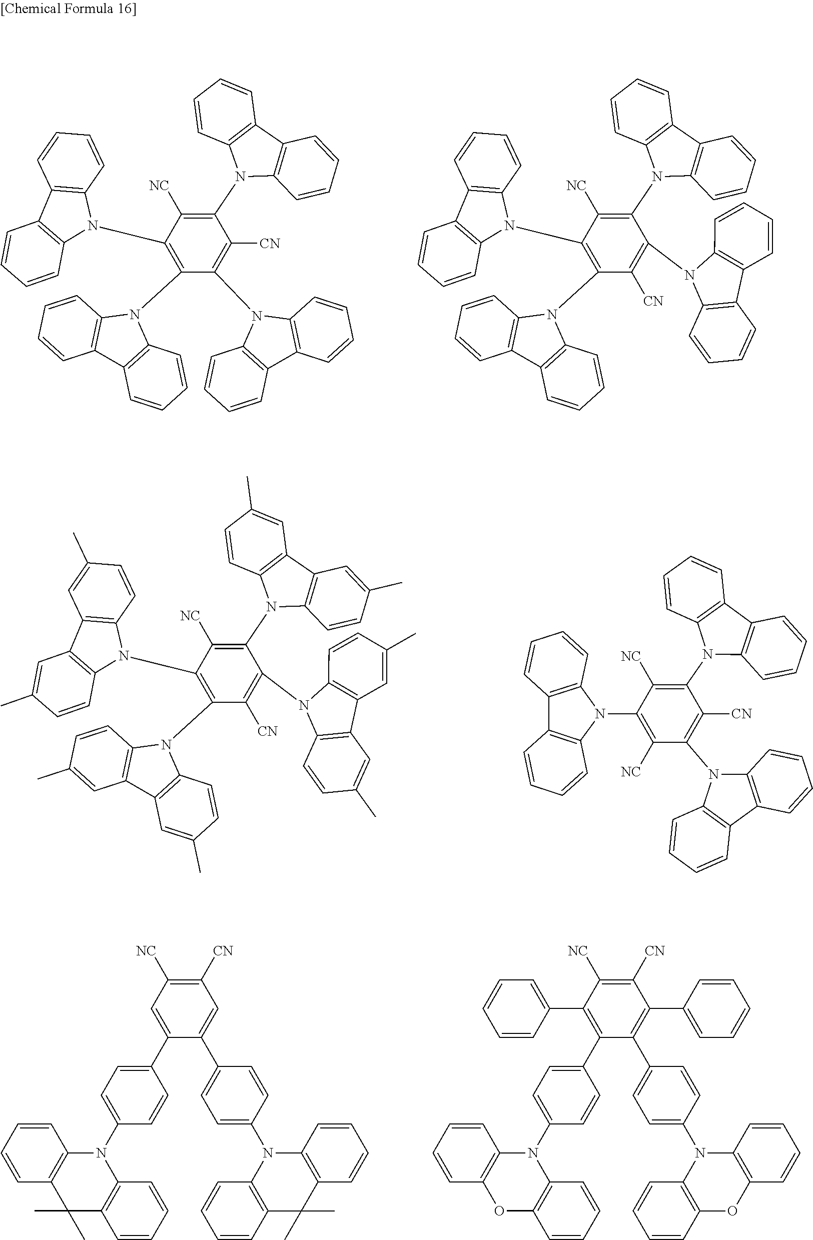

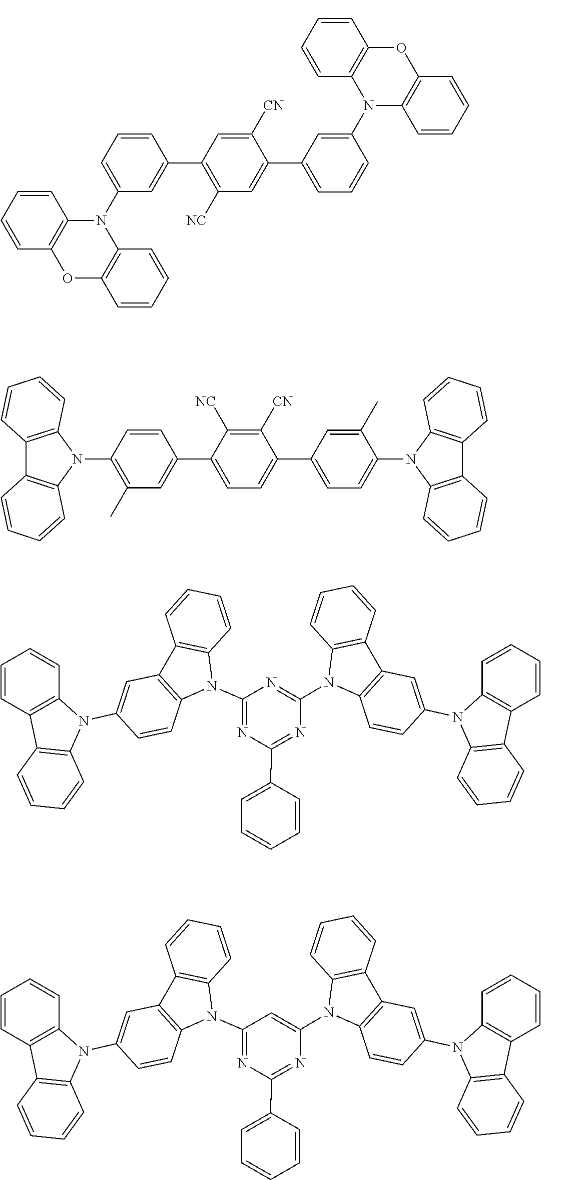 [SMILES: N#Cc1cc(-c2cccc(N3c4ccccc4Oc4ccccc43)c2)c(C#N)cc1-c1cccc(N2c3ccccc3Oc3ccccc32)c1 ; Cc1cc(-c2ccc(-c3ccc(-n4c5ccccc5c5ccccc54)c(C)c3)c(C#N)c2C#N)ccc1-n1c2ccccc2c2ccccc21 ; c1ccc(-c2nc(-n3c4ccccc4c4cc(-n5c6ccccc6c6ccccc65)ccc43)nc(-n3c4ccccc4c4cc(-n5c6ccccc6c6ccccc65)ccc43)n2)cc1 ; c1ccc(-c2nc(-n3c4ccccc4c4cc(-n5c6ccccc6c6ccccc65)ccc43)cc(-n3c4ccccc4c4cc(-n5c6ccccc6c6ccccc65)ccc43)n2)cc1]

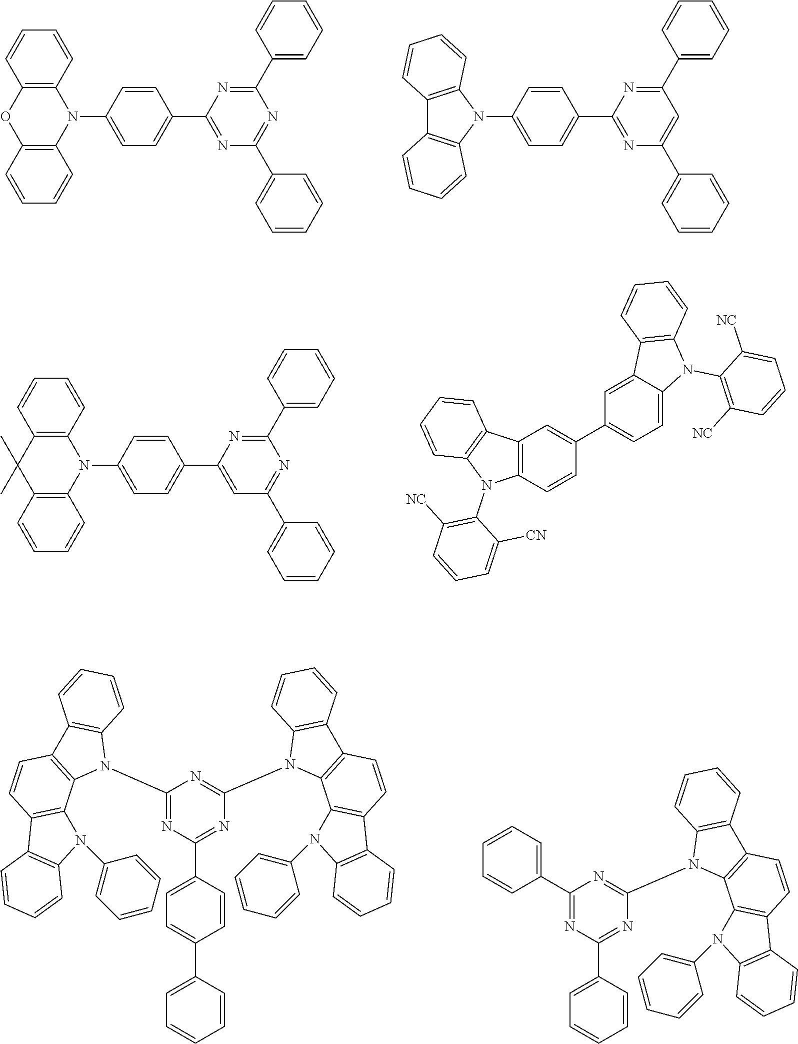 [SMILES: c1ccc(-c2nc(-c3ccccc3)nc(-c3ccc(N4c5ccccc5Oc5ccccc54)cc3)n2)cc1 ; c1ccc(-c2cc(-c3ccccc3)nc(-c3ccc(-n4c5ccccc5c5ccccc54)cc3)n2)cc1 ; CC1(C)c2ccccc2N(c2ccc(-c3cc(-c4ccccc4)nc(-c4ccccc4)n3)cc2)c2ccccc21 ; N#Cc1cccc(C#N)c1-n1c2ccccc2c2cc(-c3ccc4c(c3)c3ccccc3n4-c3c(C#N)cccc3C#N)ccc21 ; c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(-c2nc(-c3ccccc3)nc(-n3c4ccccc4c4ccc5c6ccccc6n(-c6ccccc6)c5c43)n2)cc1]

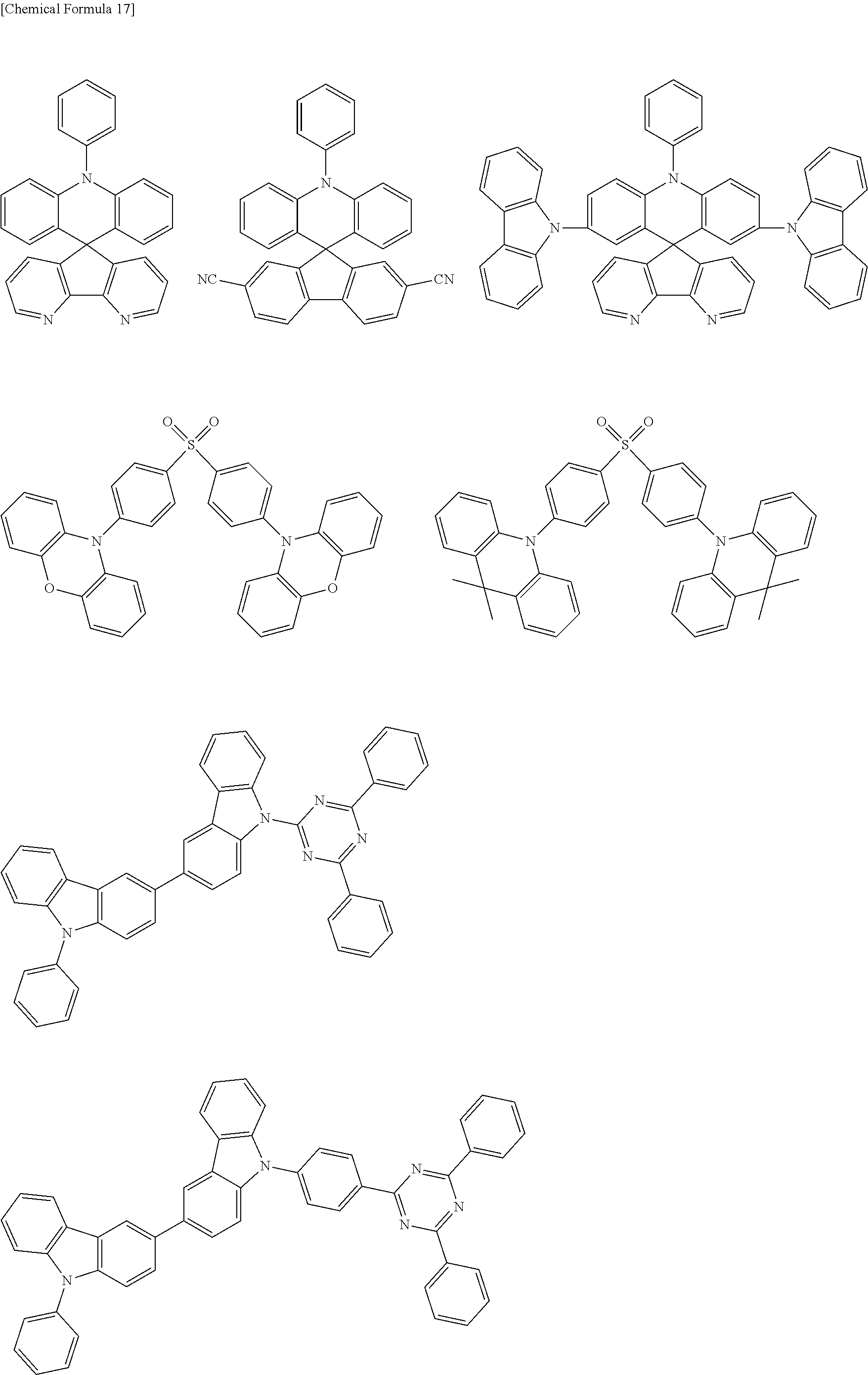

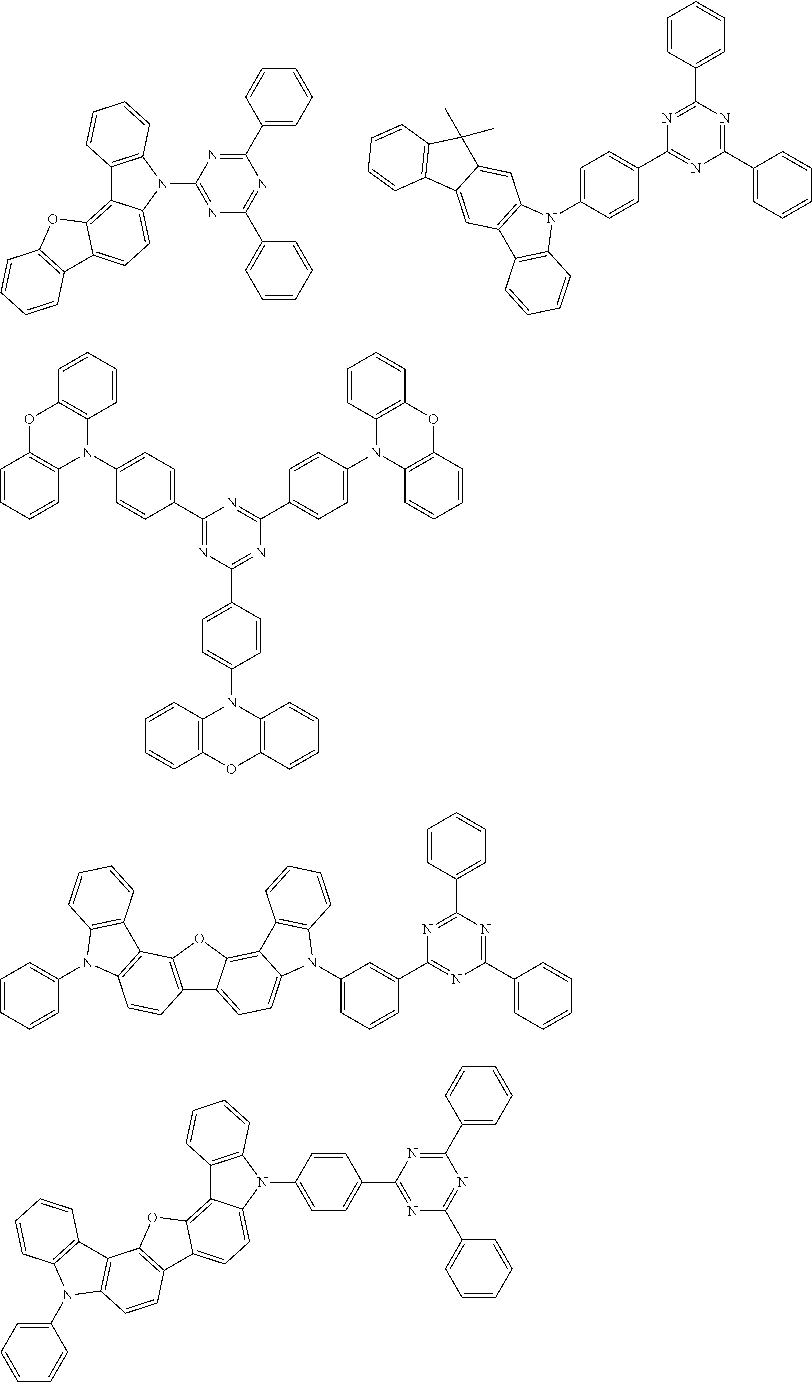 [SMILES: c1ccc(-c2nc(-c3ccccc3)nc(-n3c4ccccc4c4c5oc6ccccc6c5ccc43)n2)cc1 ; CC1(C)c2ccccc2-c2cc3c4ccccc4n(-c4ccc(-c5nc(-c6ccccc6)nc(-c6ccccc6)n5)cc4)c3cc21 ; c1ccc2c(c1)Oc1ccccc1N2c1ccc(-c2nc(-c3ccc(N4c5ccccc5Oc5ccccc54)cc3)nc(-c3ccc(N4c5ccccc5Oc5ccccc54)cc3)n2)cc1 ; c1ccc(-c2nc(-c3ccccc3)nc(-c3cccc(-n4c5ccccc5c5c6oc7c(ccc8c7c7ccccc7n8-c7ccccc7)c6ccc54)c3)n2)cc1 ; c1ccc(-c2nc(-c3ccccc3)nc(-c3ccc(-n4c5ccccc5c5c6oc7c(ccc8c7c7ccccc7n8-c7ccccc7)c6ccc54)cc3)n2)cc1]

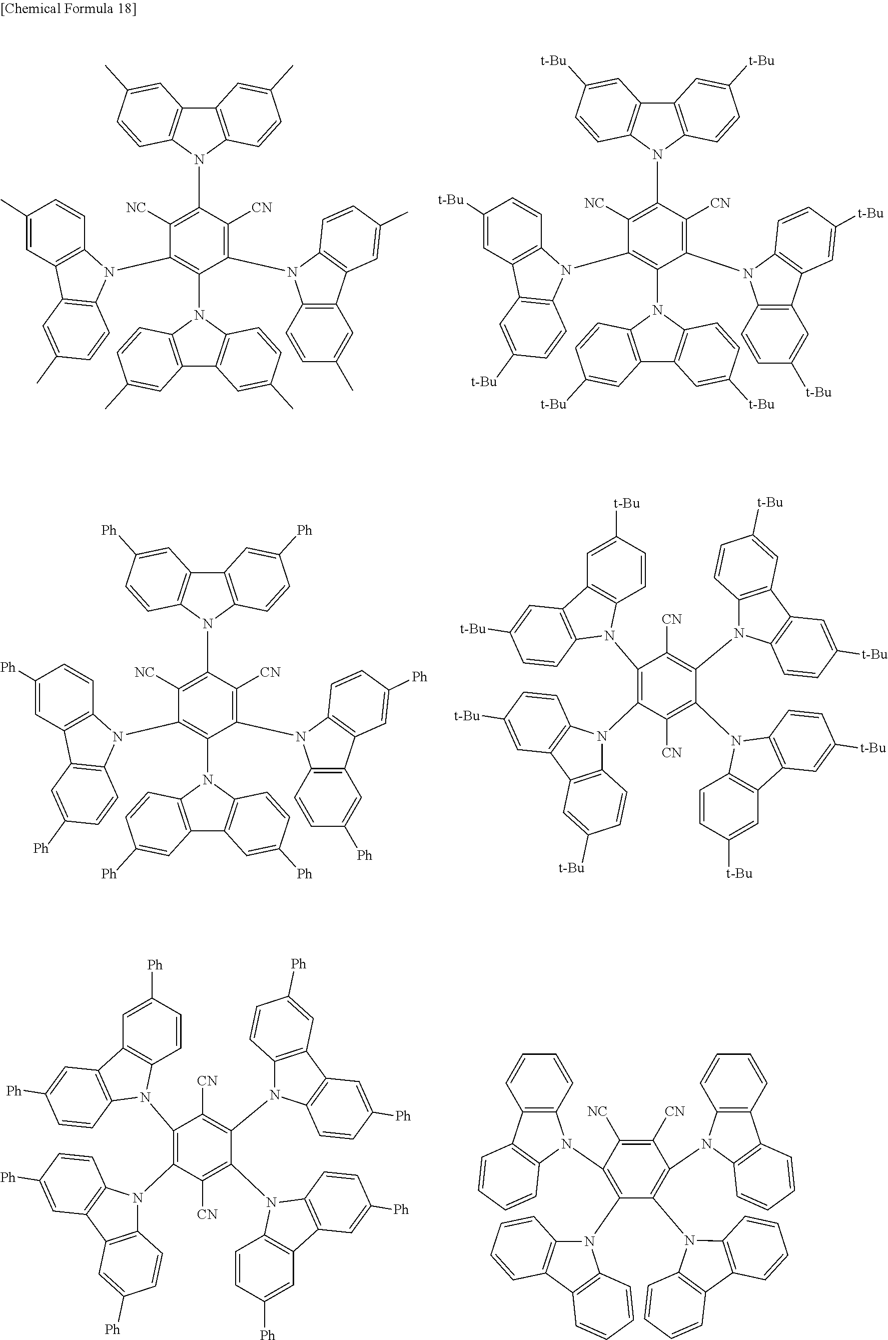

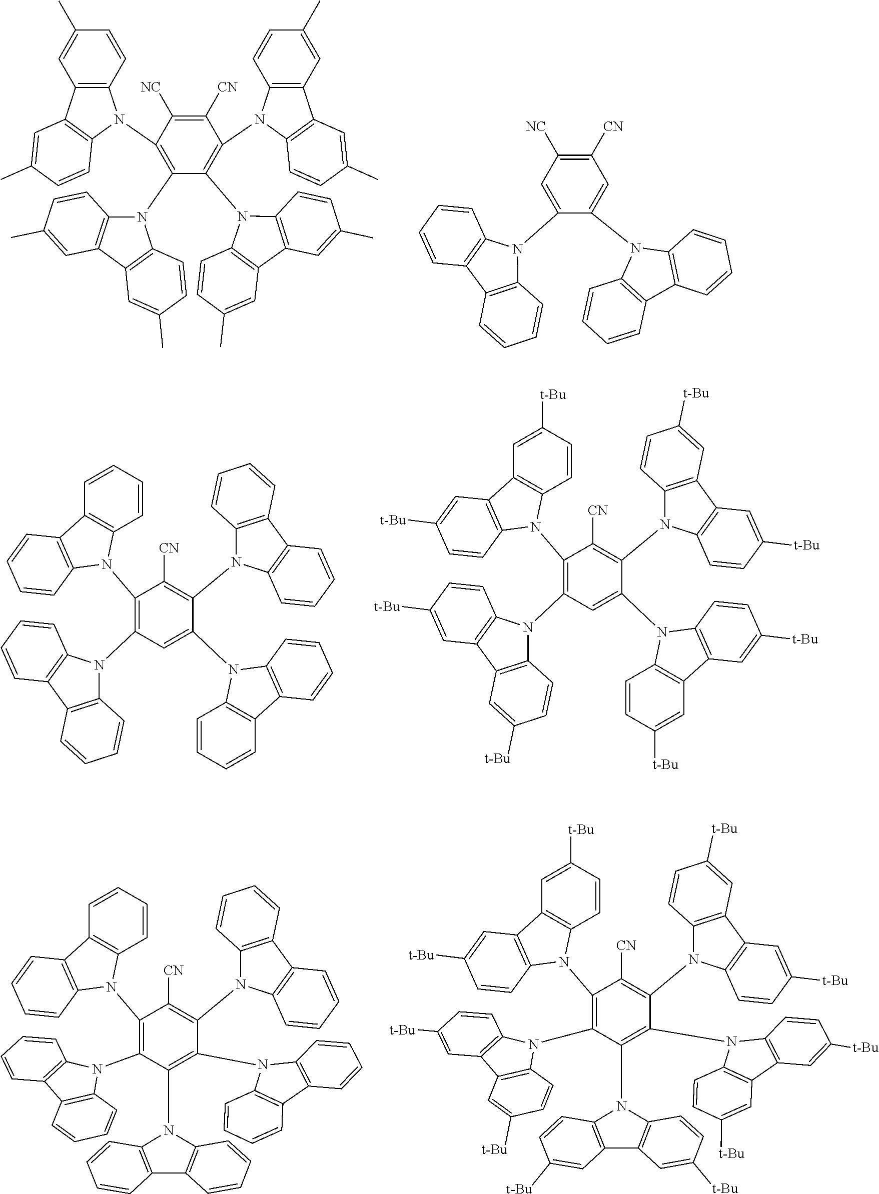

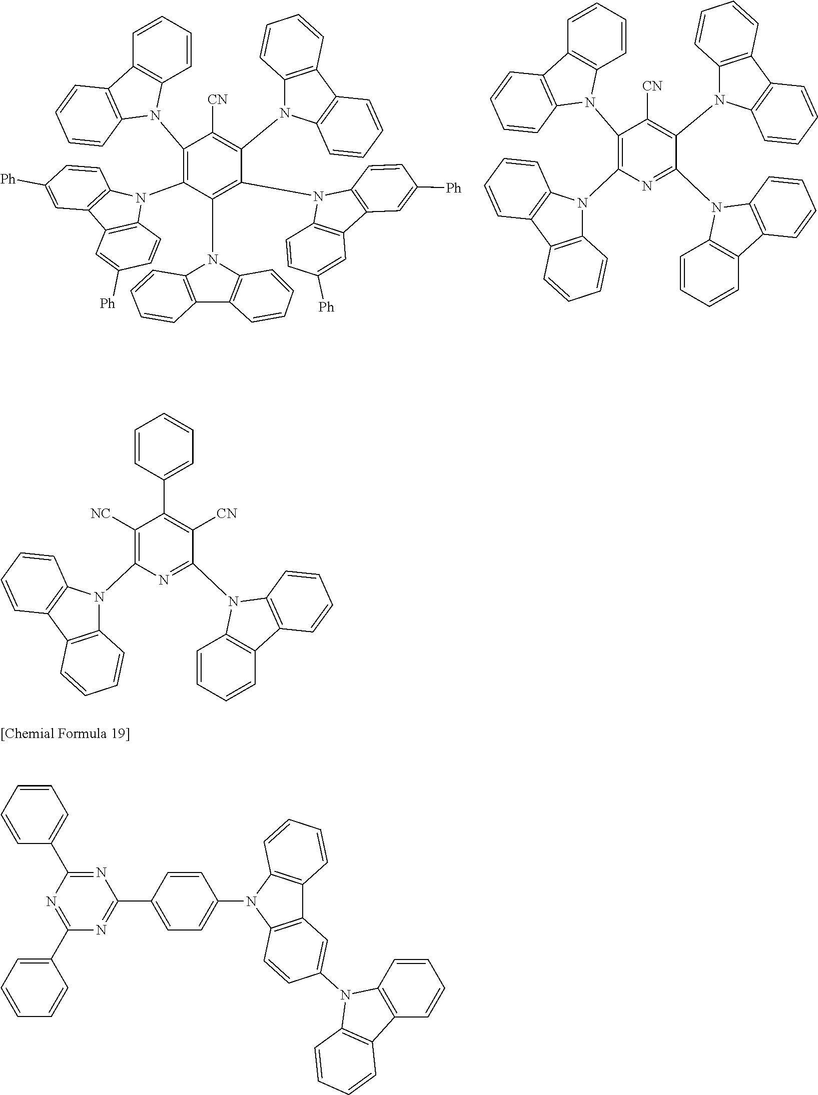

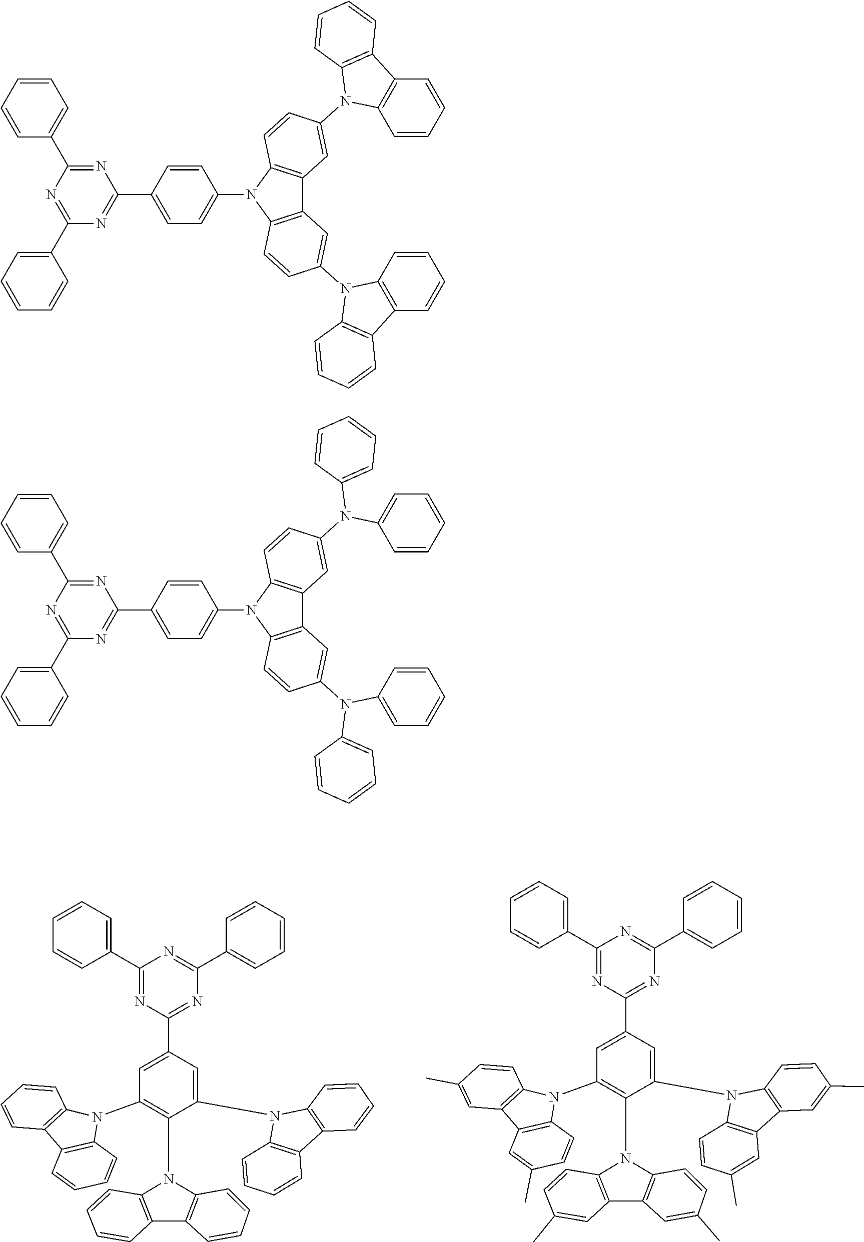

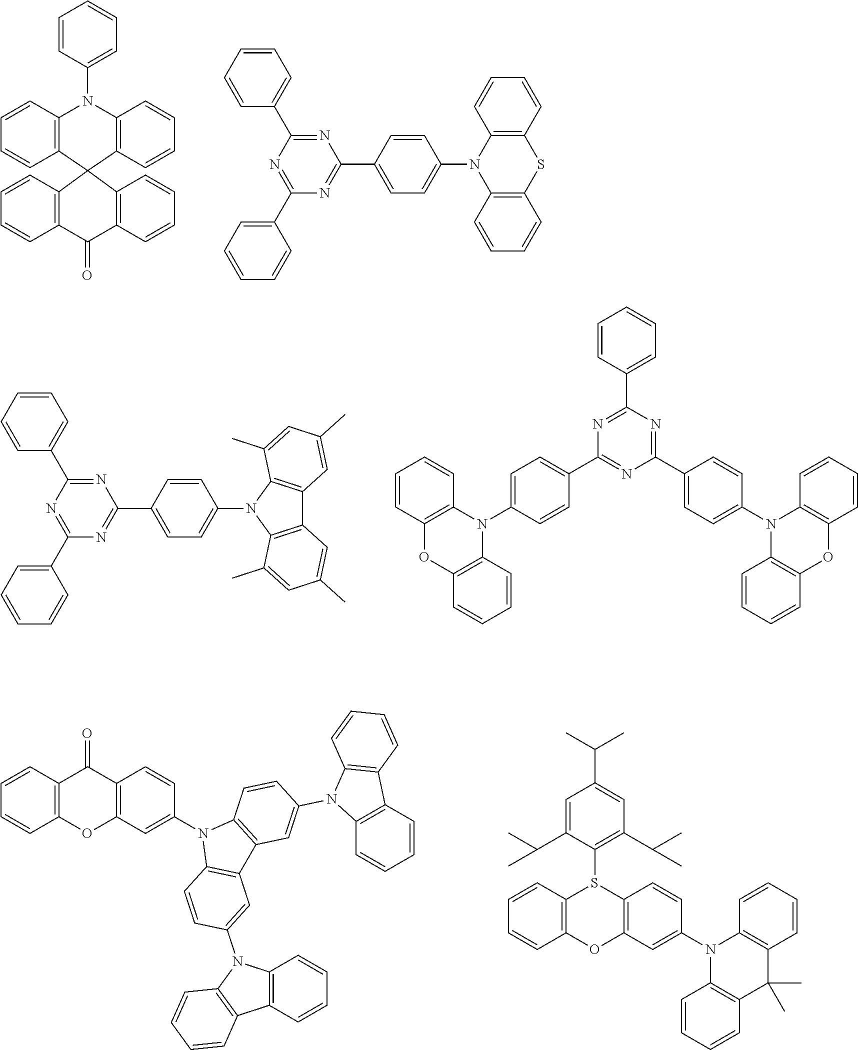

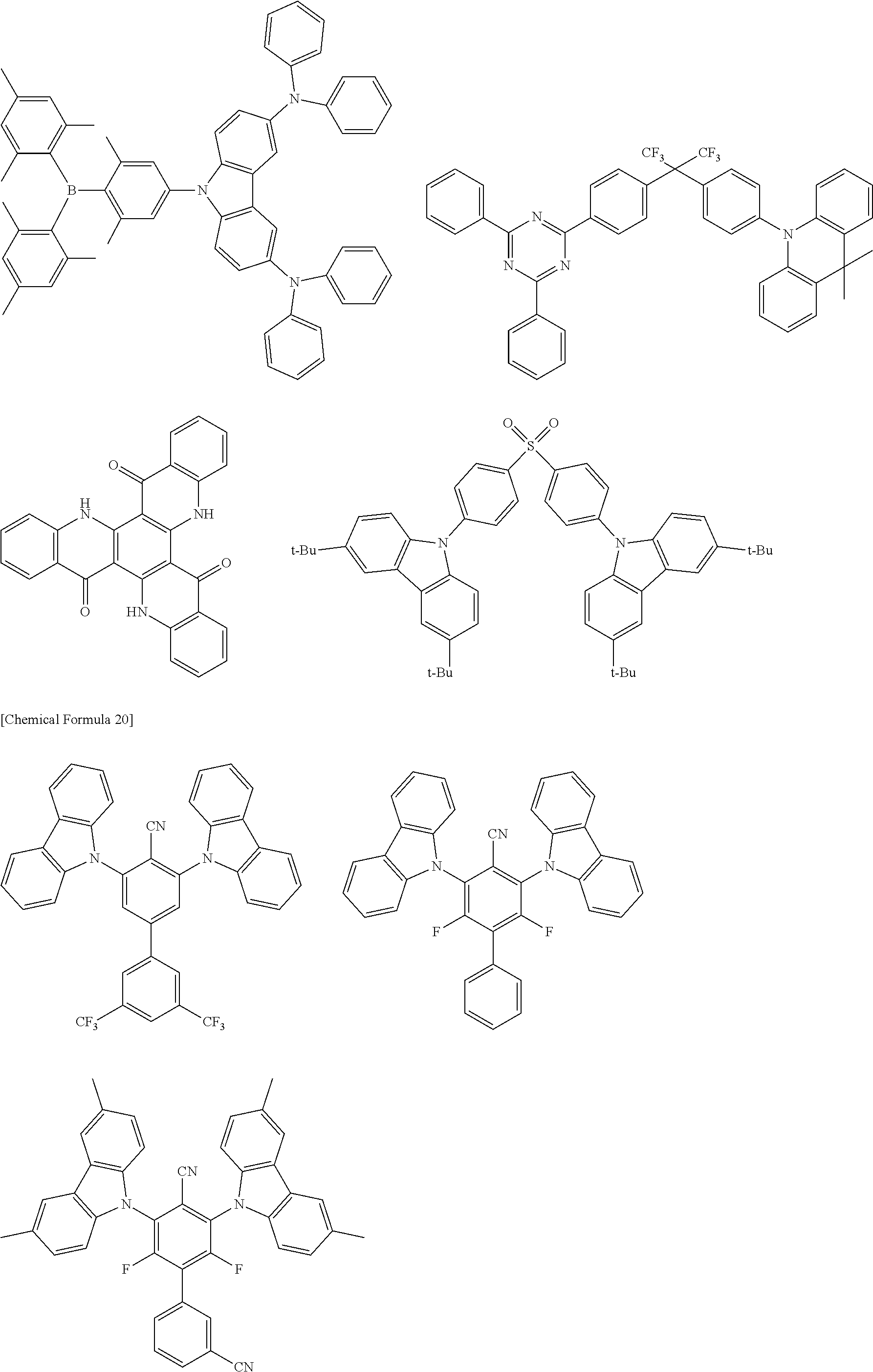

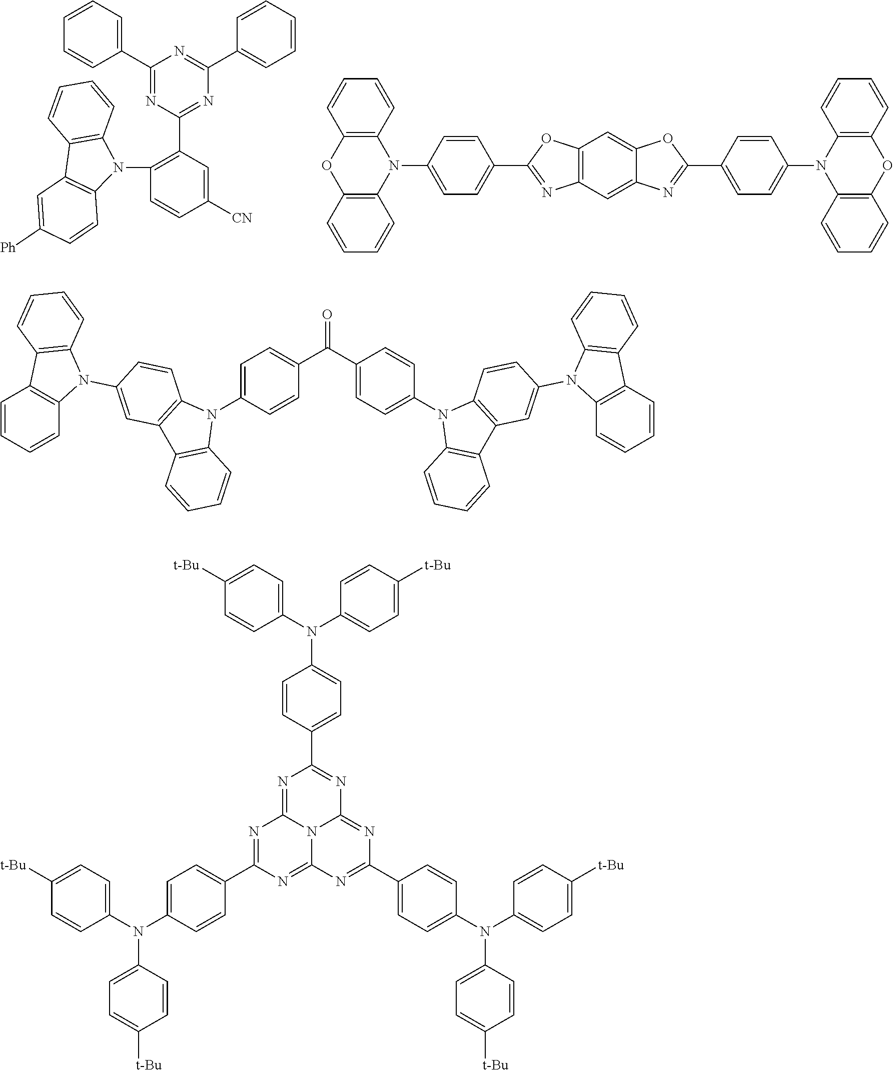 [SMILES: N#Cc1ccc(-n2c3ccccc3c3cc(-c4ccccc4)ccc32)c(-c2nc(-c3ccccc3)nc(-c3ccccc3)n2)c1 ; c1ccc2c(c1)Oc1ccccc1N2c1ccc(-c2nc3cc4nc(-c5ccc(N6c7ccccc7Oc7ccccc76)cc5)oc4cc3o2)cc1 ; O=C(c1ccc(-n2c3ccccc3c3cc(-n4c5ccccc5c5ccccc54)ccc32)cc1)c1ccc(-n2c3ccccc3c3cc(-n4c5ccccc5c5ccccc54)ccc32)cc1 ; CC(C)(C)c1ccc(N(c2ccc(C3=NC4=NC(c5ccc(N(c6ccc(C(C)(C)C)cc6)c6ccc(C(C)(C)C)cc6)cc5)=NC5=NC(c6ccc(N(c7ccc(C(C)(C)C)cc7)c7ccc(C(C)(C)C)cc7)cc6)=NC(=N3)N45)cc2)c2ccc(C(C)(C)C)cc2)cc1]

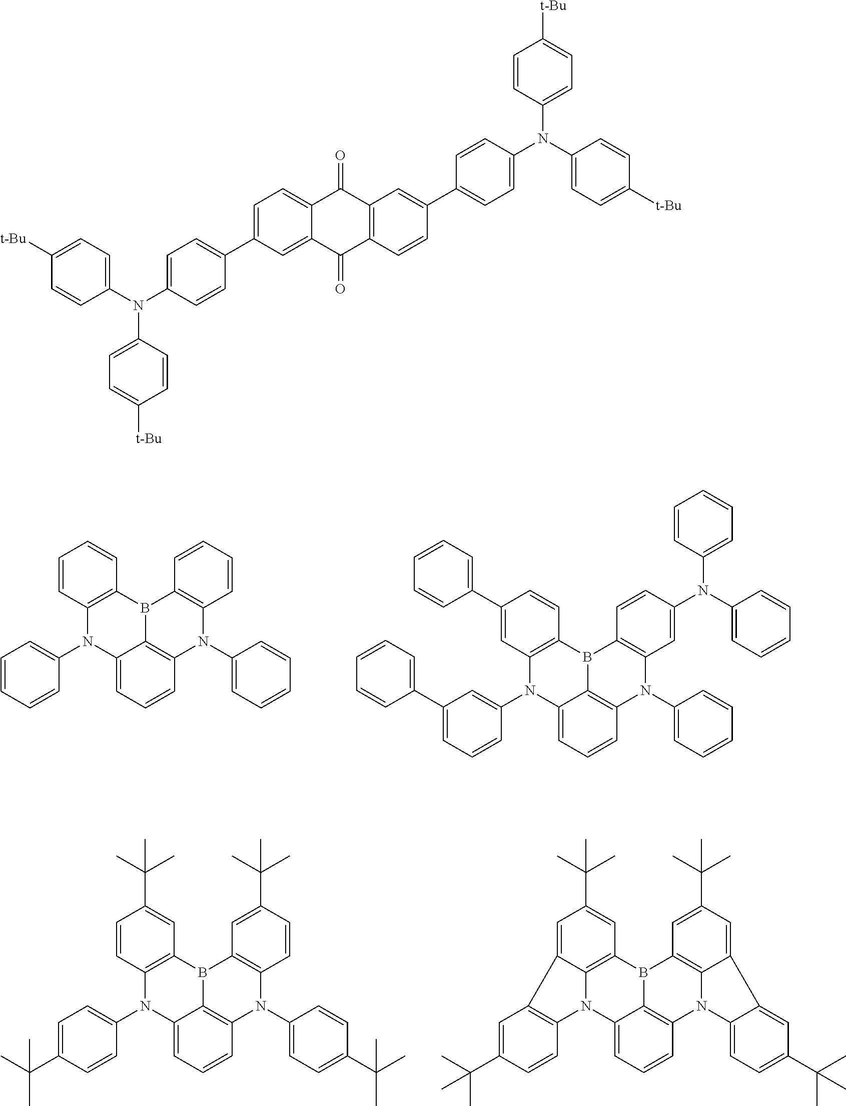

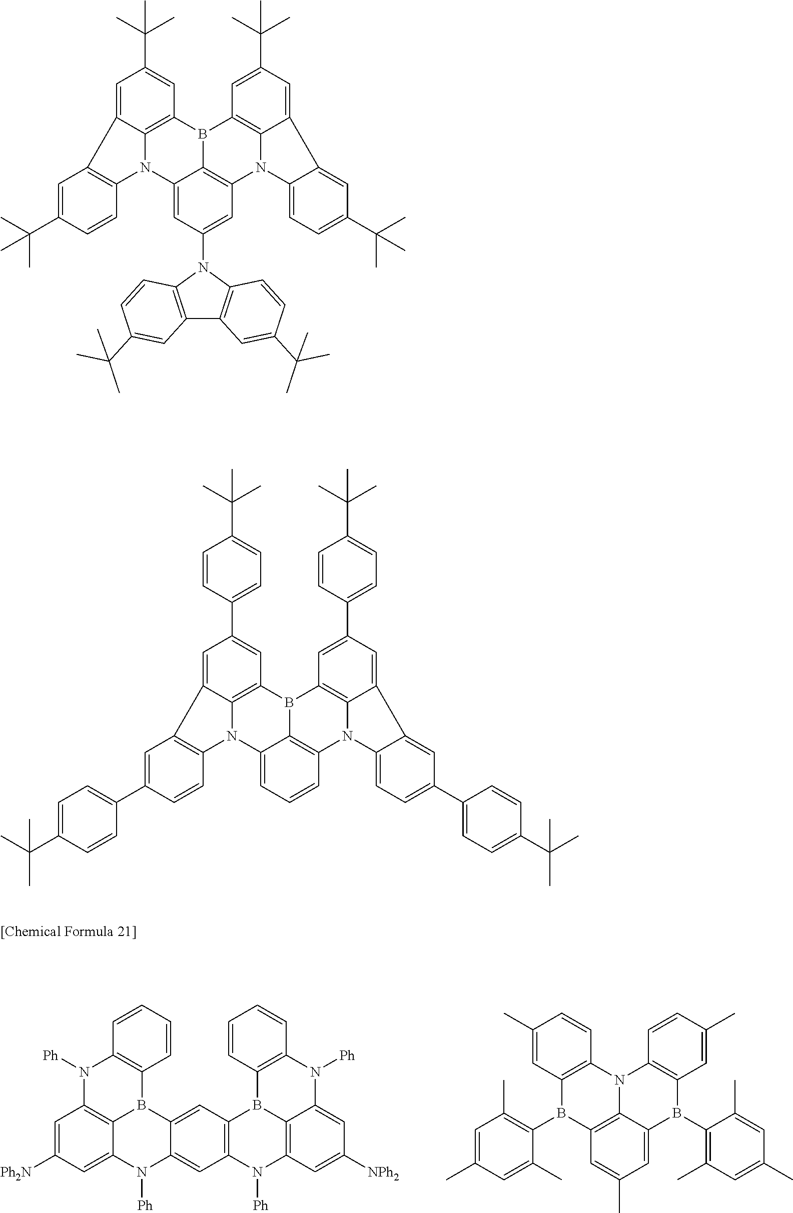

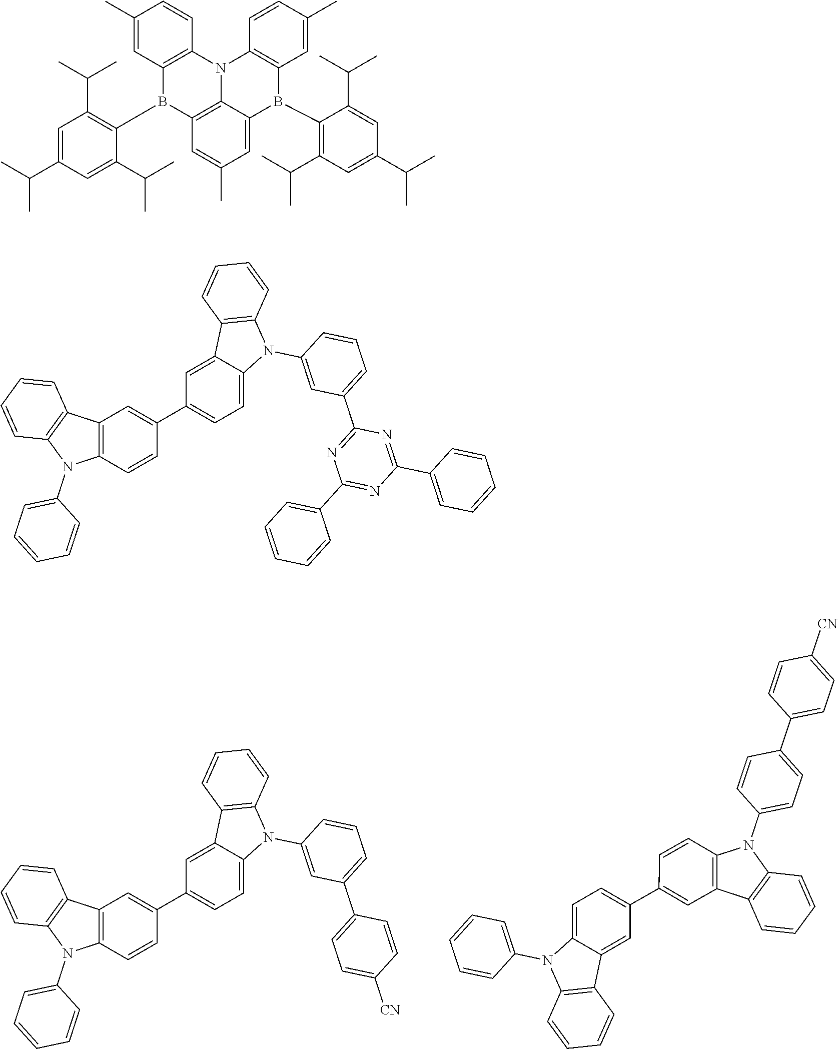 [SMILES: Cc1ccc2c(c1)B(c1c(C(C)C)cc(C(C)C)cc1C(C)C)c1cc(C)cc3c1N2c1ccc(C)cc1B3c1c(C(C)C)cc(C(C)C)cc1C(C)C ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1 ; N#Cc1ccc(-c2cccc(-n3c4ccccc4c4cc(-c5ccc6c(c5)c5ccccc5n6-c5ccccc5)ccc43)c2)cc1 ; N#Cc1ccc(-c2ccc(-n3c4ccccc4c4cc(-c5ccc6c(c5)c5ccccc5n6-c5ccccc5)ccc43)cc2)cc1]

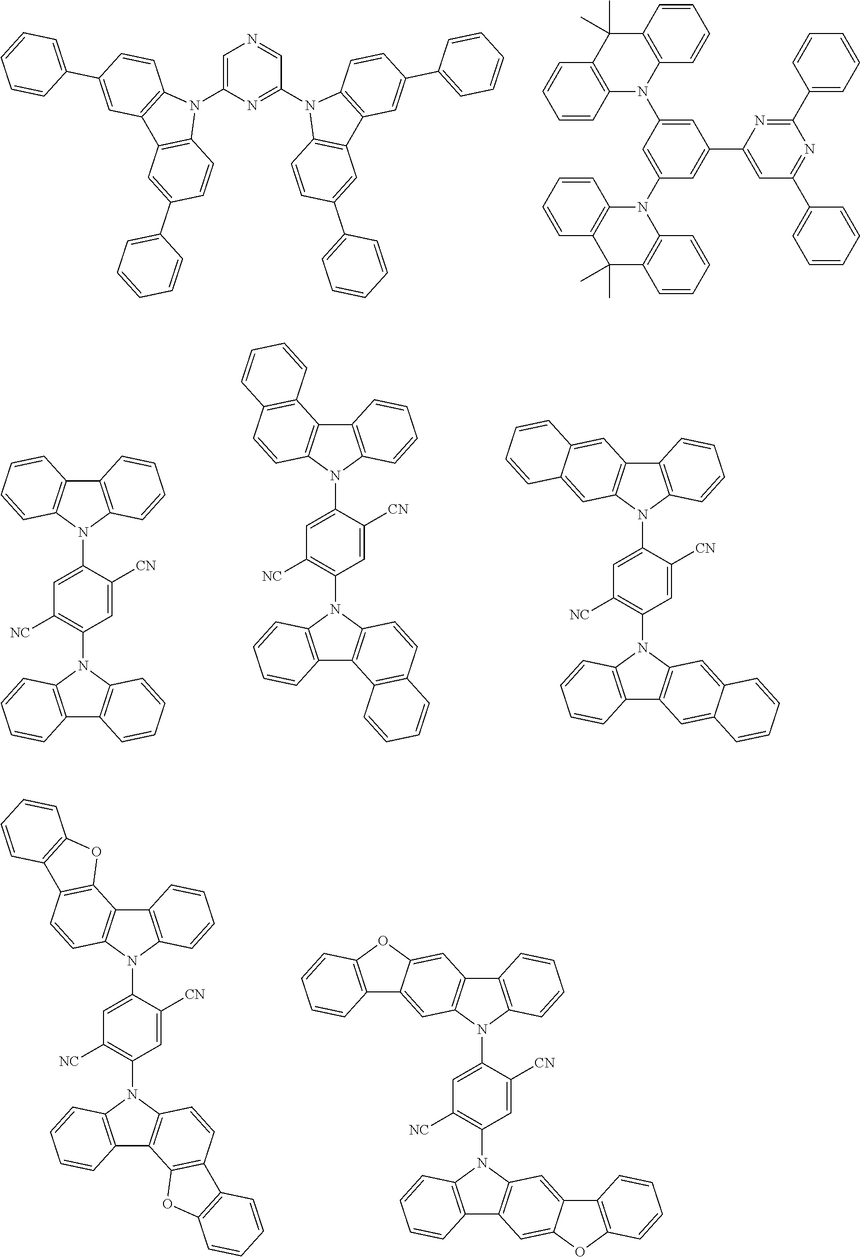

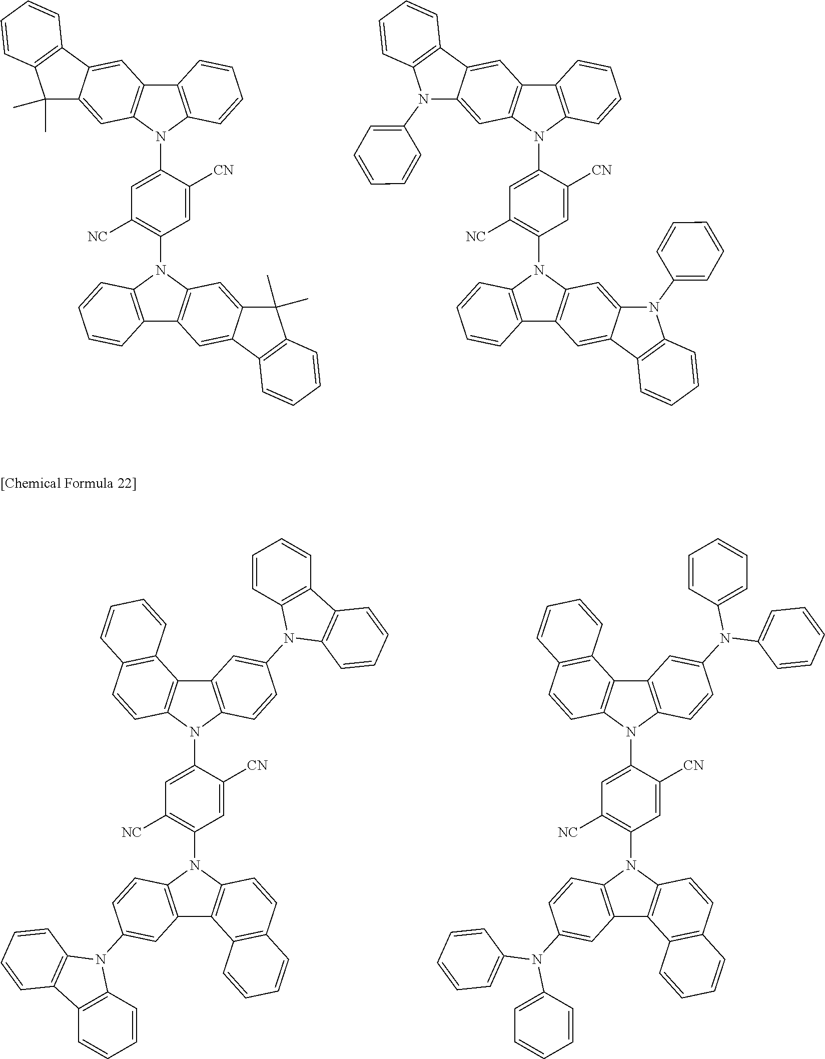 [SMILES: CC1(C)c2ccccc2-c2cc3c4ccccc4n(-c4cc(C#N)c(-n5c6ccccc6c6cc7c(cc65)C(C)(C)c5ccccc5-7)cc4C#N)c3cc21 ; N#Cc1cc(-n2c3ccccc3c3cc4c5ccccc5n(-c5ccccc5)c4cc32)c(C#N)cc1-n1c2ccccc2c2cc3c4ccccc4n(-c4ccccc4)c3cc21 ; N#Cc1cc(-n2c3ccc(-n4c5ccccc5c5ccccc54)cc3c3c4ccccc4ccc32)c(C#N)cc1-n1c2ccc(-n3c4ccccc4c4ccccc43)cc2c2c3ccccc3ccc21 ; N#Cc1cc(-n2c3ccc(N(c4ccccc4)c4ccccc4)cc3c3c4ccccc4ccc32)c(C#N)cc1-n1c2ccc(N(c3ccccc3)c3ccccc3)cc2c2c3ccccc3ccc21]

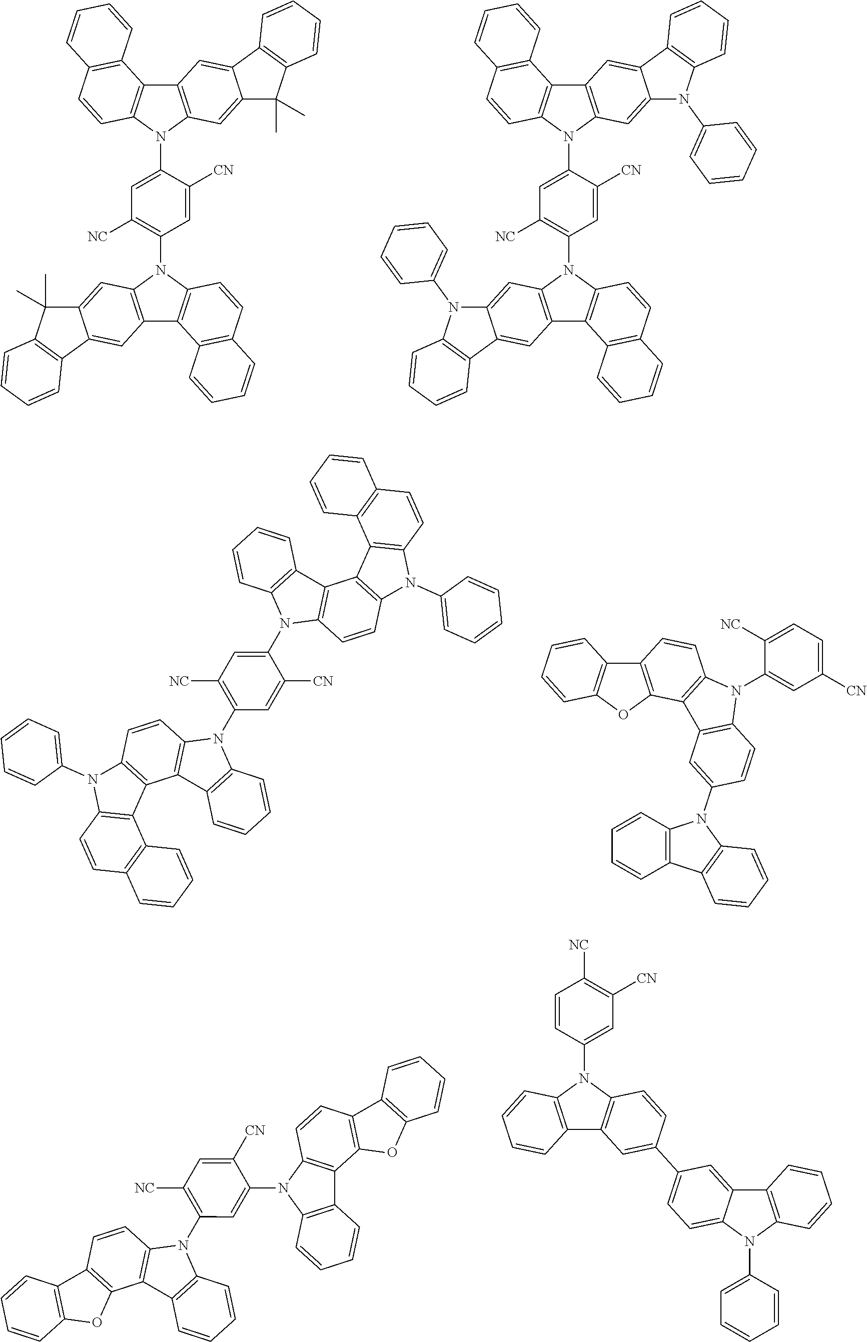

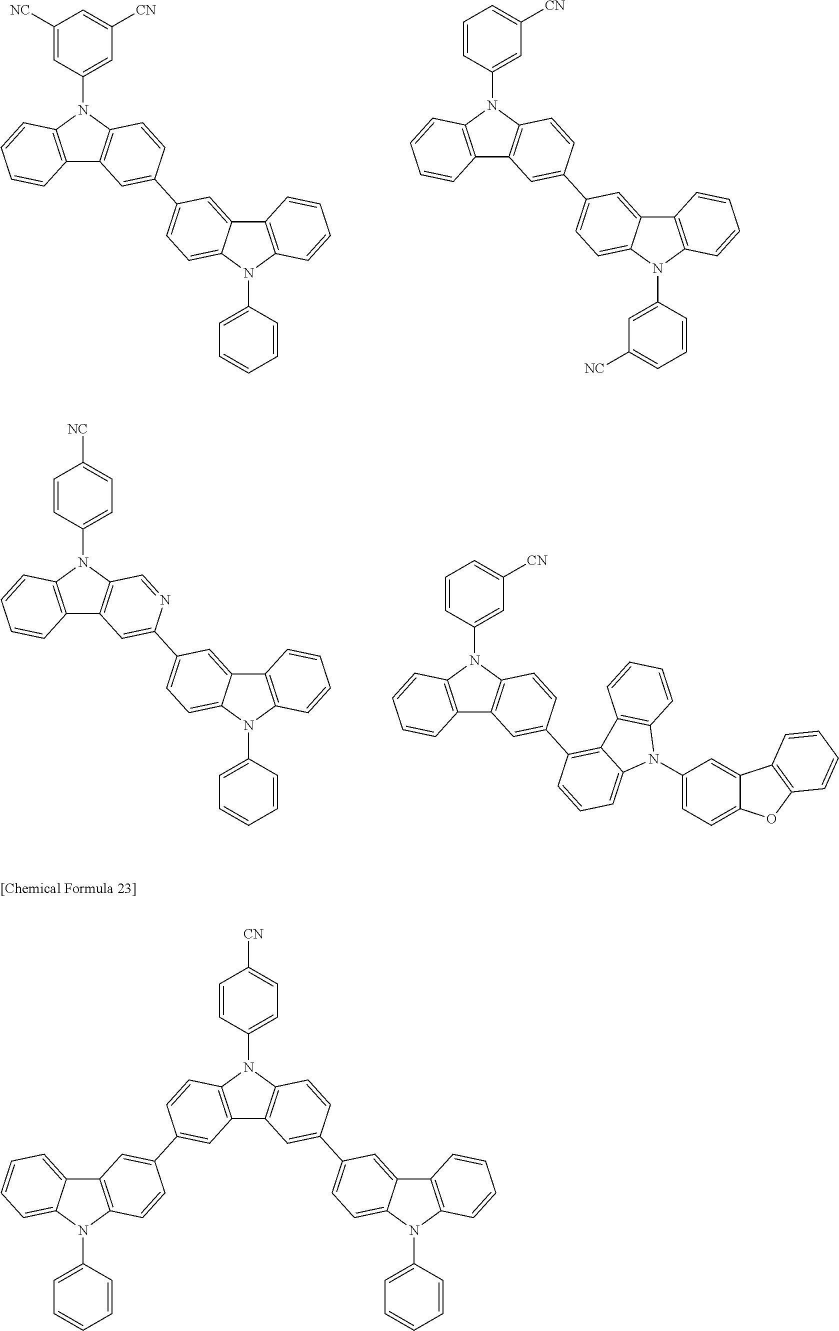 [SMILES: N#Cc1cc(C#N)cc(-n2c3ccccc3c3cc(-c4ccc5c(c4)c4ccccc4n5-c4ccccc4)ccc32)c1 ; N#Cc1cccc(-n2c3ccccc3c3cc(-c4ccc5c(c4)c4ccccc4n5-c4cccc(C#N)c4)ccc32)c1 ; N#Cc1ccc(-n2c3ccccc3c3cc(-c4ccc5c(c4)c4ccccc4n5-c4ccccc4)ncc32)cc1 ; N#Cc1cccc(-n2c3ccccc3c3cc(-c4cccc5c4c4ccccc4n5-c4ccc5oc6ccccc6c5c4)ccc32)c1 ; N#Cc1ccc(-n2c3ccc(-c4ccc5c(c4)c4ccccc4n5-c4ccccc4)cc3c3cc(-c4ccc5c(c4)c4ccccc4n5-c4ccccc4)ccc32)cc1]

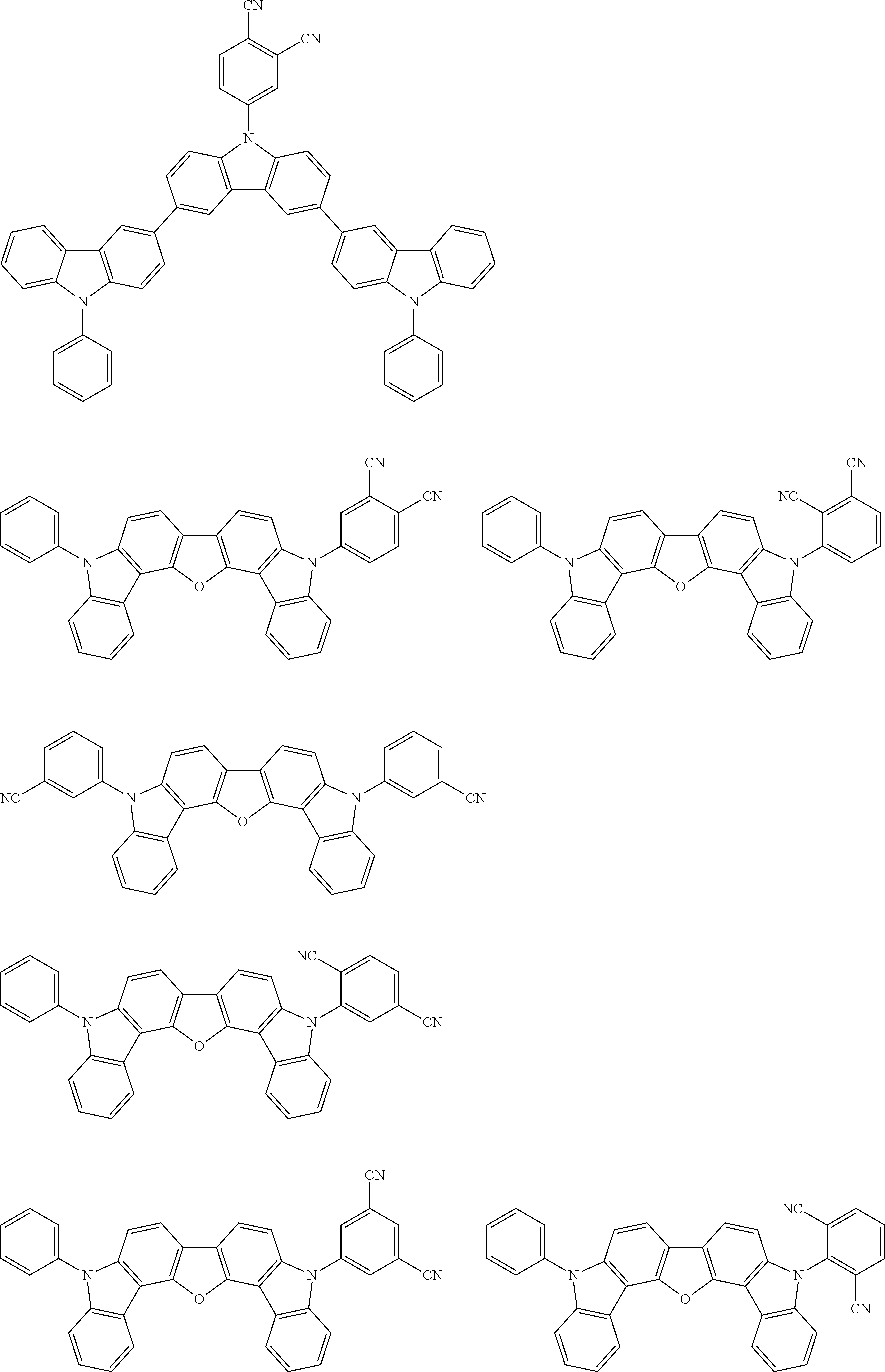

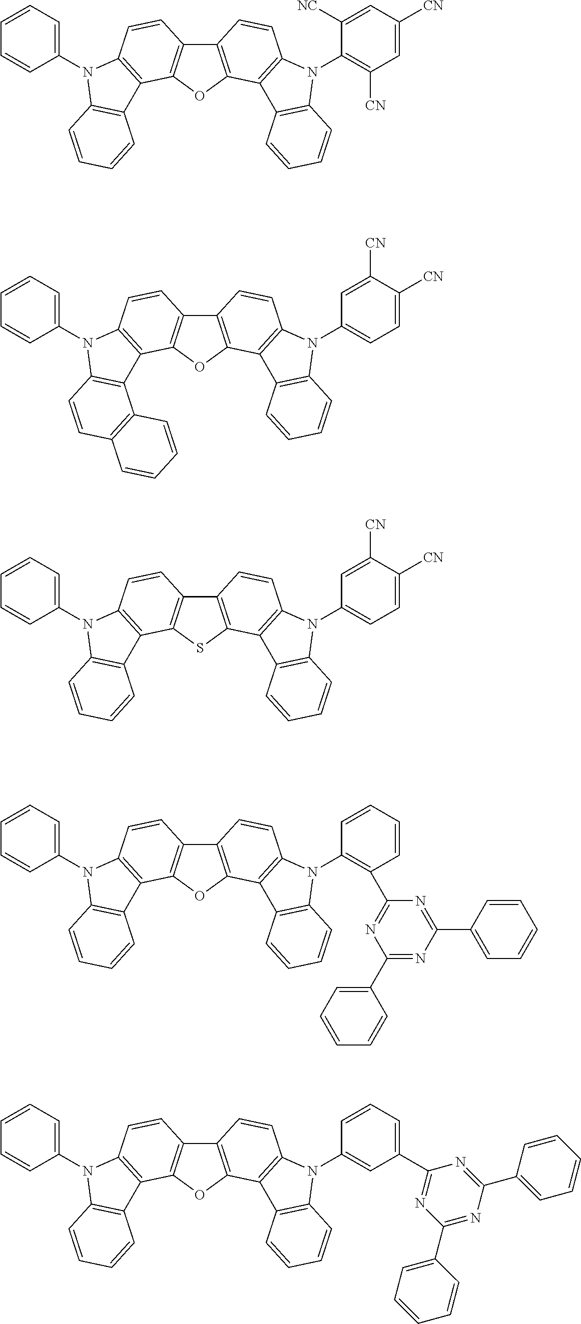 [SMILES: N#Cc1cc(C#N)c(-n2c3ccccc3c3c4oc5c(ccc6c5c5ccccc5n6-c5ccccc5)c4ccc32)c(C#N)c1 ; N#Cc1ccc(-n2c3ccccc3c3c4oc5c(ccc6c5c5c7ccccc7ccc5n6-c5ccccc5)c4ccc32)cc1C#N ; N#Cc1ccc(-n2c3ccccc3c3c4sc5c(ccc6c5c5ccccc5n6-c5ccccc5)c4ccc32)cc1C#N ; c1ccc(-c2nc(-c3ccccc3)nc(-c3ccccc3-n3c4ccccc4c4c5oc6c(ccc7c6c6ccccc6n7-c6ccccc6)c5ccc43)n2)cc1 ; c1ccc(-c2nc(-c3ccccc3)nc(-c3cccc(-n4c5ccccc5c5c6oc7c(ccc8c7c7ccccc7n8-c7ccccc7)c6ccc54)c3)n2)cc1]

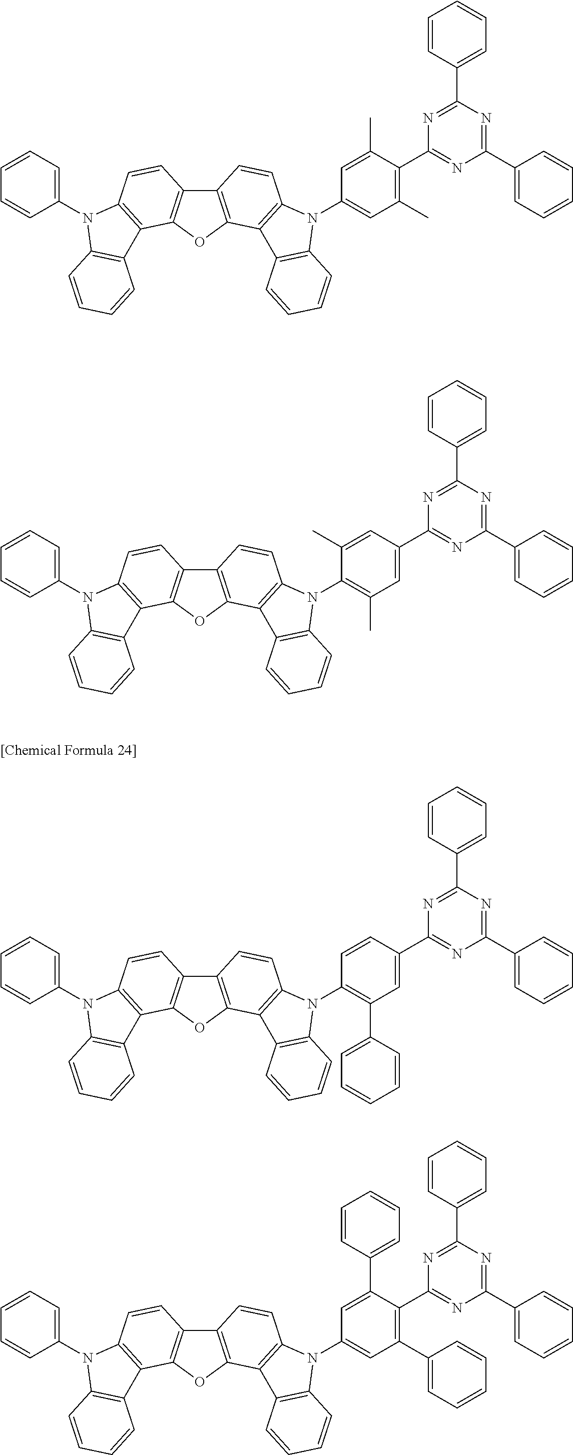 [SMILES: Cc1cc(-n2c3ccccc3c3c4oc5c(ccc6c5c5ccccc5n6-c5ccccc5)c4ccc32)cc(C)c1-c1nc(-c2ccccc2)nc(-c2ccccc2)n1 ; Cc1cc(-c2nc(-c3ccccc3)nc(-c3ccccc3)n2)cc(C)c1-n1c2ccccc2c2c3oc4c(ccc5c4c4ccccc4n5-c4ccccc4)c3ccc21 ; c1ccc(-c2nc(-c3ccccc3)nc(-c3ccc(-n4c5ccccc5c5c6oc7c(ccc8c7c7ccccc7n8-c7ccccc7)c6ccc54)c(-c4ccccc4)c3)n2)cc1 ; c1ccc(-c2nc(-c3ccccc3)nc(-c3c(-c4ccccc4)cc(-n4c5ccccc5c5c6oc7c(ccc8c7c7ccccc7n8-c7ccccc7)c6ccc54)cc3-c3ccccc3)n2)cc1]

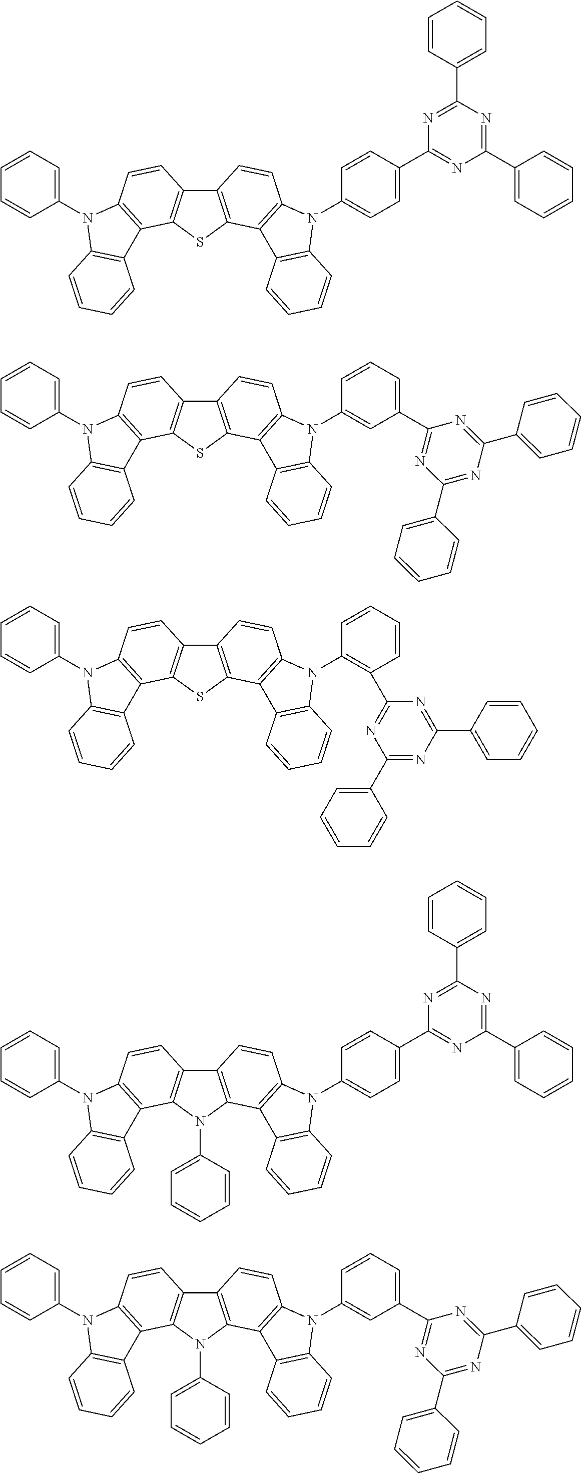

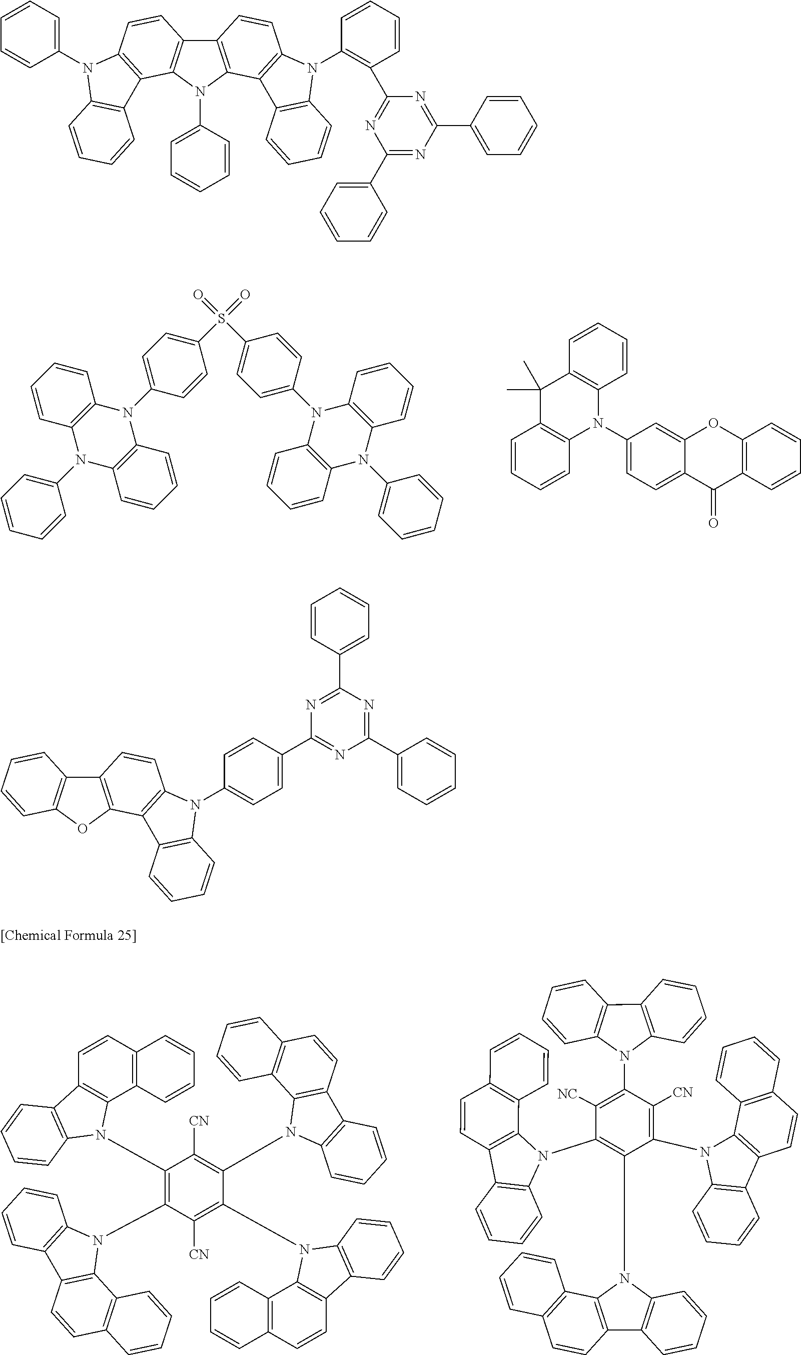

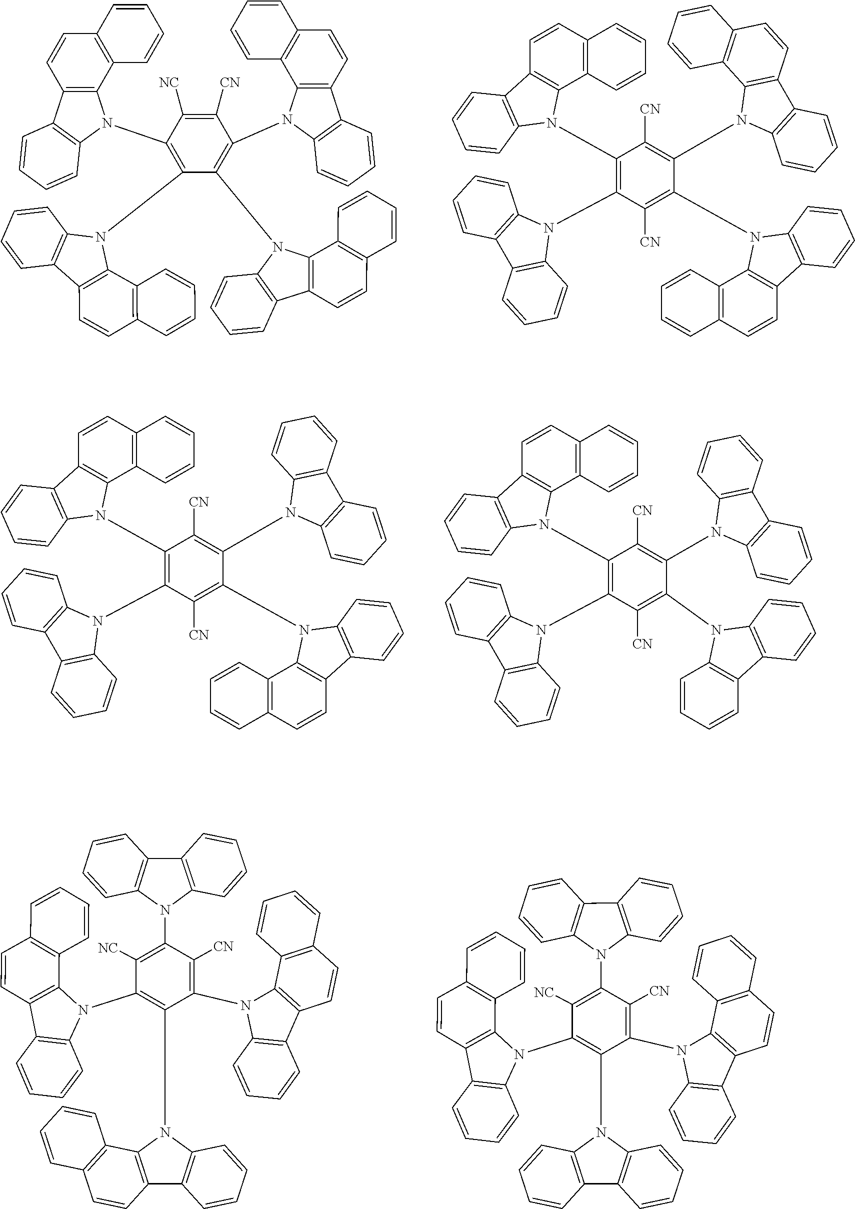

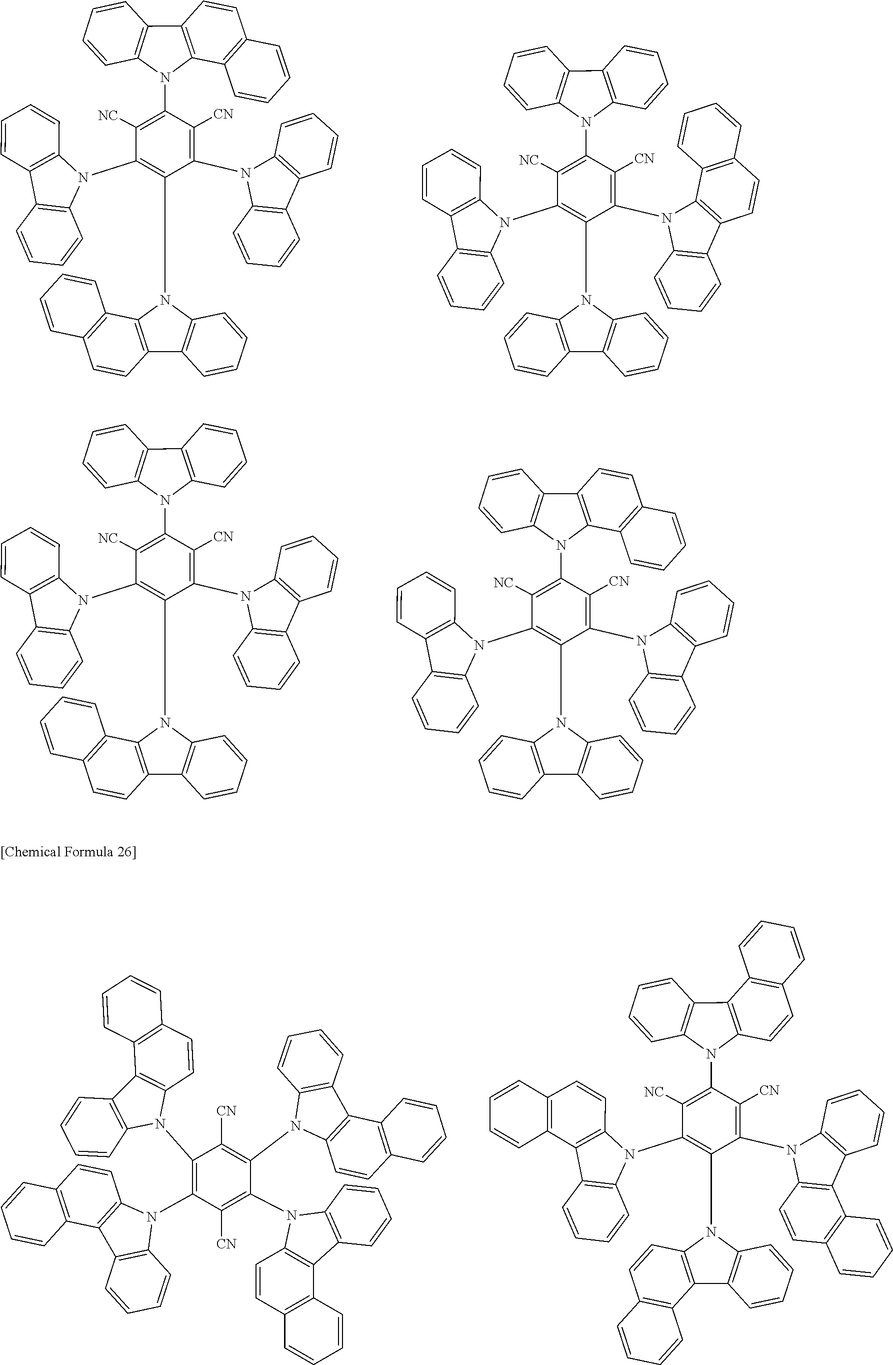

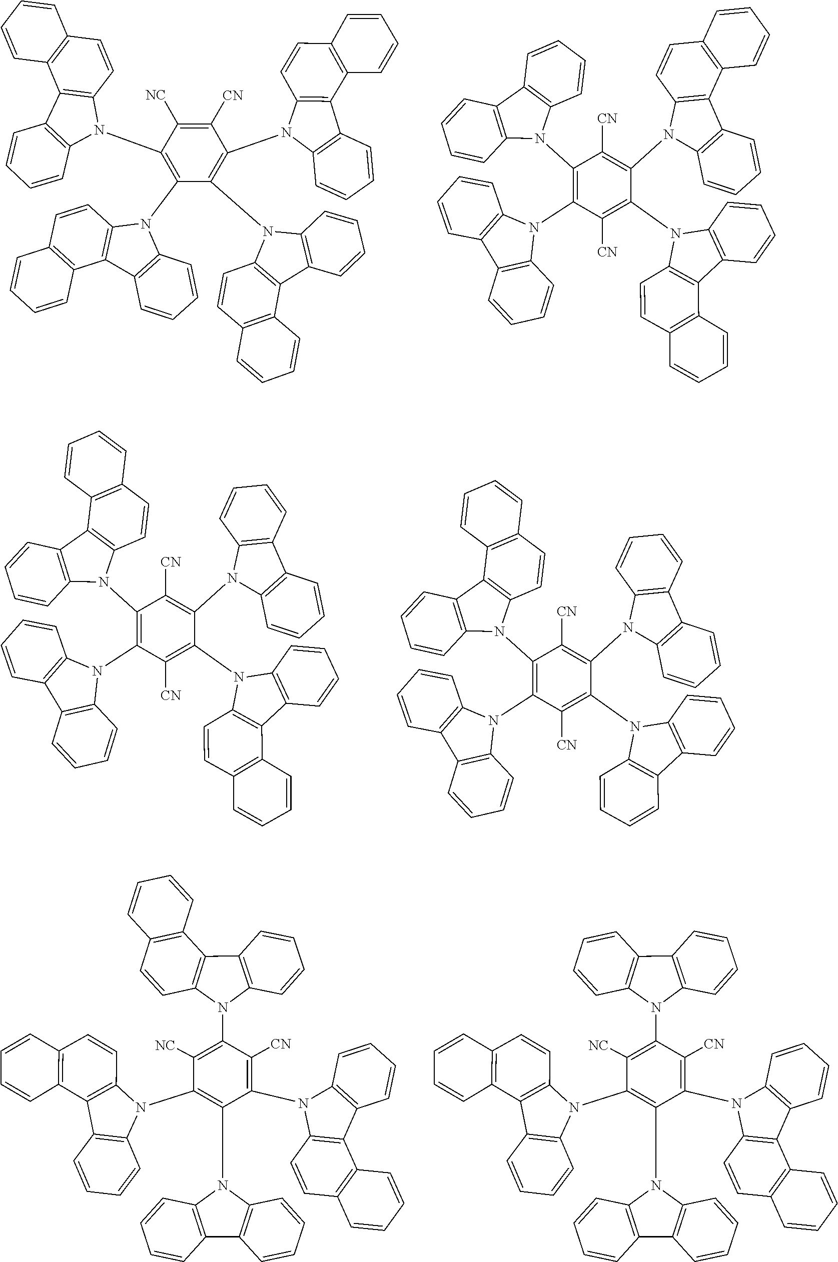

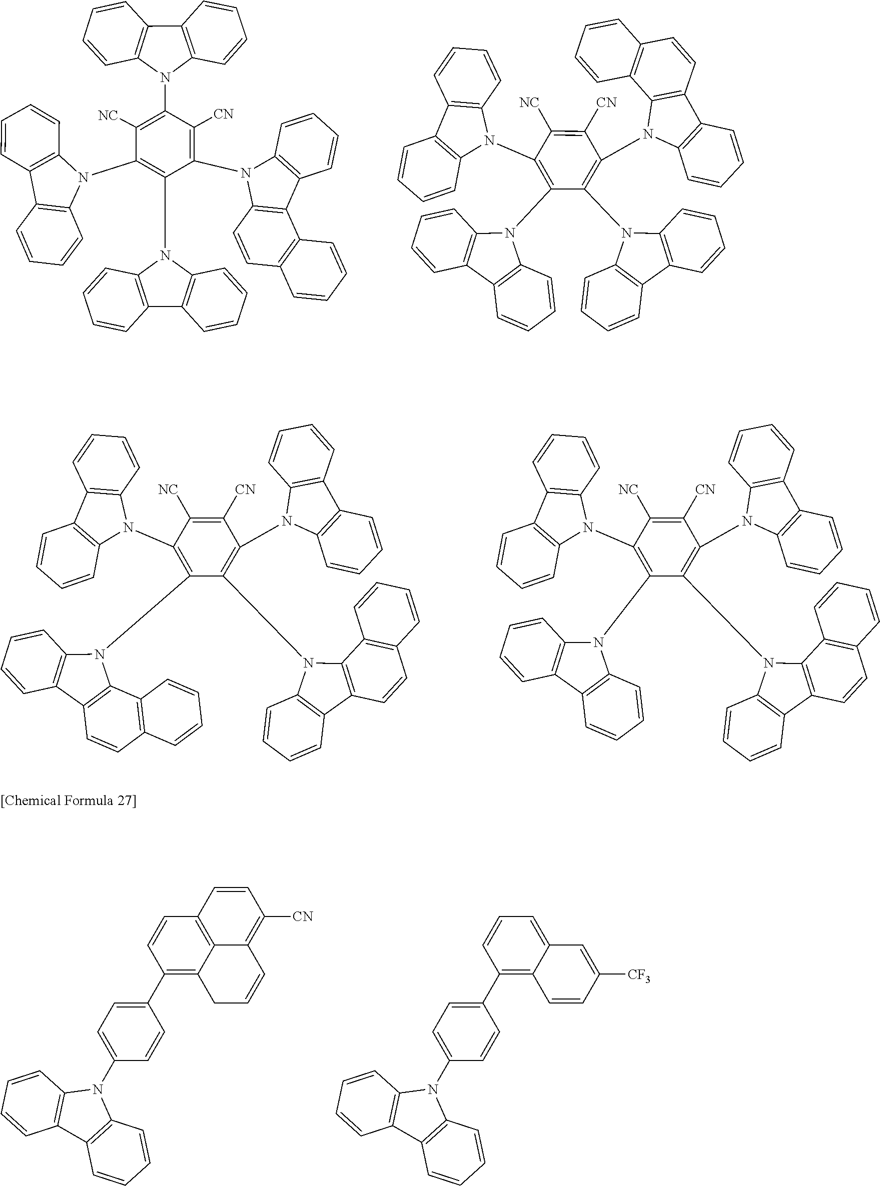

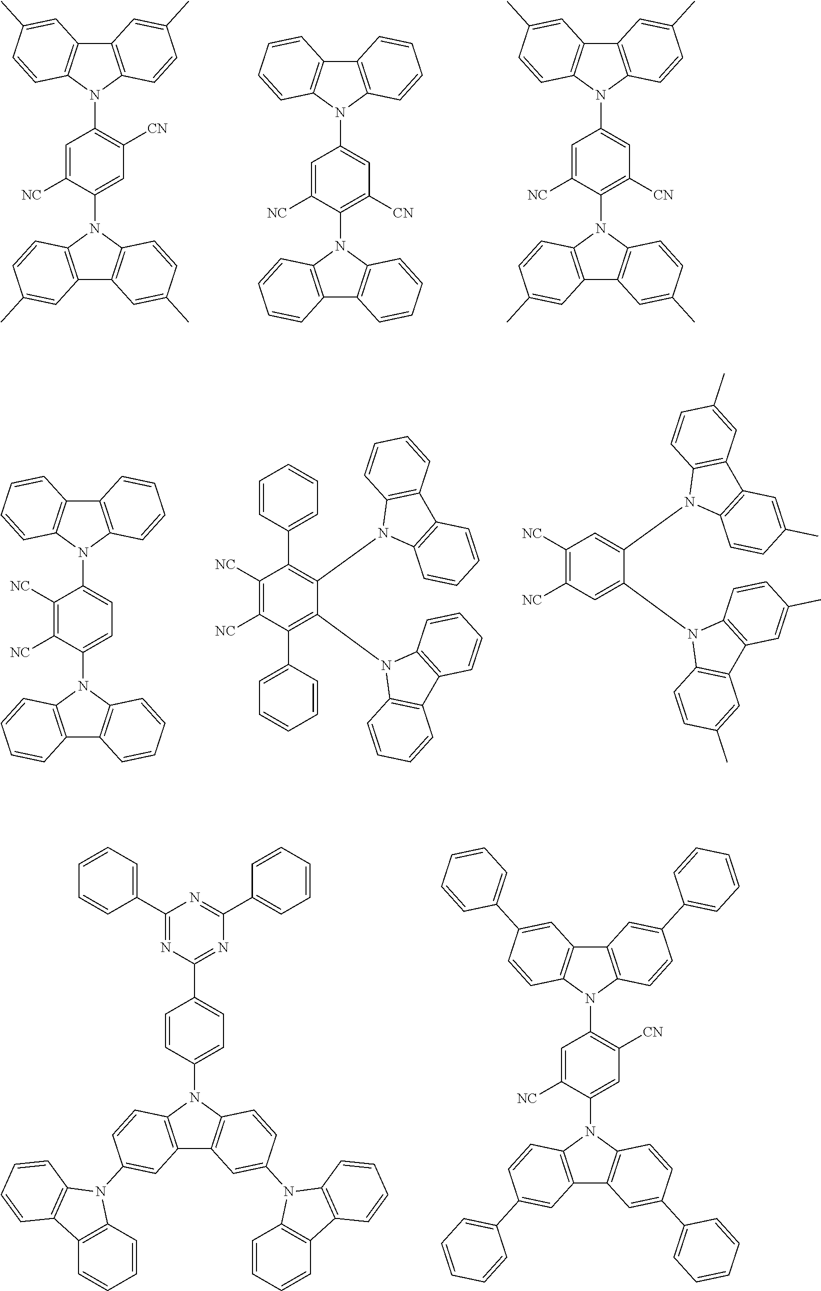

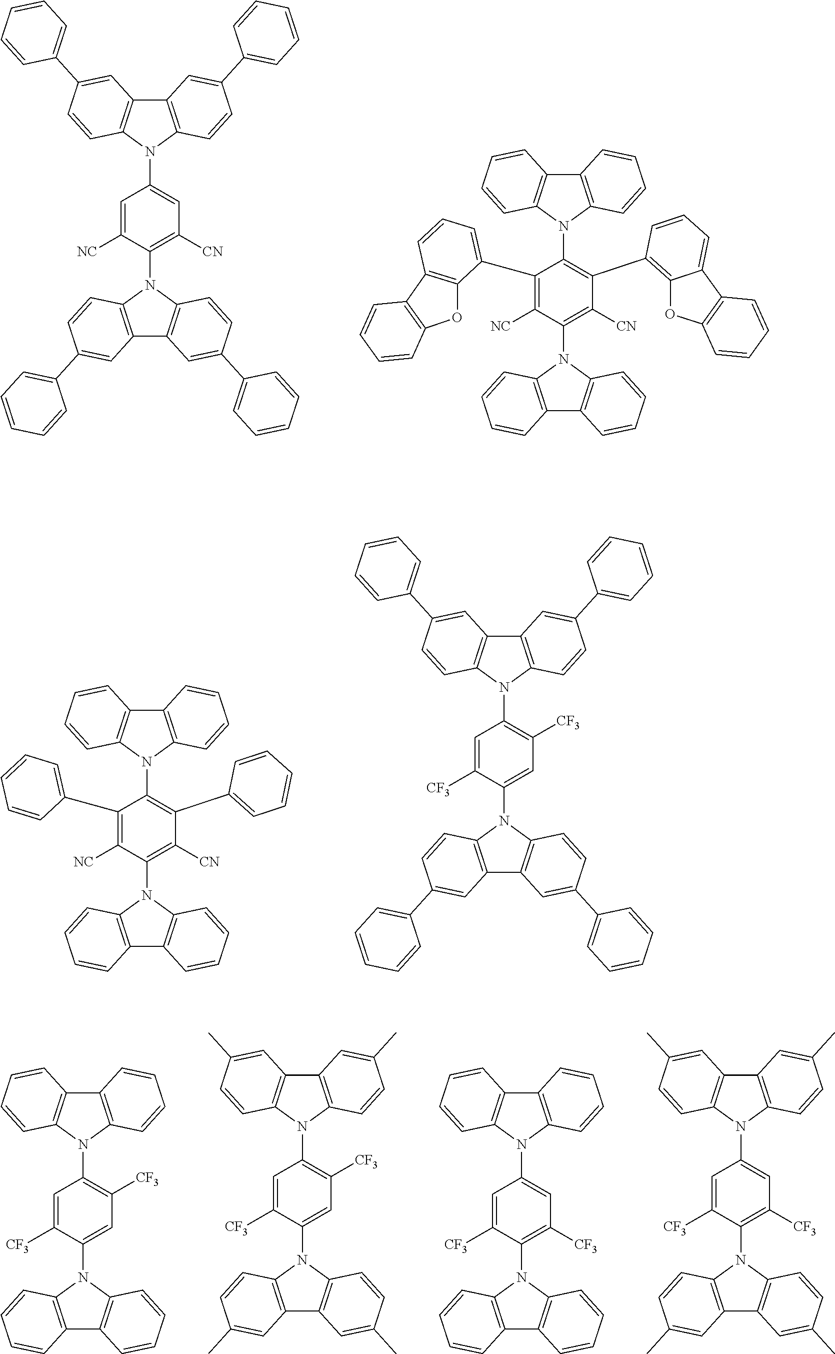

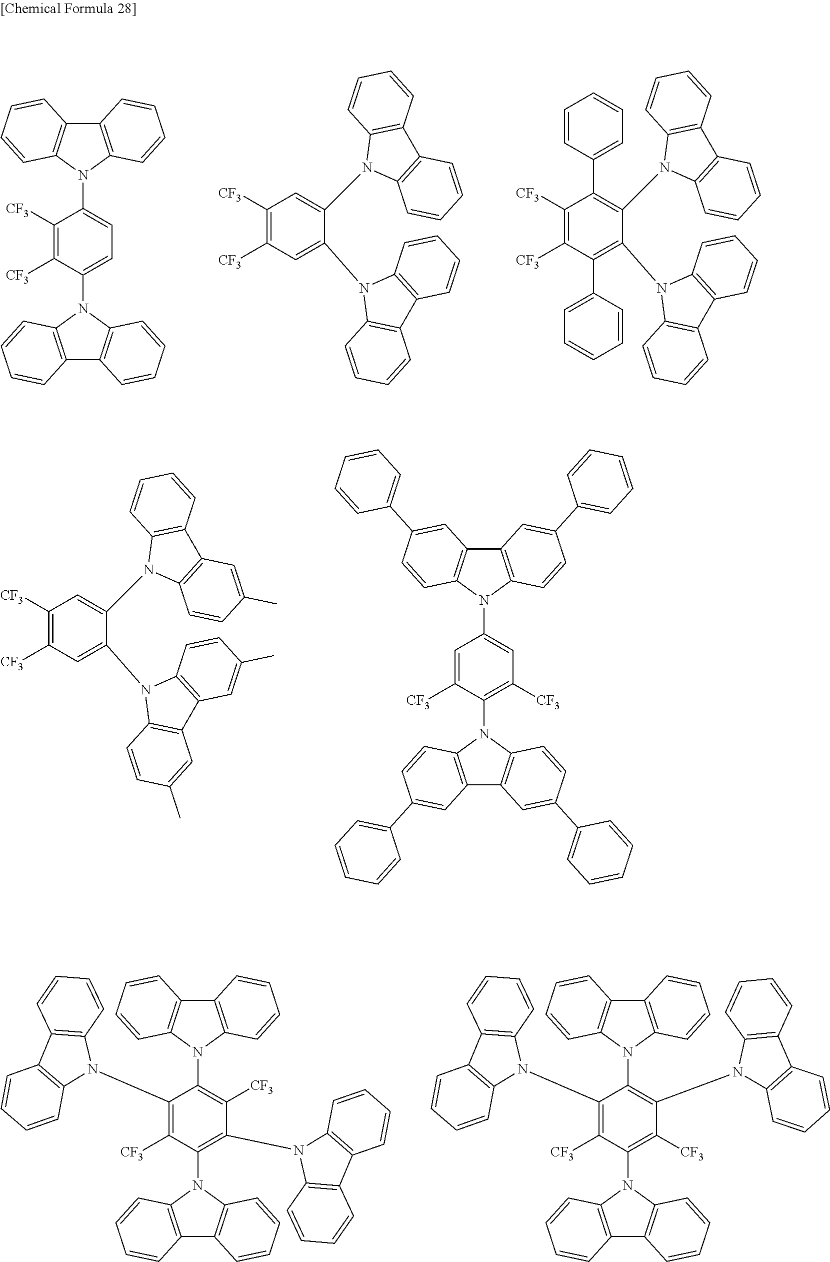

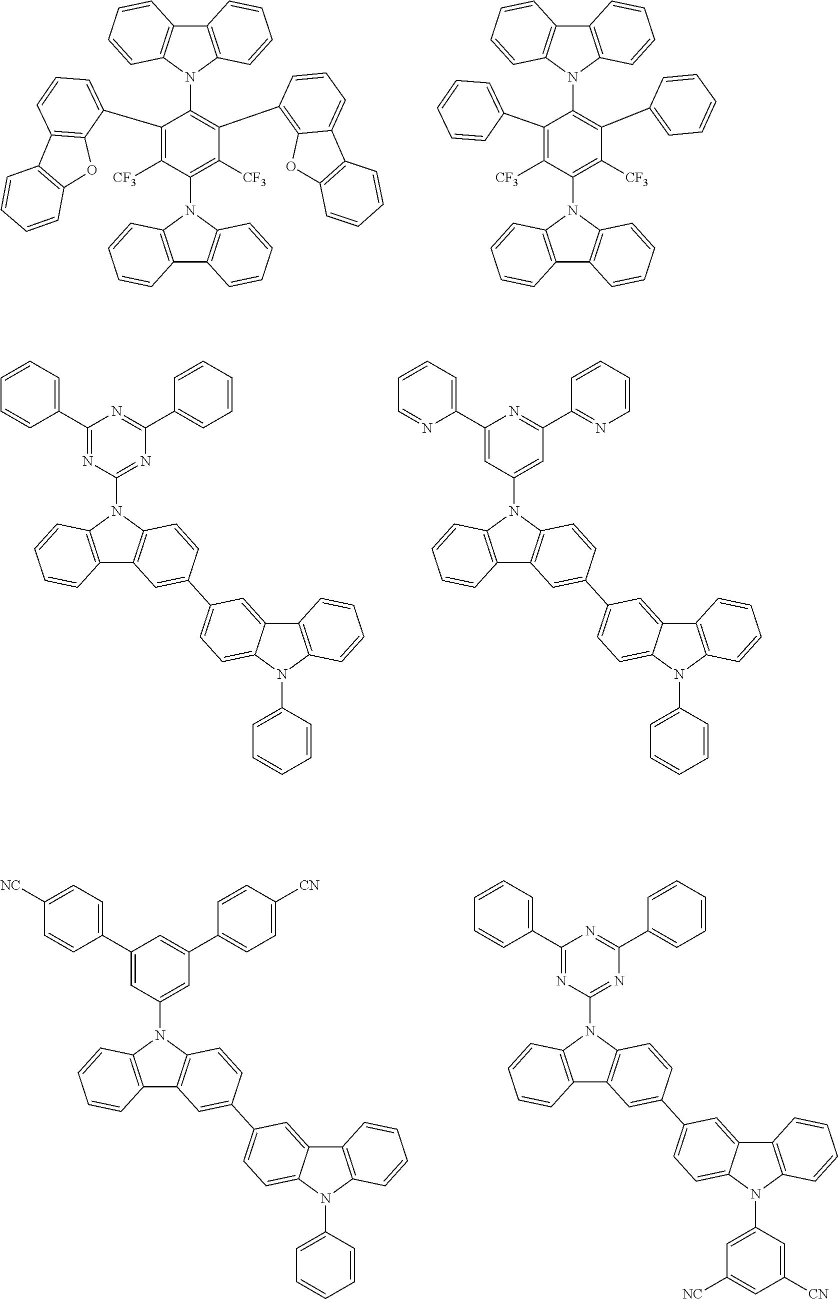

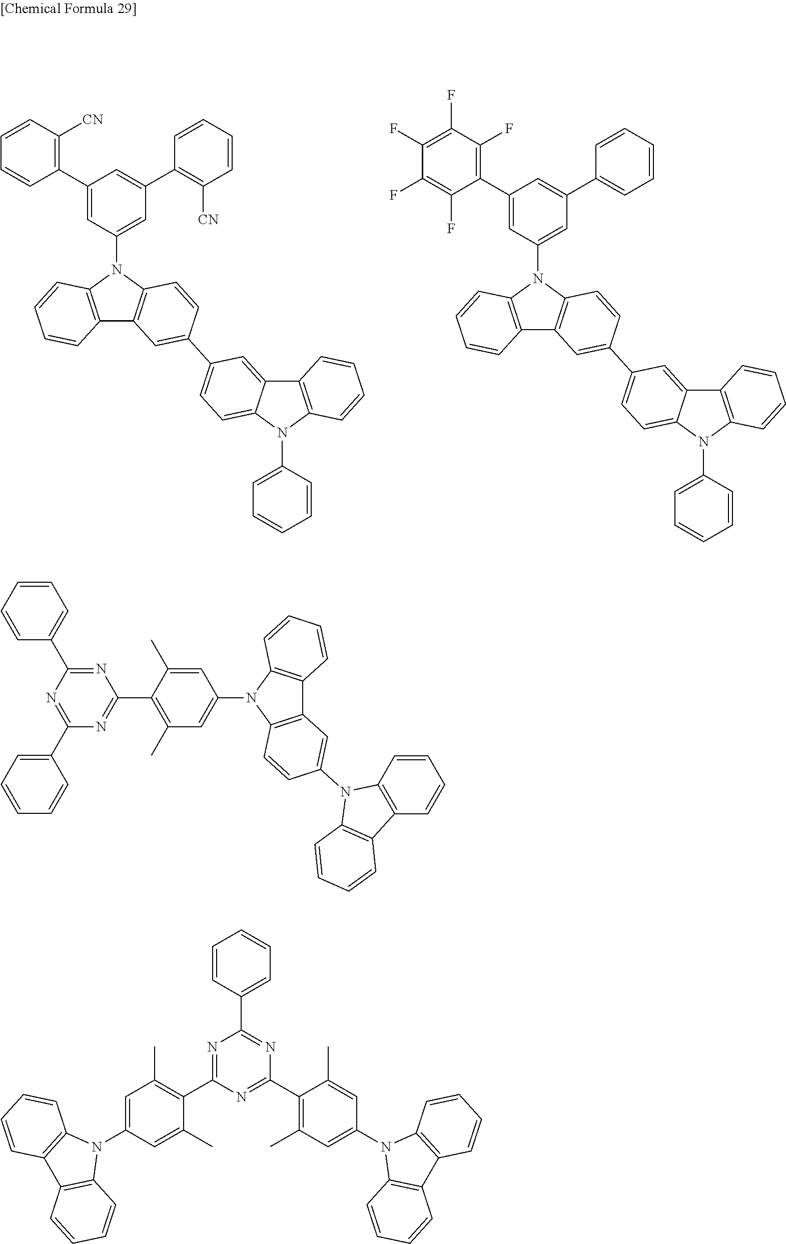 [SMILES: N#Cc1ccccc1-c1cc(-c2ccccc2C#N)cc(-n2c3ccccc3c3cc(-c4ccc5c(c4)c4ccccc4n5-c4ccccc4)ccc32)c1 ; Fc1c(F)c(F)c(-c2cc(-c3ccccc3)cc(-n3c4ccccc4c4cc(-c5ccc6c(c5)c5ccccc5n6-c5ccccc5)ccc43)c2)c(F)c1F ; Cc1cc(-n2c3ccccc3c3cc(-n4c5ccccc5c5ccccc54)ccc32)cc(C)c1-c1nc(-c2ccccc2)nc(-c2ccccc2)n1 ; Cc1cc(-n2c3ccccc3c3ccccc32)cc(C)c1-c1nc(-c2ccccc2)nc(-c2c(C)cc(-n3c4ccccc4c4ccccc43)cc2C)n1]

When thermally activated delayed fluorescence is exhibited by a plurality of compounds, it is preferable to form an excited complex (exciplex) by a combination of an electron transporting material (acceptor) and a hole transporting material (donor). Since the difference between the level of the lowest excited singlet state and the level of the lowest excited triplet state of the excited complex decreases, energy transfer is likely to occur from the level of the lowest excited triplet state to the level of the lowest excited singlet state, leading to an improvement in luminance efficiency. By adjusting the mixing ratio of the electron transporting material to the hole transporting material, the emission wavelength of the excited complex is adjusted, thus enabling an enhancement in energy transfer efficiency.

Examples of such electron transporting material include a compound or a metal complex which contains a n-electron deficient heteroaromatic ring. Specific examples thereof include metal complexes such as bis(2-methyl-8-quinolinolate) (4-phenylphenolato)aluminum(III), bis(8-quinolinolato)zinc(II) and bis[2-(2-benzoxazolyl))phenolato]zinc(II); heterocyclic compounds having a polyazole skeleton, such as 2-(4-biphenylyl)-5-(4-tert-butylphenyl)-1,3,4-oxadiazole, 3-(4-biphenylyl)-4-phenyl-5-(4-tert-butylphenyl)-1,2,4-triazole and 2-[3-(dibenzothiophen-4-yl)phenyl]-1-phenyl-1H-benzimidazole; heterocyclic compounds having a diazine skeleton, such as 2-[3′-(dibenzothiophen-4-yl)biphenyl-3-yl]dibenzo[f,h]quinoxaline and 4,6-bis[3-(phenanthren-9-yl)phenyl]pyrimidine; and heterocyclic compounds having a pyridine skeleton, such as 3,5-bis[3-(9H-carbazol-9-yl)phenyl]pyridine.

Meanwhile, examples of the hole transporting material include compounds containing a Π-electron excess heteroaromatic ring and aromatic amine compounds. Specific examples thereof include compounds having an aromatic amine skeleton, such as 4,4′-bis[N-(1-naphthyl)-N-phenylamino]biphenyl (abbreviation: NPB), N,N′-bis(3-methylphenyl)-N,N′-diphenyl-[1,1′-biphenyl]-4,4′-diamine (abbreviation: TPD), 4-phenyl-4′-(9-phenyl-9H-carbazol-3-yl)triphenylamine, 4-(1-naphthyl)-4′-(9-phenyl-9H-carbazol-3-yl)triphenylamine and N-phenyl-N-[4-(9-phenyl-9H-carbazol-3-yl)phenyl]-spiro-9,9′-bifluorene-2-amine; compounds having a carbazole skeleton, such as 1,3-bis(N-carbazolyl)benzene, 4,4′-di(N-carbazolyl)biphenyl (CBP), 3,3′-di(N-carbazolyl)biphenyl (mCBP), 1,3,5-tris[4-(N-carbazolyl)phenyl]benzene (TCPB), 9-[4-(10-phenyl-9-anthracenyl)phenyl]-9H-carbazole (CzPA), 1,4-bis[4-(N-carbazolyl)phenyl]-2,3,5,6-tetraphenylbenzene, 9-phenyl-9H-3-(9-phenyl-9H-carbazol-3-yl)carbazole, 3,6-bis[N-(9-phenylcarbazol-3-yl)-N-phenylamino]-9-phenylcarbazole (PCzPCA2), 3-[N-(1-naphthyl)-N-(9-phenylcarbazol-3-yl)amino]-9-phenylcarbazole (PCzPCN1), 9-([1,1-biphenyl]-4-yl)-9′-([1,1′:4′,1″-terphenyl]-4-yl)-9H,9′H-3,3′-bicarbazole, 9-([1,1′:4′,1″-terphenyl]-4-yl)-9′-(naphthalen-2-yl)-9H,9′H-3,3′-bicarbazole and 9,9′,9″-triphenyl-9H,9′H,9″H-3,3′:6′,3″-tricarbazole; compounds having a thiophene skeleton, such as 4,4′,4″-(benzene-1,3,5-triyl)tri(dibenzothiophene) and 2,8-diphenyl-4-[4-(9-phenyl-9H-fluoren-9-yl)phenyl]dibenzothiophene; and compounds having a furan skeleton, such as 4,4′,4″-(benzene-1,3,5-triyl)tri(dibenzofuran) and 4-{3-[3-(9-phenyl-9H-fluoren-9-yl)phenyl]phenyl}dibenzofuran.

When the first compound is a thermally activated delayed fluorescent material, it is preferable that the light emitting layer further contains a third compound, and the lowest excited singlet energy of the third compound is higher than that of the first compound. It is more preferable that the lowest excited triplet energy of the third compound is larger than that of the first compound. As a result, the third compound can have a function of confining the energy of the light emitting material in the light emitting layer, thus making it possible to efficiently emit light.

The third compound is preferably an organic compound having high charge transporting ability and high glass transition temperature. Examples of the third compound include, but are not particularly limited to, the following.

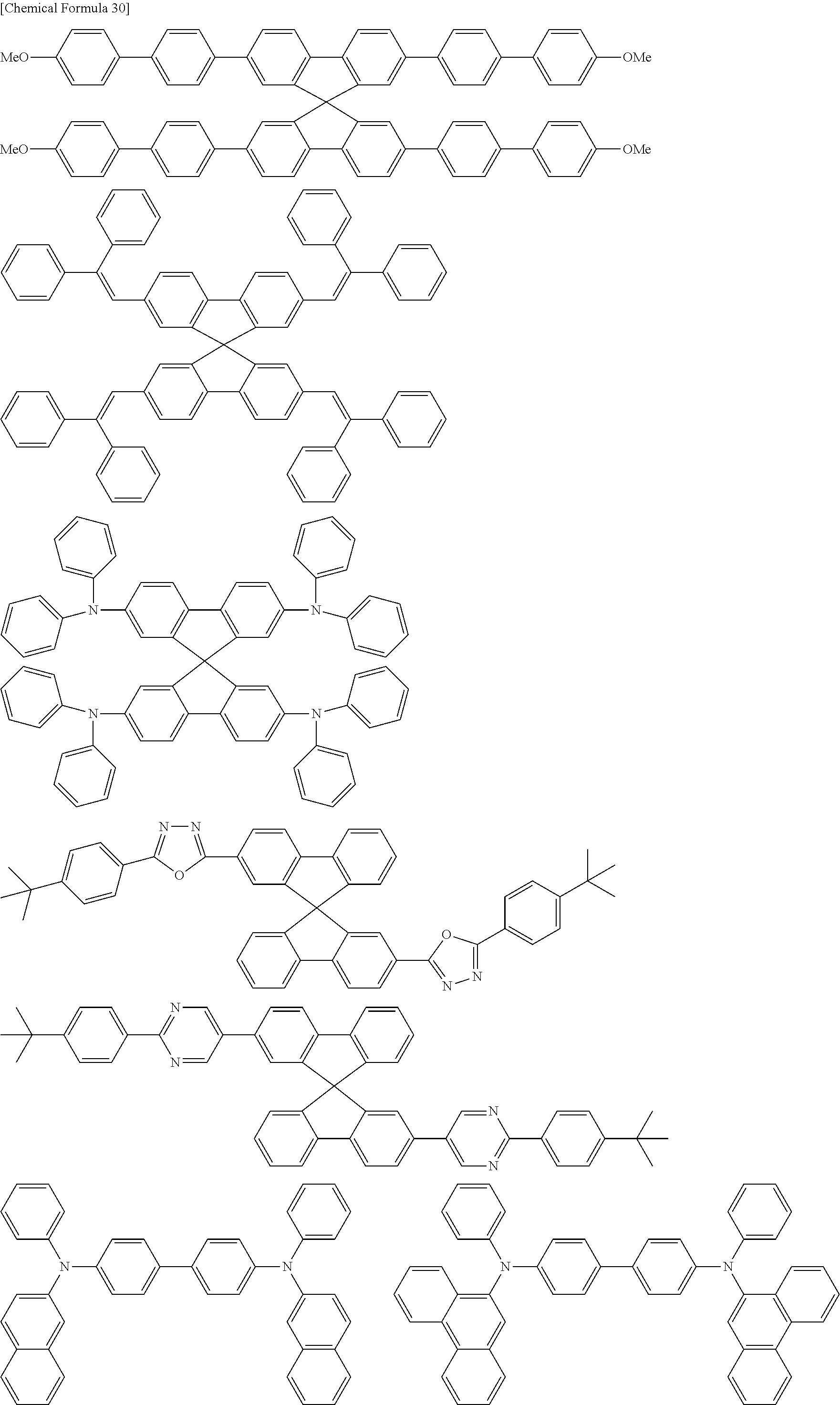

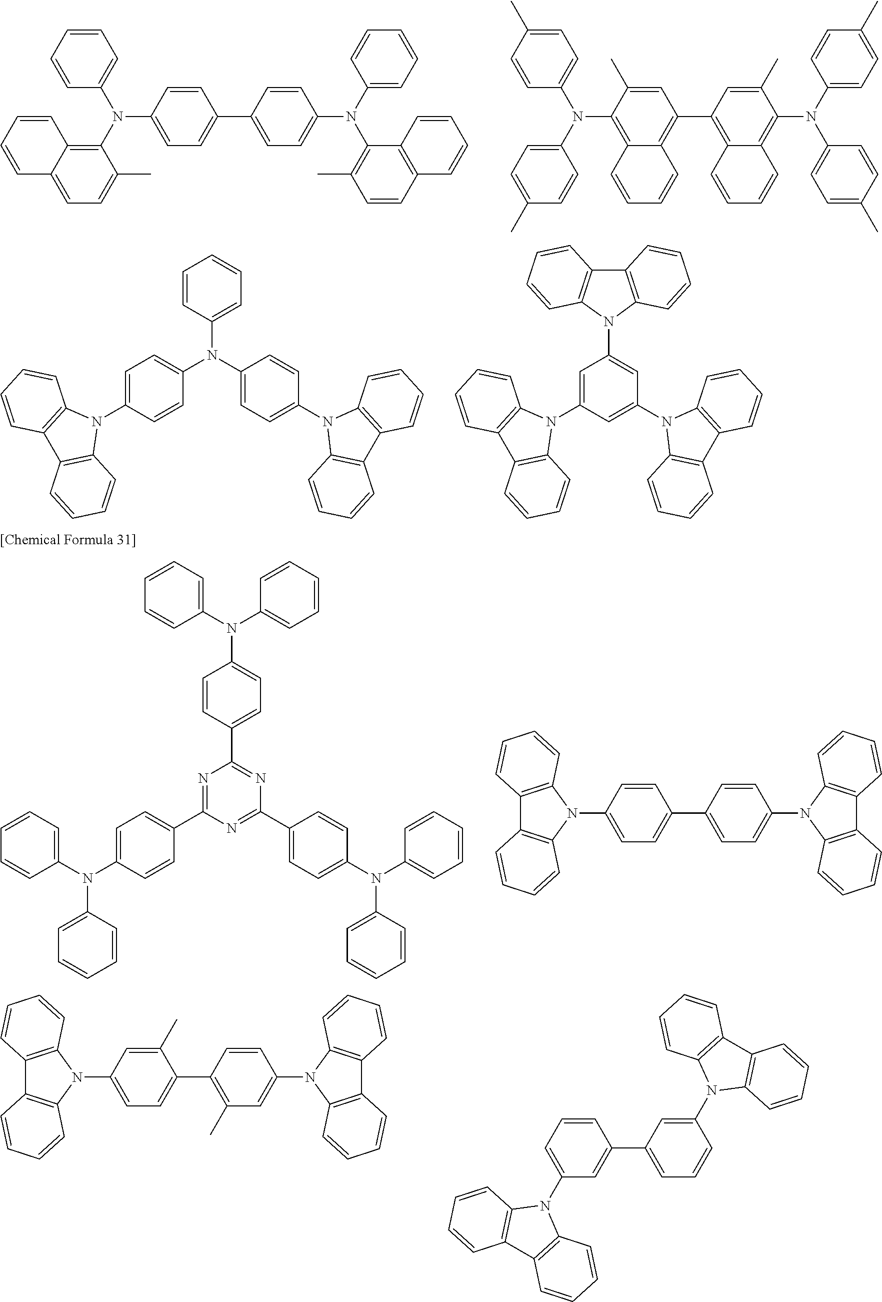

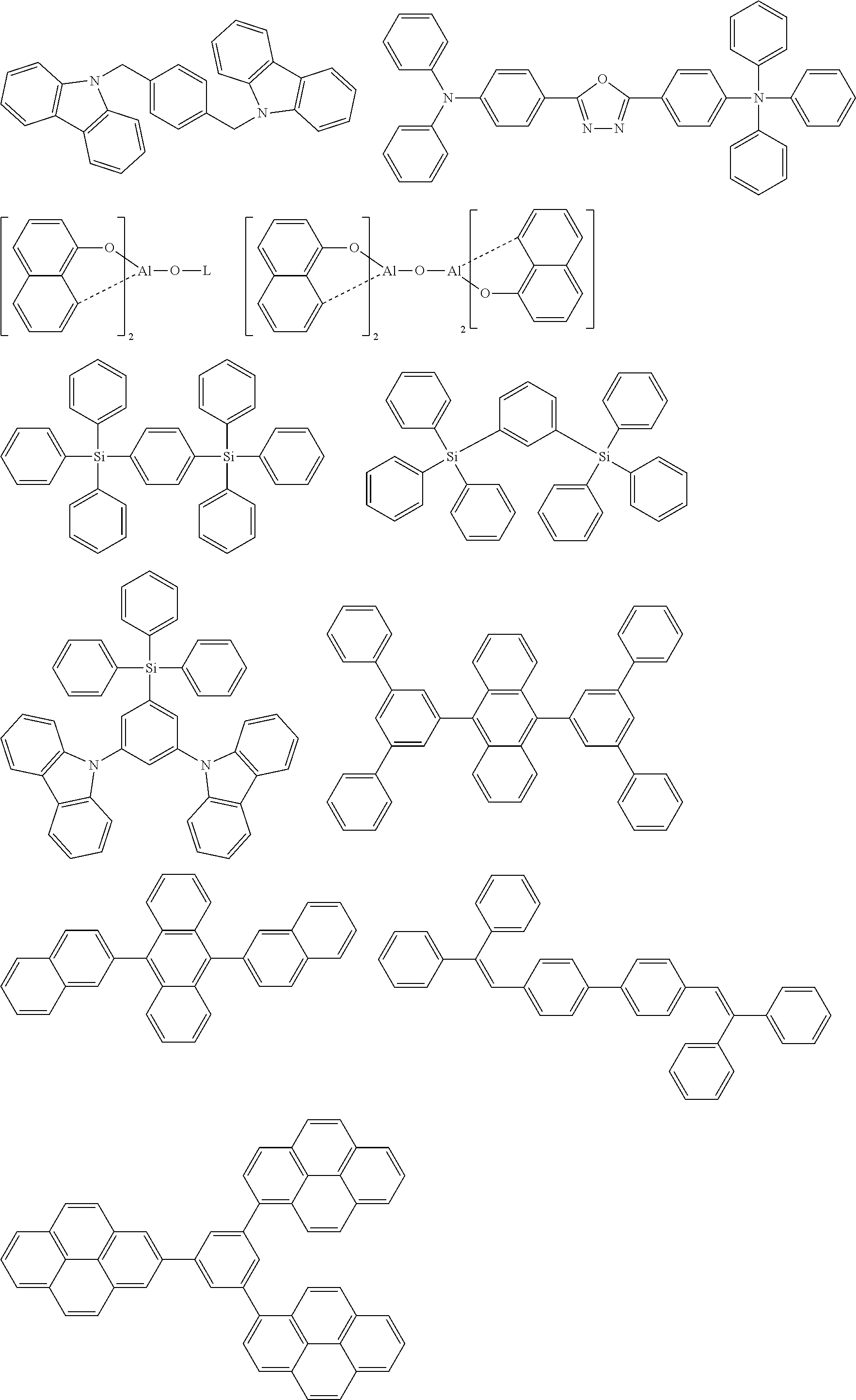

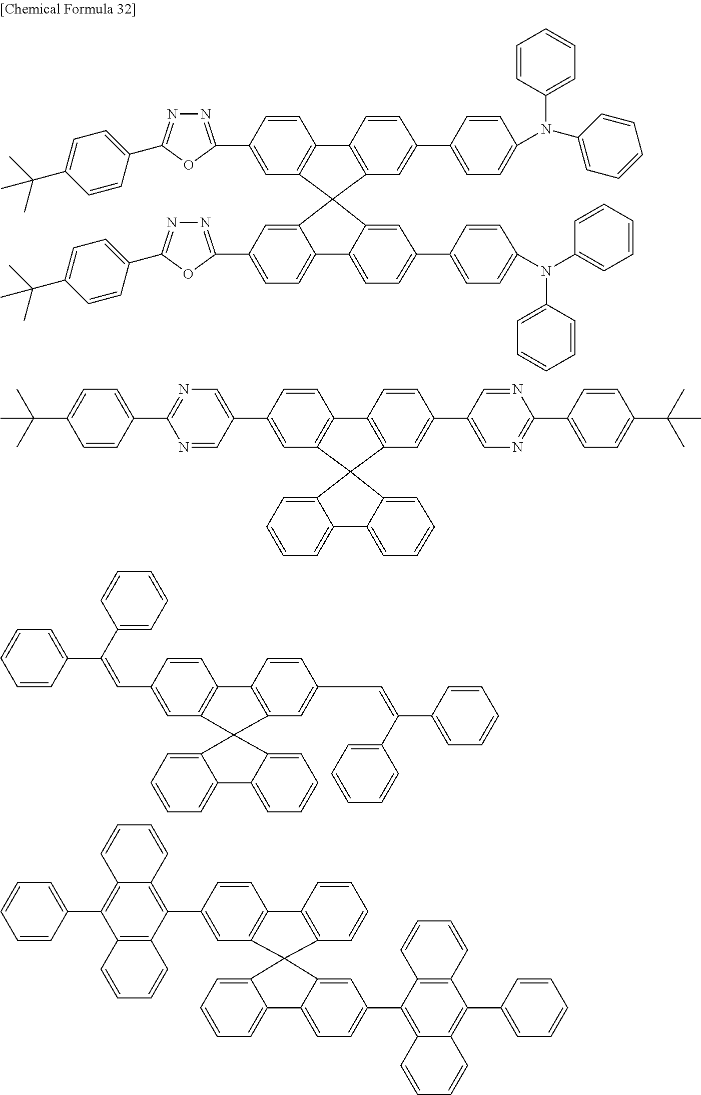

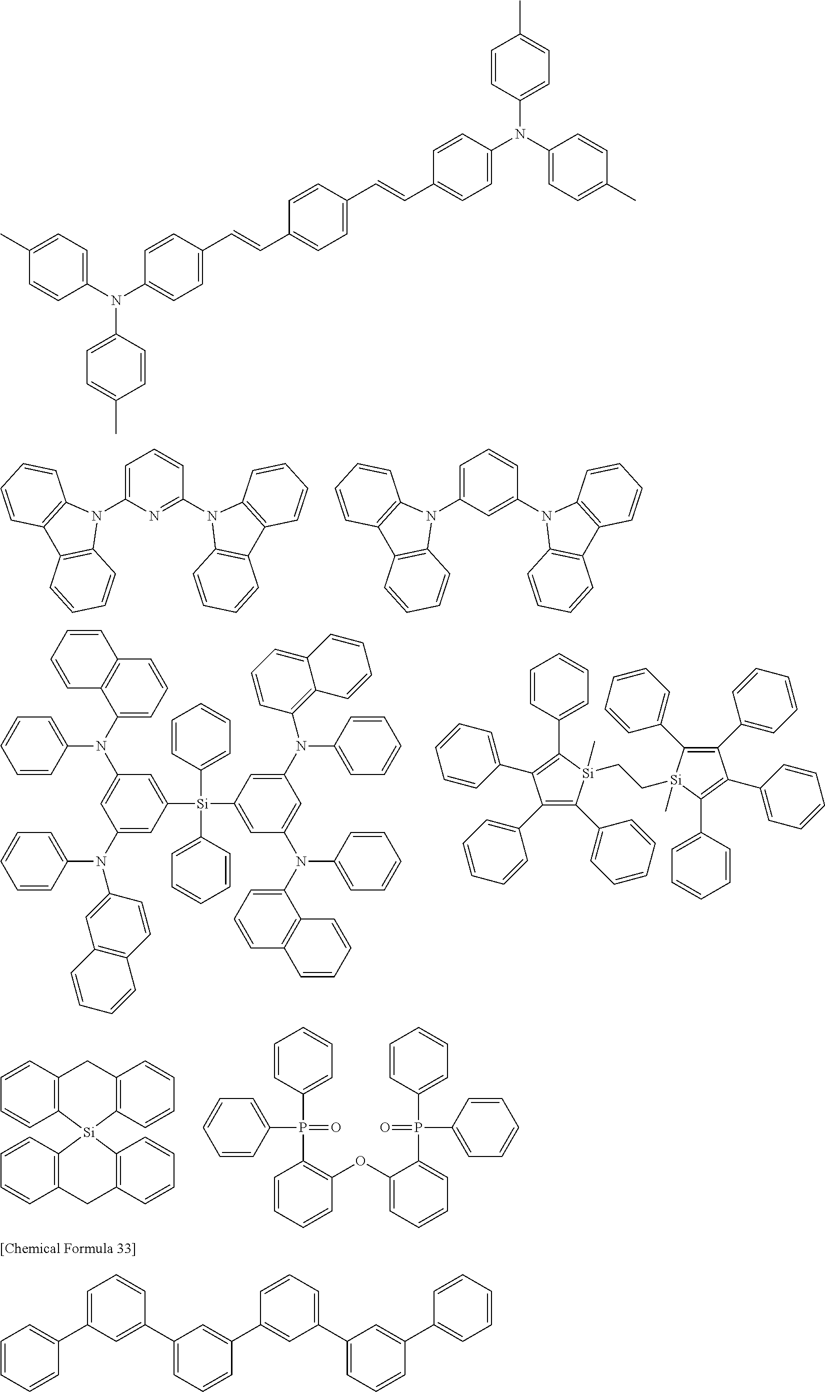

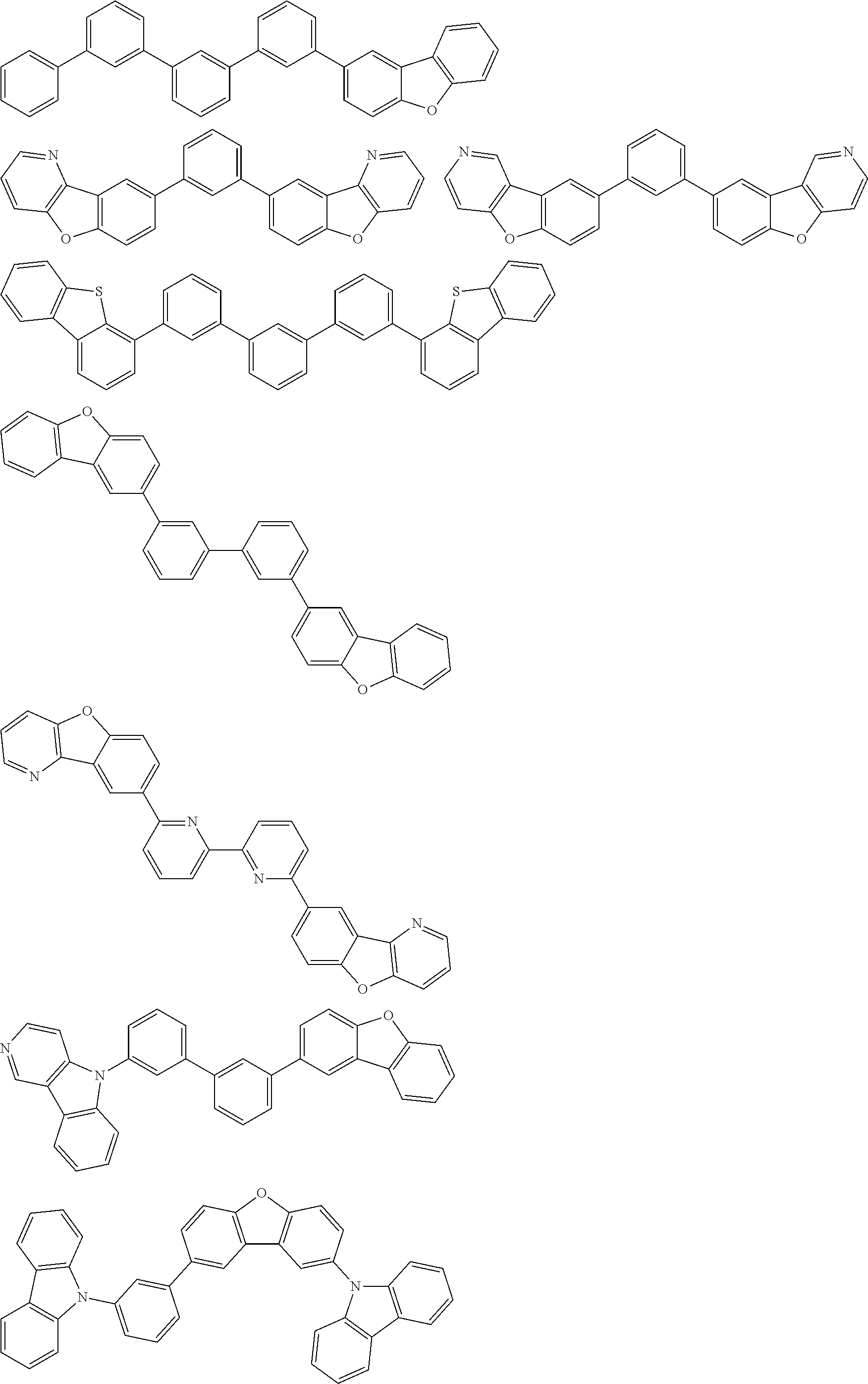

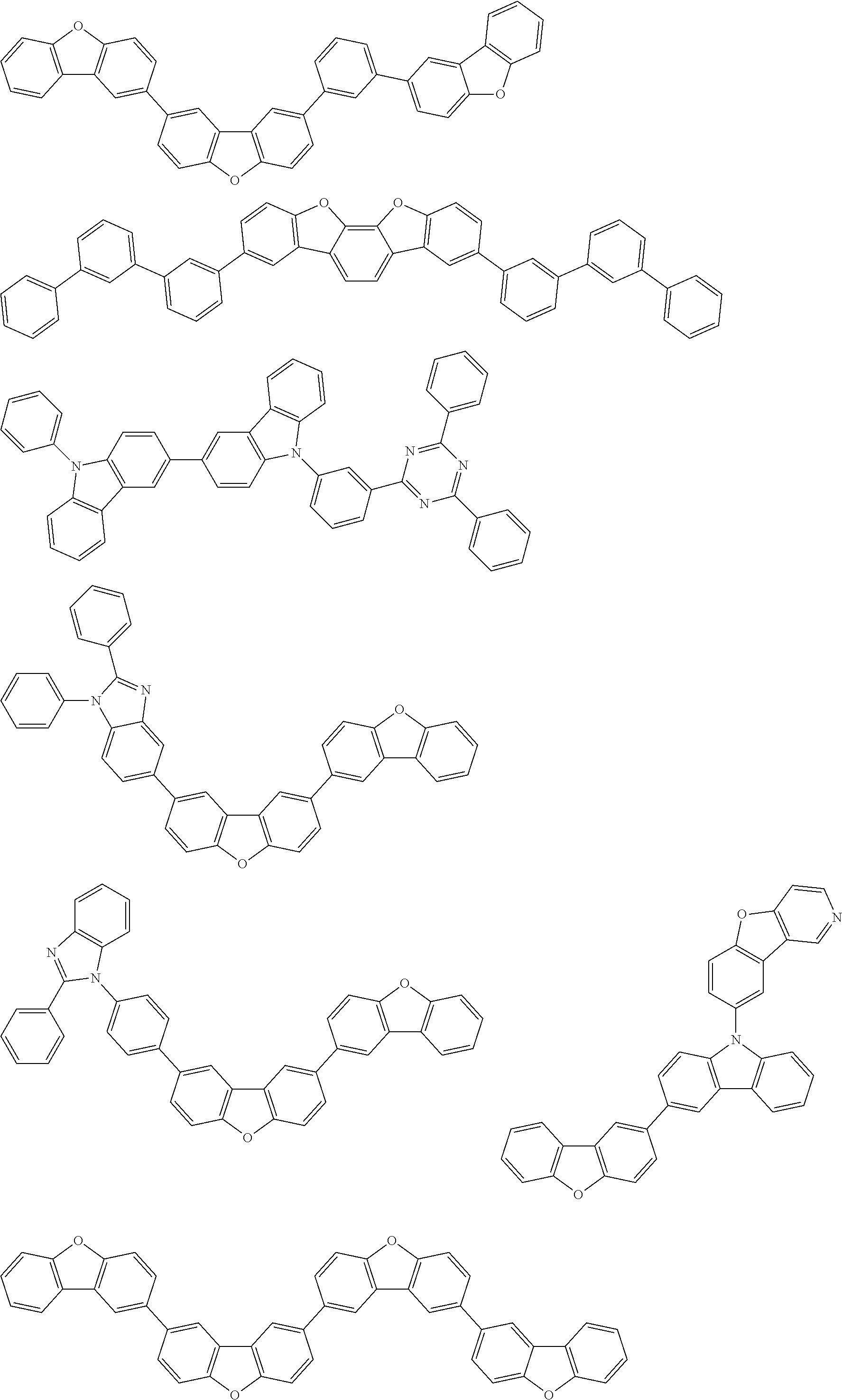

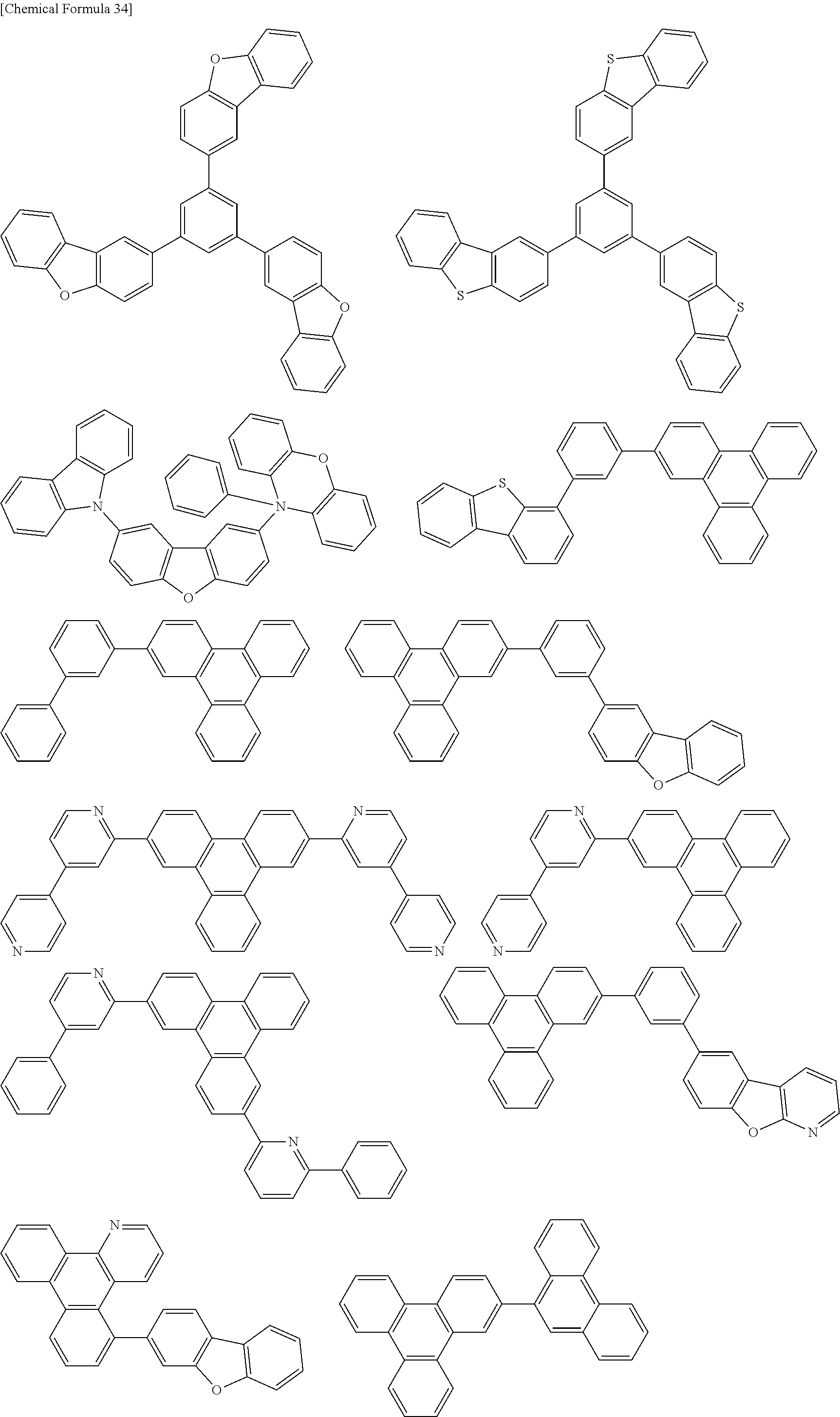

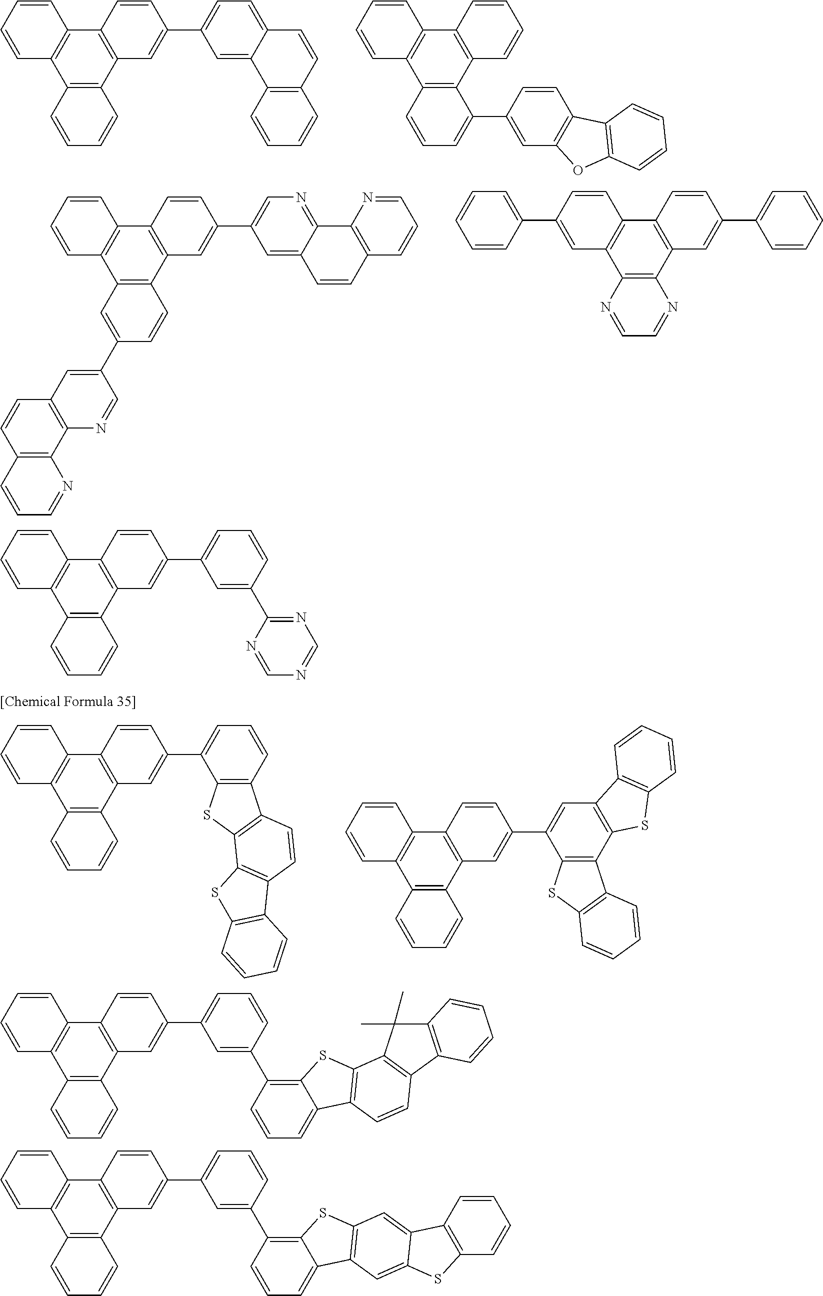

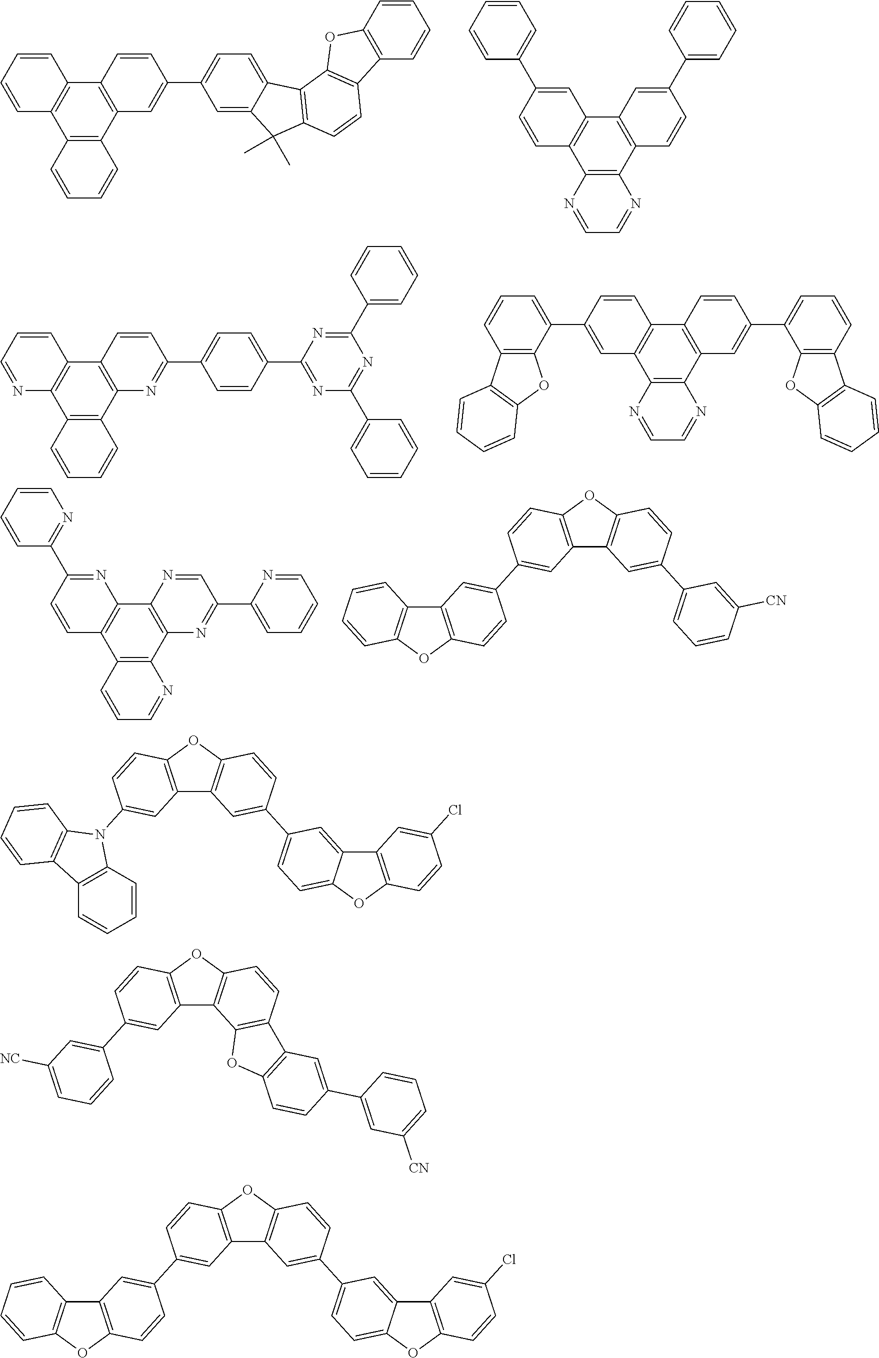

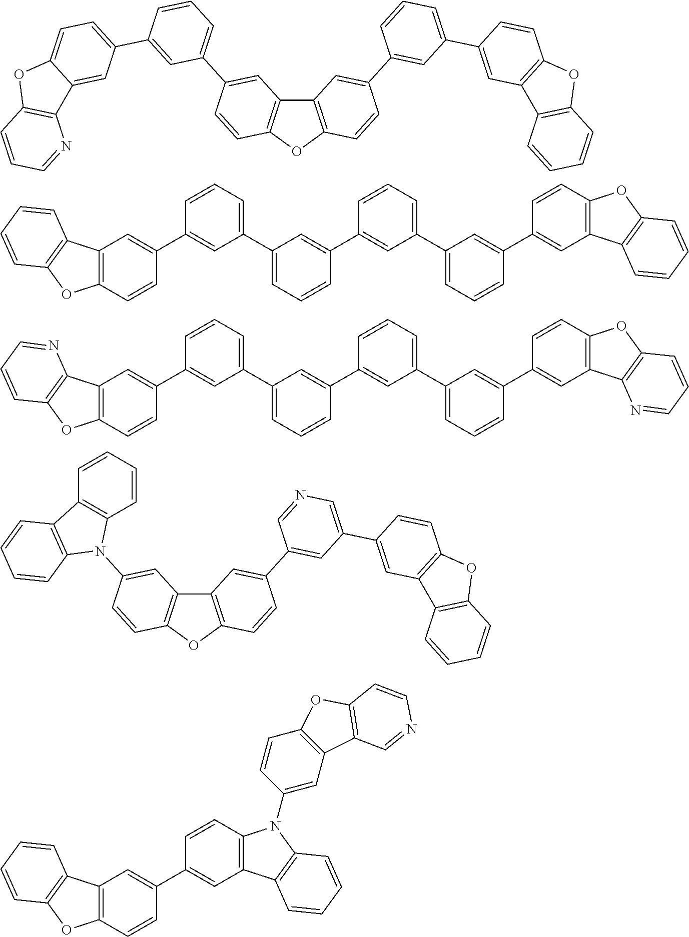

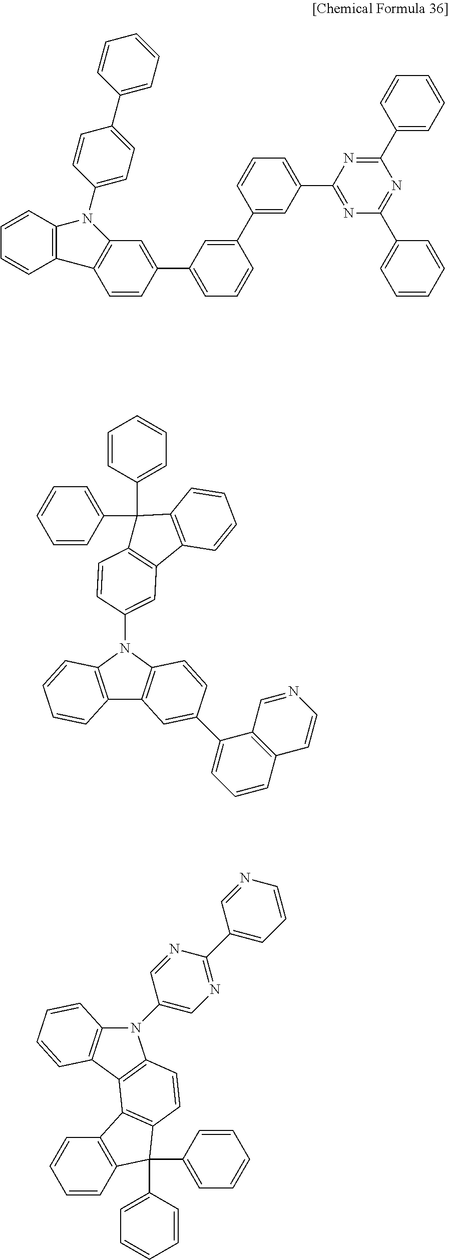 [SMILES: c1ccc(-c2ccc(-n3c4ccccc4c4ccc(-c5cccc(-c6cccc(-c7nc(-c8ccccc8)nc(-c8ccccc8)n7)c6)c5)cc43)cc2)cc1 ; c1ccc(C2(c3ccccc3)c3ccccc3-c3cc(-n4c5ccccc5c5cc(-c6cccc7ccncc67)ccc54)ccc32)cc1 ; c1ccc(C2(c3ccccc3)c3ccccc3-c3c2ccc2c3c3ccccc3n2-c2cnc(-c3cccnc3)nc2)cc1]

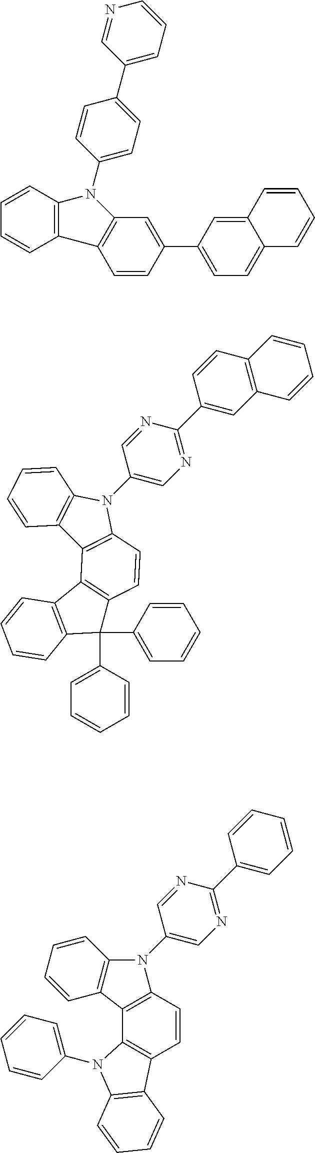 [SMILES: c1cncc(-c2ccc(-n3c4ccccc4c4ccc(-c5ccc6ccccc6c5)cc43)cc2)c1 ; c1ccc(C2(c3ccccc3)c3ccccc3-c3c2ccc2c3c3ccccc3n2-c2cnc(-c3ccc4ccccc4c3)nc2)cc1 ; c1ccc(-c2ncc(-n3c4ccccc4c4c3ccc3c5ccccc5n(-c5ccccc5)c34)cn2)cc1]

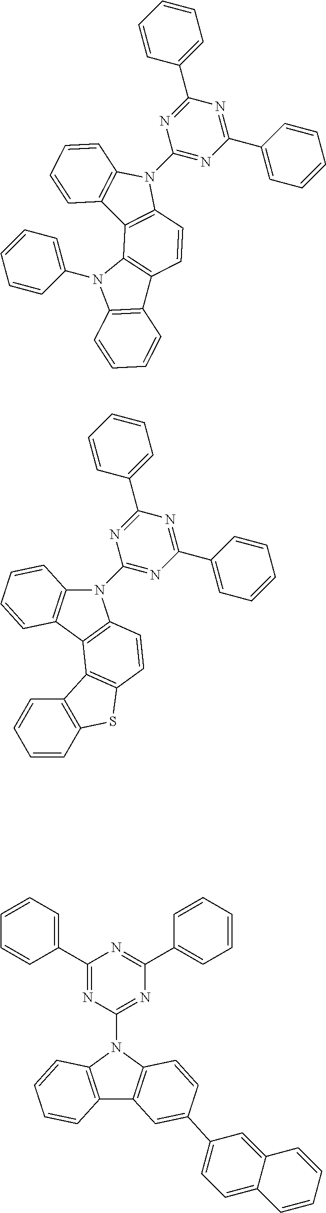

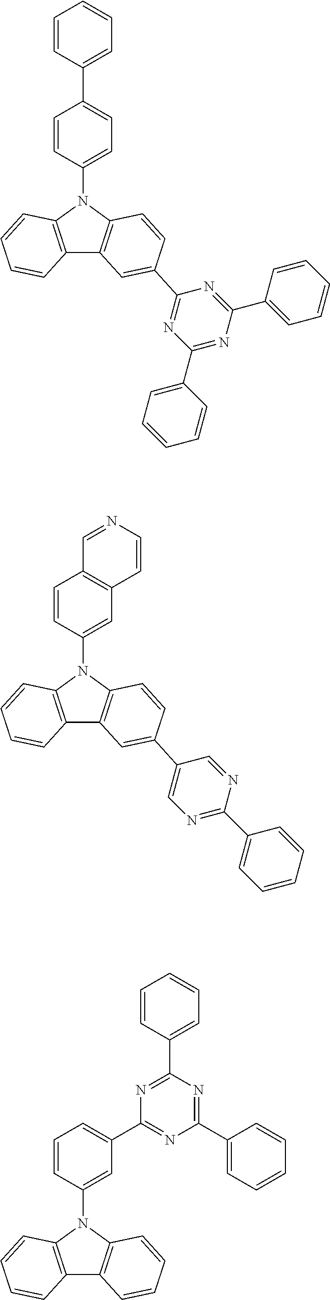 [SMILES: c1ccc(-c2ccc(-n3c4ccccc4c4cc(-c5nc(-c6ccccc6)nc(-c6ccccc6)n5)ccc43)cc2)cc1 ; c1ccc(-c2ncc(-c3ccc4c(c3)c3ccccc3n4-c3ccc4cnccc4c3)cn2)cc1 ; c1ccc(-c2nc(-c3ccccc3)nc(-c3cccc(-n4c5ccccc5c5ccccc54)c3)n2)cc1]

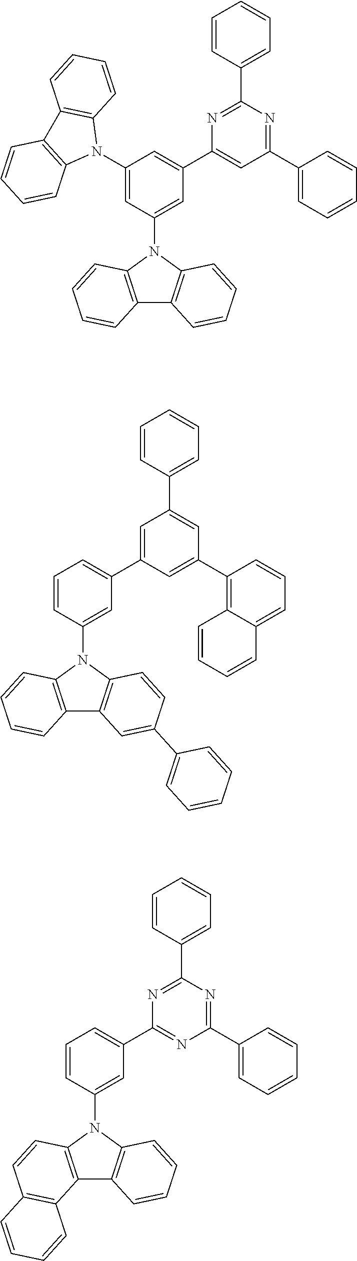 [SMILES: c1ccc(-c2cc(-c3cc(-n4c5ccccc5c5ccccc54)cc(-n4c5ccccc5c5ccccc54)c3)nc(-c3ccccc3)n2)cc1 ; c1ccc(-c2cc(-c3cccc(-n4c5ccccc5c5cc(-c6ccccc6)ccc54)c3)cc(-c3cccc4ccccc34)c2)cc1 ; c1ccc(-c2nc(-c3ccccc3)nc(-c3cccc(-n4c5ccccc5c5c6ccccc6ccc54)c3)n2)cc1]

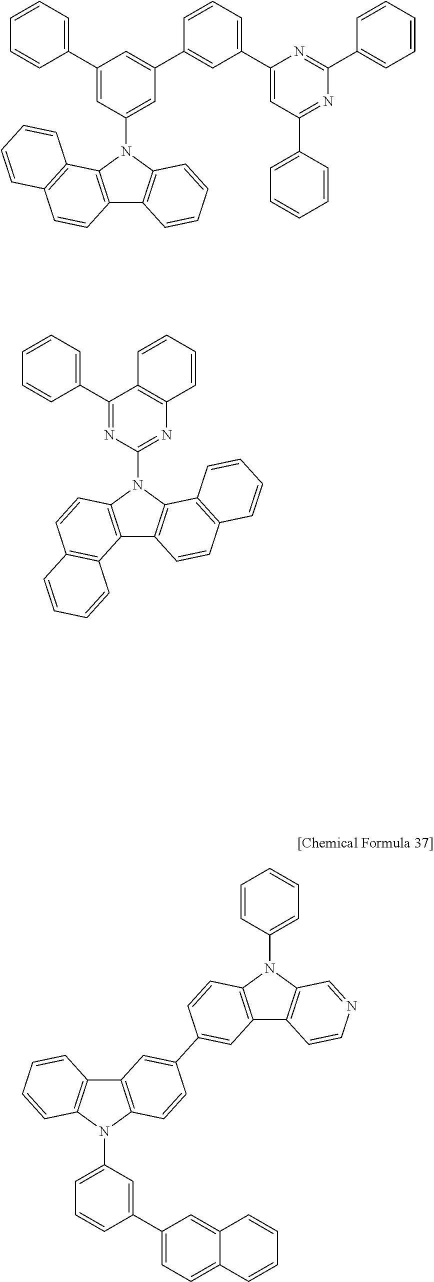 [SMILES: c1ccc(-c2cc(-c3cccc(-c4cc(-c5ccccc5)nc(-c5ccccc5)n4)c3)cc(-n3c4ccccc4c4ccc5ccccc5c43)c2)cc1 ; c1ccc(-c2nc(-n3c4ccc5ccccc5c4c4ccc5ccccc5c43)nc3ccccc23)cc1 ; c1ccc(-n2c3ccc(-c4ccc5c(c4)c4ccccc4n5-c4cccc(-c5ccc6ccccc6c5)c4)cc3c3ccncc32)cc1]

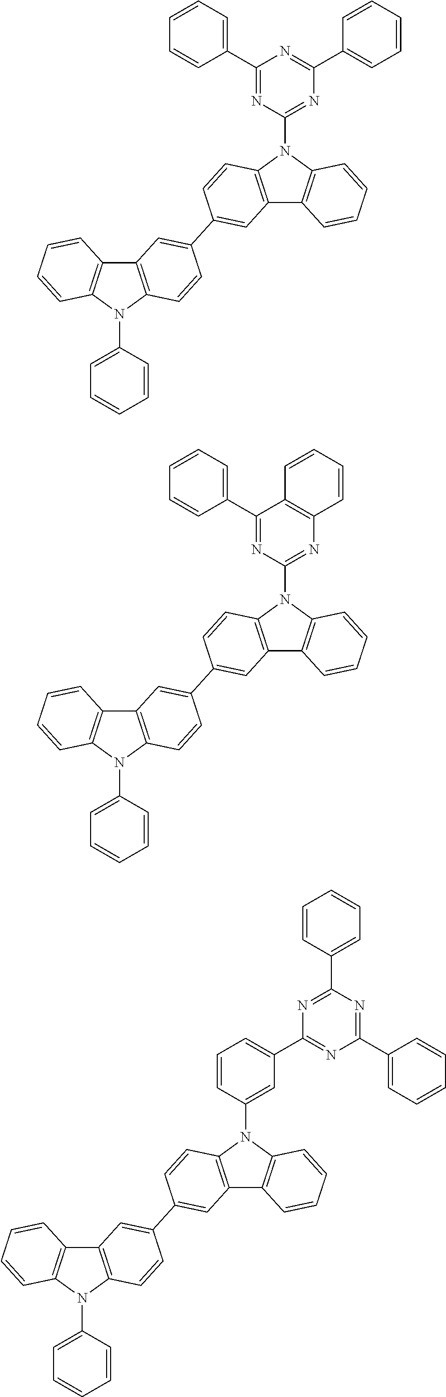 [SMILES: c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2nc(-n3c4ccccc4c4cc(-c5ccc6c(c5)c5ccccc5n6-c5ccccc5)ccc43)nc3ccccc23)cc1 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1]

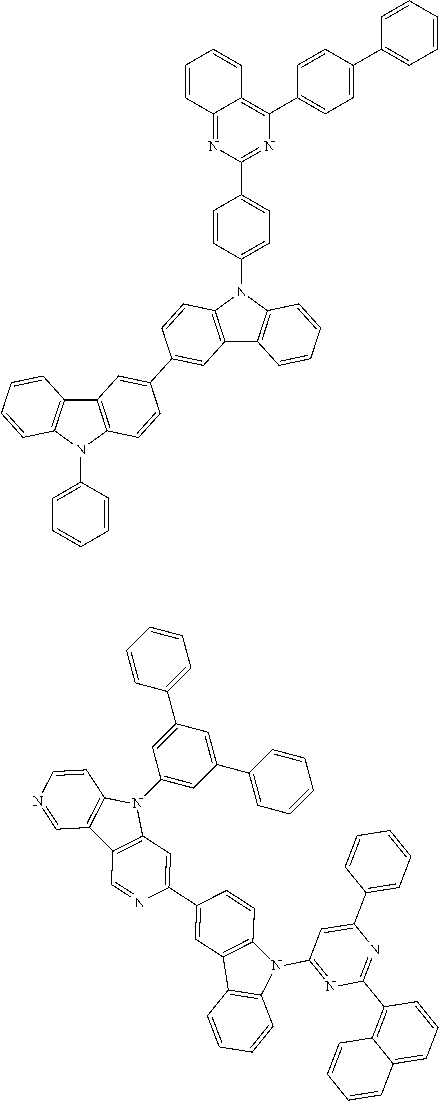 [SMILES: c1ccc(-c2ccc(-c3nc(-c4ccc(-n5c6ccccc6c6cc(-c7ccc8c(c7)c7ccccc7n8-c7ccccc7)ccc65)cc4)nc4ccccc34)cc2)cc1 ; c1ccc(-c2cc(-c3ccccc3)cc(-n3c4ccncc4c4cnc(-c5ccc6c(c5)c5ccccc5n6-c5cc(-c6ccccc6)nc(-c6cccc7ccccc67)n5)cc43)c2)cc1]

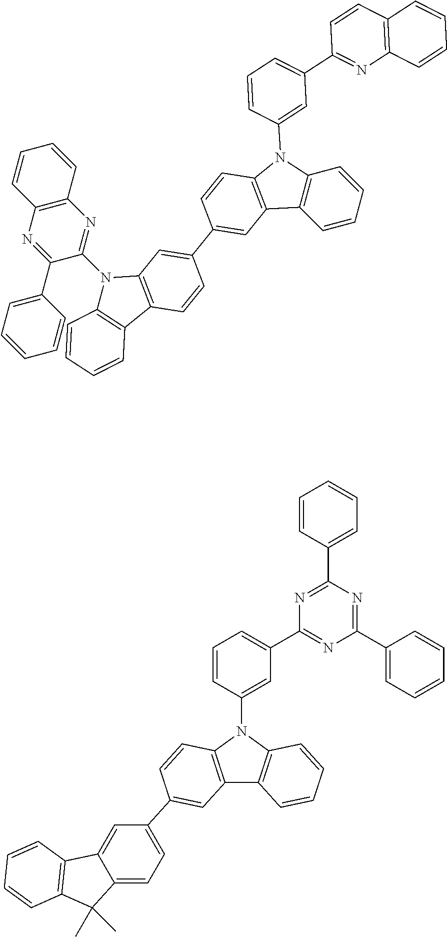 [SMILES: c1ccc(-c2nc3ccccc3nc2-n2c3ccccc3c3ccc(-c4ccc5c(c4)c4ccccc4n5-c4cccc(-c5ccc6ccccc6n5)c4)cc32)cc1 ; CC1(C)c2ccccc2-c2cc(-c3ccc4c(c3)c3ccccc3n4-c3cccc(-c4nc(-c5ccccc5)nc(-c5ccccc5)n4)c3)ccc21]

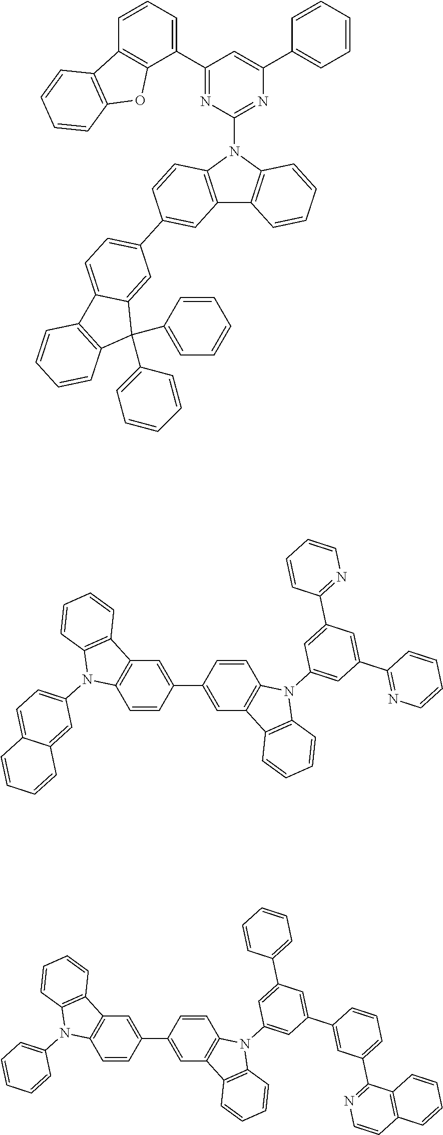 [SMILES: c1ccc(-c2cc(-c3cccc4c3oc3ccccc34)nc(-n3c4ccccc4c4cc(-c5ccc6c(c5)C(c5ccccc5)(c5ccccc5)c5ccccc5-6)ccc43)n2)cc1 ; c1ccc(-c2cc(-c3ccccn3)cc(-n3c4ccccc4c4cc(-c5ccc6c(c5)c5ccccc5n6-c5ccc6ccccc6c5)ccc43)c2)nc1 ; c1ccc(-c2cc(-c3cccc(-c4nccc5ccccc45)c3)cc(-n3c4ccccc4c4cc(-c5ccc6c(c5)c5ccccc5n6-c5ccccc5)ccc43)c2)cc1]

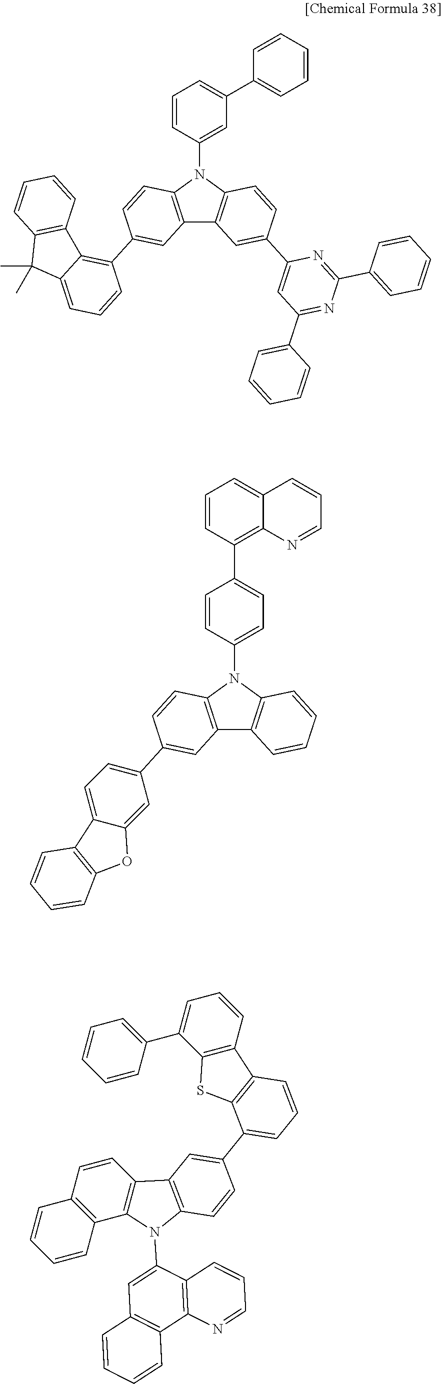 [SMILES: CC1(C)c2ccccc2-c2c(-c3ccc4c(c3)c3cc(-c5cc(-c6ccccc6)nc(-c6ccccc6)n5)ccc3n4-c3cccc(-c4ccccc4)c3)cccc21 ; c1cnc2c(-c3ccc(-n4c5ccccc5c5cc(-c6ccc7c(c6)oc6ccccc67)ccc54)cc3)cccc2c1 ; c1ccc(-c2cccc3c2sc2c(-c4ccc5c(c4)c4ccc6ccccc6c4n5-c4cc5ccccc5c5ncccc45)cccc23)cc1]

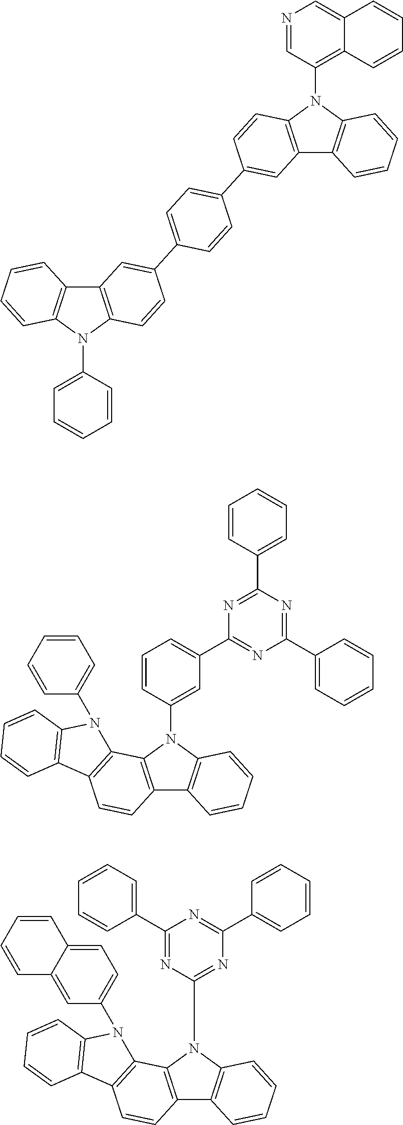 [SMILES: c1ccc(-n2c3ccccc3c3cc(-c4ccc(-c5ccc6c(c5)c5ccccc5n6-c5cncc6ccccc56)cc4)ccc32)cc1 ; c1ccc(-c2nc(-c3ccccc3)nc(-c3cccc(-n4c5ccccc5c5ccc6c7ccccc7n(-c7ccccc7)c6c54)c3)n2)cc1 ; c1ccc(-c2nc(-c3ccccc3)nc(-n3c4ccccc4c4ccc5c6ccccc6n(-c6ccc7ccccc7c6)c5c43)n2)cc1]

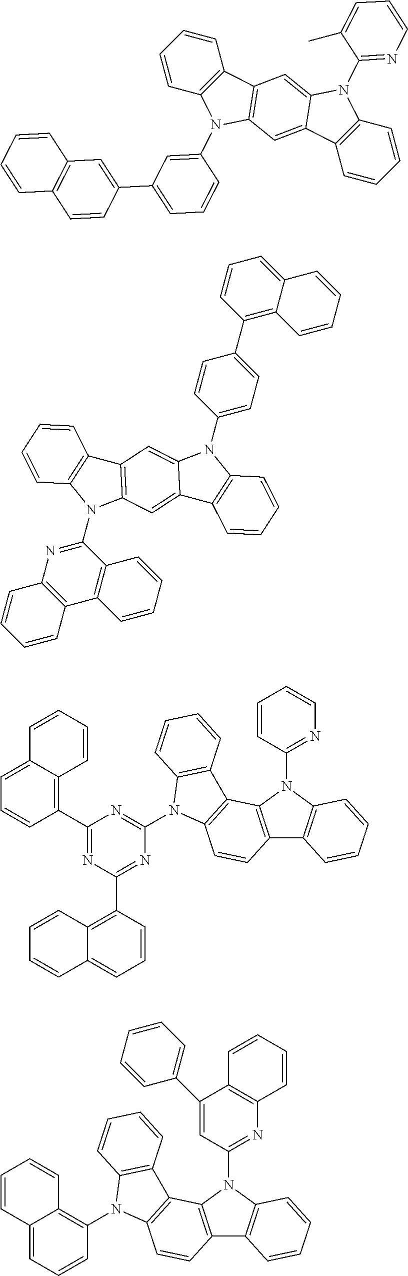 [SMILES: Cc1cccnc1-n1c2ccccc2c2cc3c(cc21)c1ccccc1n3-c1cccc(-c2ccc3ccccc3c2)c1 ; c1ccc2c(-c3ccc(-n4c5ccccc5c5cc6c(cc54)c4ccccc4n6-c4nc5ccccc5c5ccccc45)cc3)cccc2c1 ; c1ccc(-n2c3ccccc3c3ccc4c(c5ccccc5n4-c4nc(-c5cccc6ccccc56)nc(-c5cccc6ccccc56)n4)c32)nc1 ; c1ccc(-c2cc(-n3c4ccccc4c4ccc5c(c6ccccc6n5-c5cccc6ccccc56)c43)nc3ccccc23)cc1]

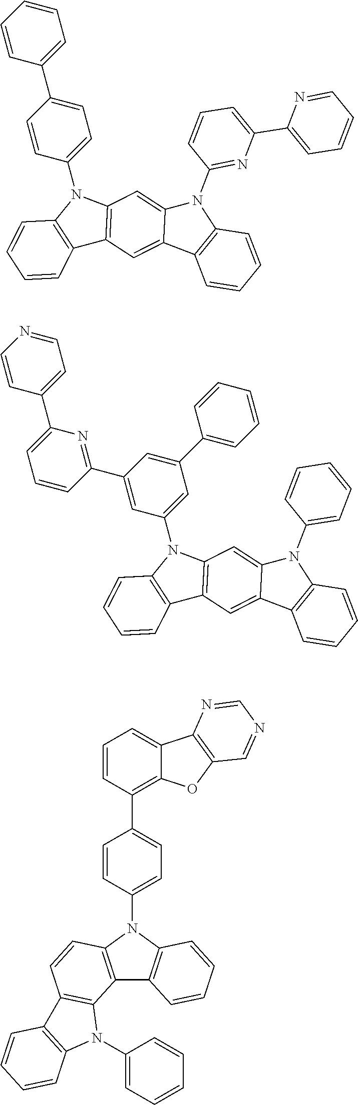 [SMILES: c1ccc(-c2ccc(-n3c4ccccc4c4cc5c6ccccc6n(-c6cccc(-c7ccccn7)n6)c5cc43)cc2)cc1 ; c1ccc(-c2cc(-c3cccc(-c4ccncc4)n3)cc(-n3c4ccccc4c4cc5c6ccccc6n(-c6ccccc6)c5cc43)c2)cc1 ; c1ccc(-n2c3ccccc3c3ccc4c(c5ccccc5n4-c4ccc(-c5cccc6c5oc5cncnc56)cc4)c32)cc1]

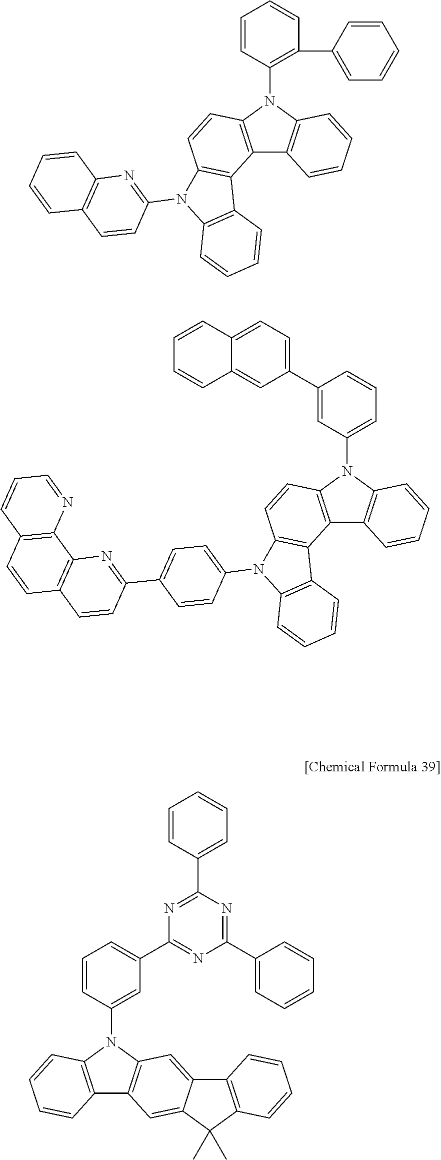 [SMILES: c1ccc(-c2ccccc2-n2c3ccccc3c3c4c5ccccc5n(-c5ccc6ccccc6n5)c4ccc32)cc1 ; c1cc(-c2ccc3ccccc3c2)cc(-n2c3ccccc3c3c4c5ccccc5n(-c5ccc(-c6ccc7ccc8cccnc8c7n6)cc5)c4ccc32)c1 ; CC1(C)c2ccccc2-c2cc3c(cc21)c1ccccc1n3-c1cccc(-c2nc(-c3ccccc3)nc(-c3ccccc3)n2)c1]

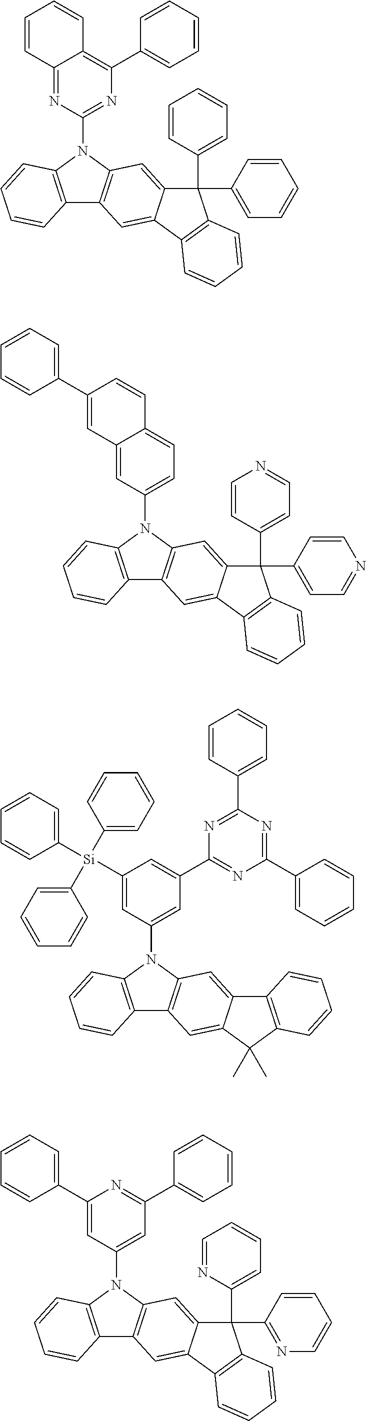 [SMILES: c1ccc(-c2nc(-n3c4ccccc4c4cc5c(cc43)C(c3ccccc3)(c3ccccc3)c3ccccc3-5)nc3ccccc23)cc1 ; c1ccc(-c2ccc3ccc(-n4c5ccccc5c5cc6c(cc54)C(c4ccncc4)(c4ccncc4)c4ccccc4-6)cc3c2)cc1 ; CC1(C)c2ccccc2-c2cc3c(cc21)c1ccccc1n3-c1cc(-c2nc(-c3ccccc3)nc(-c3ccccc3)n2)cc([Si](c2ccccc2)(c2ccccc2)c2ccccc2)c1 ; c1ccc(-c2cc(-n3c4ccccc4c4cc5c(cc43)C(c3ccccn3)(c3ccccn3)c3ccccc3-5)cc(-c3ccccc3)n2)cc1]

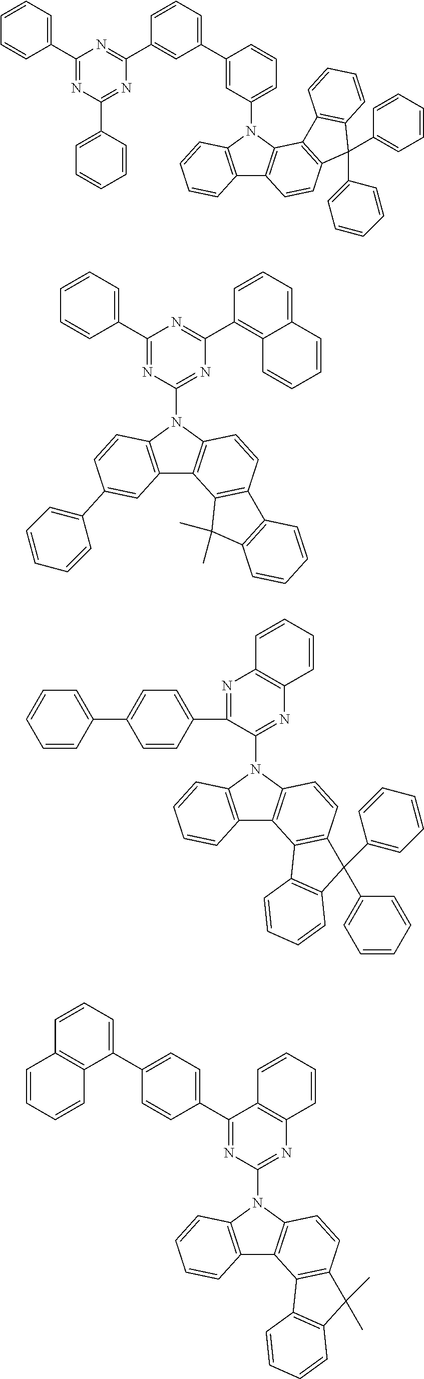

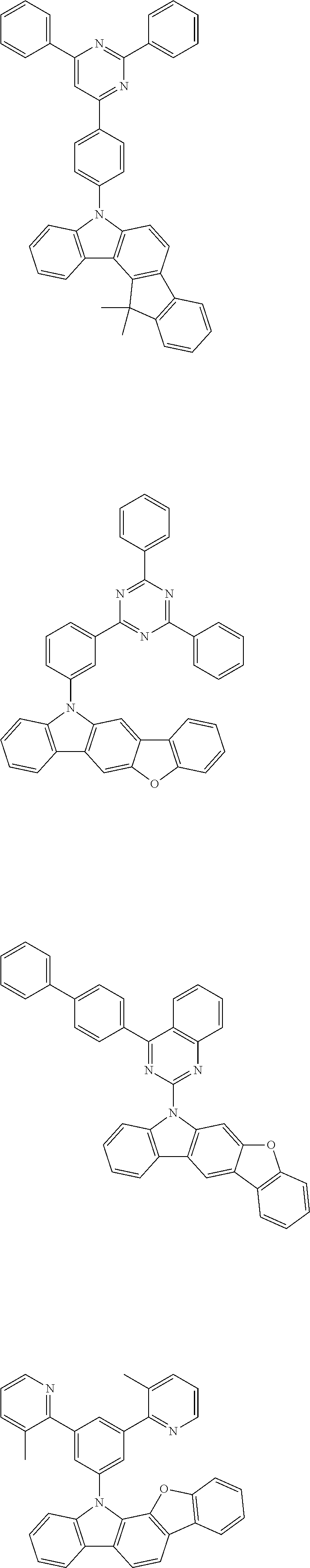 [SMILES: CC1(C)c2ccccc2-c2ccc3c(c21)c1ccccc1n3-c1ccc(-c2cc(-c3ccccc3)nc(-c3ccccc3)n2)cc1 ; c1ccc(-c2nc(-c3ccccc3)nc(-c3cccc(-n4c5ccccc5c5cc6oc7ccccc7c6cc54)c3)n2)cc1 ; c1ccc(-c2ccc(-c3nc(-n4c5ccccc5c5cc6c(cc54)oc4ccccc46)nc4ccccc34)cc2)cc1 ; Cc1cccnc1-c1cc(-c2ncccc2C)cc(-n2c3ccccc3c3ccc4c5ccccc5oc4c32)c1]

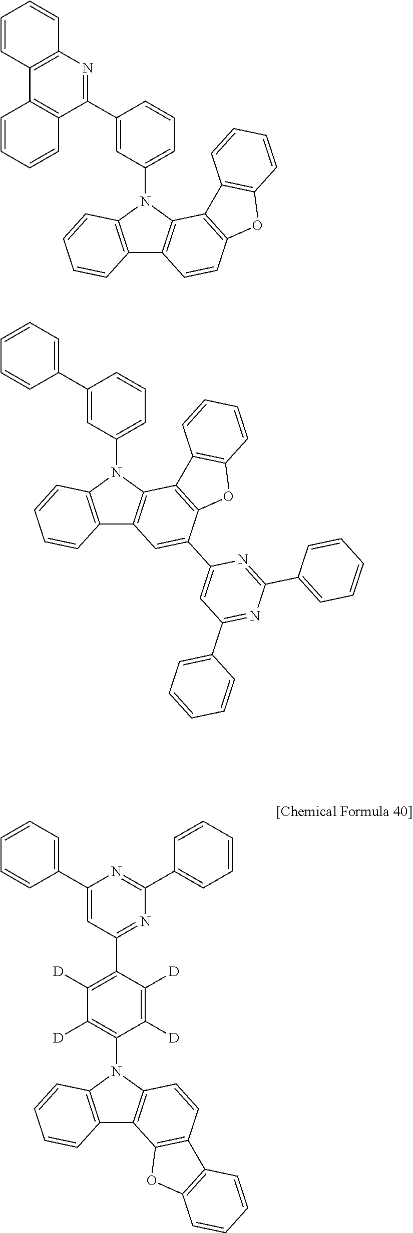 [SMILES: c1cc(-c2nc3ccccc3c3ccccc23)cc(-n2c3ccccc3c3ccc4oc5ccccc5c4c32)c1 ; c1ccc(-c2cccc(-n3c4ccccc4c4cc(-c5cc(-c6ccccc6)nc(-c6ccccc6)n5)c5oc6ccccc6c5c43)c2)cc1 ; [2H]c1c([2H])c(-n2c3ccccc3c3c4oc5ccccc5c4ccc32)c([2H])c([2H])c1-c1cc(-c2ccccc2)nc(-c2ccccc2)n1]

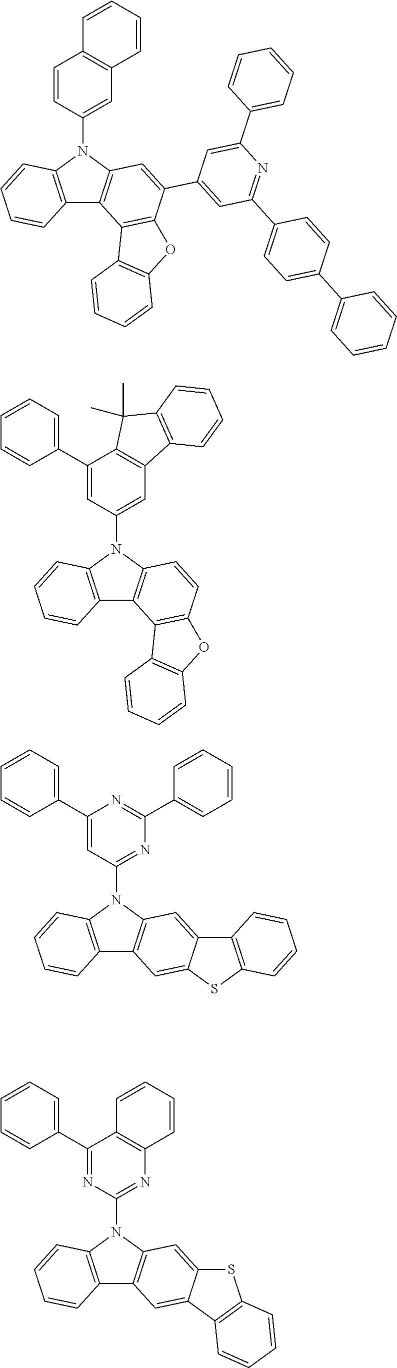

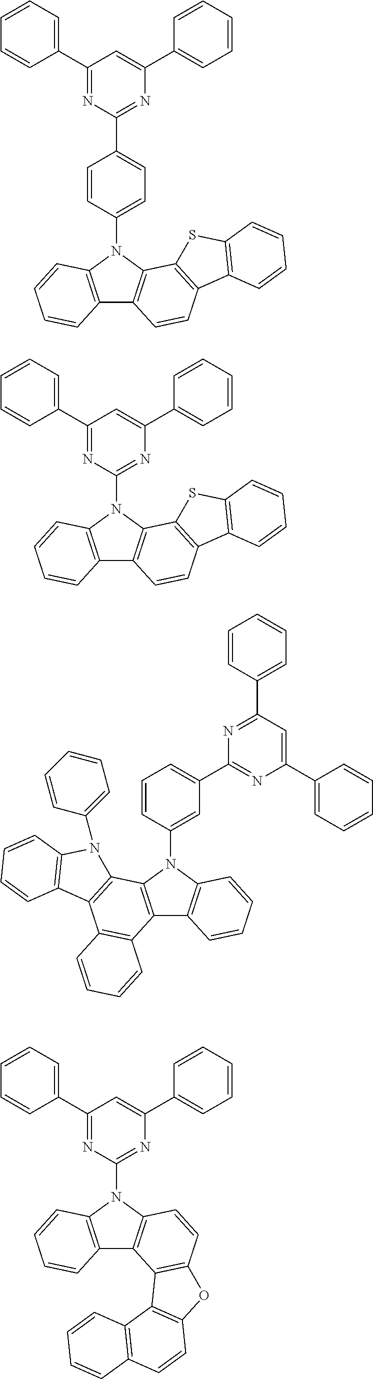

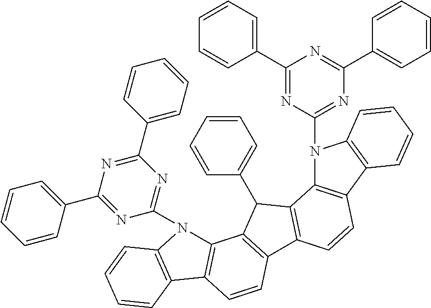 [SMILES: c1ccc(-c2nc(-c3ccccc3)nc(-n3c4ccccc4c4ccc5c(c43)C(c3ccccc3)c3c-5ccc4c5ccccc5n(-c5nc(-c6ccccc6)nc(-c6ccccc6)n5)c34)n2)cc1]

The third compound may be composed of either a single compound or two or more types of materials. When two or more types of materials are used as the third compound, it is preferable a combination of an electron transporting third compound and a hole transporting third compound. By combining the electron transporting third compound with the hole transporting third compound at an appropriate mixing ratio, the charge balance in the light emitting layer is adjusted and the bias of the light emitting region is suppressed, thus enabling an improvement in reliability and durability. An excited complex may be formed between the electron transporting third compound and the hole transporting third compound. From the above viewpoints, it is preferable to satisfy the relational expressions of inequalities 1 to 4, respectively, more preferable inequalities 1 and 2, and still more preferably inequalities 3 and 4. It is more preferable to satisfy all the inequalities 1 to 4.

S₁ (electron transporting third compound)>S₁ (first compound) (Inequality 1)

S₁ (hole transporting third compound)>S₁ (first compound) (Inequality 2)

T₁ (electron transporting third compound)>T₁ (first compound) (Inequality 3)

T₁ (hole transporting third compound)>T₁ (first compound) (Inequality 4)

where S₁represents the energy level of the lowest excited singlet state of each compound, and Tᵢ represents the energy level of the lowest excited triplet state of each compound.

Examples of the electron transporting third compound include compounds containing a Π-electron deficient heteroaromatic ring. Specific examples thereof include compounds having a polyazole skeleton, such as 2-(4-biphenyl)-5-(4-tert-butylphenyl)-1,3,4-oxadiazole (PBD), 3-(4-biphenylyl)-4-phenyl-5-(4-tert-butylphenyl)-1,2,4-triazole (TAZ), 1,3-bis[5-(p-tert-butylphenyl)-1,3,4-oxadiazol-2-yl]benzene (OXD-7), 9-[4-(5-phenyl-1,3,4-oxadiazol-2-yl)phenyl]-9H-carbazole (CO11), 2,2′,2″-(1,3,5-benzenetriyl)tris(1-phenyl-1H-benzoimidazole) (TPBI) and 2-[3-(dibenzothiophen-4-yl)phenyl]-1-phenyl-1H-benzoimidazole (mDBTBIm-II); heterocyclic compounds having a quinoxaline skeleton or a dibenzoquinoxaline skeleton, such as 2-[3-(dibenzothiophen-4-yl)phenyl]dibenzo[f,h]quinoxaline (2mDBTPDBq-II), 2-[3′-(dibenzothiophen-4-yl)biphenyl-3-yl]dibenzo[f,h]quinoxaline (2mDBTBPDBq-II), 2-[4-(3,6-diphenyl-9H-carbazol-9-yl)phenyl]dibenzo[f,h]quinoxaline (2CzPDBq-III), 7-[3-(dibenzothiophen-4-yl)phenyl]dibenzo[f,h]quinoxaline (7mDBTPDBq-II), 6-[3-(dibenzothiophen-4-yl)phenyl]dibenzo[f,h]quinoxaline (6mDBTPDBq-II) and 2-[3′-(9H-carbazol-9-yl)biphenyl-3-yl]dibenzo[f,h]quinoxaline (2mCzBPDBq); heterocyclic compounds having a diazine skeleton (pyrimidine skeleton or pyrazine skeleton), such as 4,6-bis[3-(phenanthren-9-yl)phenyl]pyrimidine (4,6mPnP2Pm), 4,6-bis[3-(9H-carbazol-9-yl)phenyl]pyrimidine (4,6mCzP2Pm) and 4,6-bis[3-(4-dibenzothienyl)phenyl]pyrimidine (4,6mDBTP2Pm-II); and heterocyclic compounds having a pyridine skeleton, such as 3,5-bis[3-(9H-carbazol-9-yl)phenyl]pyridine (3,5DCzPPy), 1,3,5-tri[3-(3-pyridyl)phenyl]benzene (TmPyPB) and 3,3′,5,5′-tetra[(m-pyridyl)-phen-3-yl]biphenyl (BP4mPy).

Examples of the hole transporting third compound include compounds containing a Π-electron excess heteroaromatic ring. Specific examples thereof include compounds having a carbazole skeleton, such as 1,3-bis(N-carbazolyl)benzene, 4,4′-di(N-carbazolyl)biphenyl (CBP), 3,3′-di(N-carbazolyl)biphenyl (mCBP), 1,3,5-tris[4-(N-carbazolyl)phenyl]benzene (TCPB), 9-[4-(10-phenyl-9-anthracenyl)phenyl]-9H-carbazole (CzPA), 1,4-bis[4-(N-carbazolyl)phenyl]-2,3,5,6-tetraphenylbenzene, 9-phenyl-9H-3-(9-phenyl-9H-carbazol-3-yl)carbazole, 3,6-bis[N-(9-phenylcarbazol-3-yl)-N-phenylamino]-9-phenylcarbazole (PCzPCA2), 3-[N-(1-naphthyl)-N-(9-phenylcarbazol-3-yl)amino]-9-phenylcarbazole (PCzPCN1), 9-([1,1-biphenyl]-4-yl)-9′-([1,1′:4′,1″-terphenyl]-4-yl)-9H,9′H-3,3′-bicarbazole, 9-([1,1′:4′,1″-terphenyl]-4-yl)-9′-(naphthalen-2-yl)-9H,9′H-3,3′-bicarbazole and 9,9′,9″-triphenyl-9H,9′H,9″H-3,3′:6′,3″-tricarbazole.

### (Electron Transporting Layer)

The electron transporting layer is a layer which injects electrons from the cathode and transports the electrons. It is required that the electron transporting material to be used for the electron transporting layer has high electron affinity, high degree of electron transfer, excellent stability, and which is less likely to generate impurities, which become traps. Since the low molecular weight compound is crystallized for example and the film quality easily deteriorates a compound having a molecular weight of 400 or more is preferable.

The electron transporting layer in embodiments of the present invention also includes, as a synonym, a hole blocking layer capable of efficiently blocking the transfer of holes. The hole blocking layer is provided between the light emitting layer and the electron transporting layer. The hole blocking layer and the electron transporting layer may be a single layer, or may be formed a plurality of materials.

Examples of the electron transporting material used for the electron transporting layer include polycyclic aromatic derivatives, styryl-based aromatic ring derivatives, quinone derivatives such, phosphorus oxide derivatives, and various metal complexes such as quinolinol complexes including tris(8-quinolinolato)aluminum(III), benzoquinolinol complexes, hydroxyazole complexes, azomethine complexes, tropolone metal complexes and flavonol metal complexes. It is preferable to use a compound having a heteroaryl group containing electron accepting nitrogen since the driving voltage is reduced and high efficiency emission can be obtained. Here, the electron accepting nitrogen represents a nitrogen atom forming a multiple bond with an adjacent atom. Since the heteroaryl group containing the electron-accepting nitrogen has high electron affinity, it becomes easy to inject electrons from the cathode, thus enabling lower voltage drive. The supply of electrons to the light emitting layer increases and the recombination probability is increased, leading to an improvement in luminance efficiency. Examples of compound having a heteroaryl group structure containing the electron-accepting nitrogen are preferably pyridine derivatives, triazine derivatives, pyrazine derivatives, pyrimidine derivatives, quinoline derivatives, quinoxaline derivatives, quinazoline derivatives, naphthyridine derivatives, benzoquinoline derivatives, phenanthroline derivative, imidazole derivatives, oxazole derivatives, triazole derivatives, triazole derivatives, oxadiazole derivatives, thiadiazole derivatives, benzimidazole derivatives, benzoxazole derivatives, benzthiazole derivatives, phenanthroimidazole derivatives, and oligopyridine derivatives such as bipyridine and terpyridine. Of these, imidazole derivatives such as tris(N-phenylbenzimidazol-2-yl)benzene; oxadiazole derivatives such as 1,3-bis[(4-tert-butylphenyl)1,3,4-oxadiazolyl]phenylene; triazole derivatives such as N-naphthyl-2,5-diphenyl-1,3,4-triazole; phenanthroline derivatives such as bathocuproine and 1,3-bis(1,10-phenanthrolin-9-yl)benzene; benzoquinoline derivatives such as 2,2′-bis(benzo[h]quinolin-2-yl)-9,9′-spirobifluorene; bipyridine derivatives such as 2,5-bis(6′-(2′,2″-bipyridyl))-1,1-dimethyl-3,4-diphenylsilole; terpyridine derivatives such as 1,3-bis(4′-(2,2′:6′2″-terpyridinyl))benzene; naphthyridine derivatives such as bis(1-naphthyl)-4-(1,8-naphthylidin-2-yl)phenylphosphine oxide; and triazine derivatives are preferably used from the viewpoint of the electron transporting ability.

These derivatives more preferably have a fused polycyclic aromatic skeleton since the glass transition temperature is improved and the degree of electron transfer increases, resulting in a larger effect of lowering the voltage of the light emitting element. Such fused polycyclic aromatic skeleton is more preferably a fluoranthene skeleton, an anthracene skeleton, a pyrene skeleton or a phenanthroline skeleton, and particularly preferably a fluoranthene skeleton or a phenanthroline skeleton.

The electron transporting material may be used alone, or two or more thereof may be mixed and used. The electron transporting material may also contain a donor compound. Here, the donor compound is a compound which facilitates electron injection from the cathode or the electron injection layer to the electron transporting layer by improving the electron injection barrier, and which further improves the electrical conductivity of the electron transporting layer.

Preferred examples of donor compound include alkali metals such as Li; inorganic salts containing alkali metals, such as LiF; complexes of alkali metals and organic substances, such as lithium quinolinol; alkaline earth metals; inorganic salts containing alkaline earth metals; complexes of alkaline earth metals and organic substances; rare earth metals such as Eu and Yb; inorganic salts containing rare earth metals; complexes of rare earth metals and organic substances, and the like. As the donor material, metallic lithium, rare earth metals or lithium quinolinol (Liq) is particularly preferable.

### (Electron Injection Layer)

In the present invention, an electron injection layer may be provided between the cathode and the electron transporting layer. Generally, the electron injection layer is formed for the purpose of assisting the injection of electrons from the cathode into the electron transporting layer, and is composed of a compound having a heteroaryl ring structure containing electron accepting nitrogen and the above donor material. A phenanthroline derivative represented by the general formula (30) mentioned later is preferable.

It is also possible to use an insulator or a semiconductor inorganic substance for the electron injection layer. It is preferable to use these materials since it is possible to prevent a short circuit of the light emitting element and improve the electron injection property.

It is preferable to use, as such insulator, at least one metal compound selected from the group consisting of alkali metal chalcogenides, alkaline earth metal chalcogenides, alkali metal halides and alkaline earth metal halides.

### (Charge Generation Layer)

The charge generation layer in the present invention may be formed by a single layer or may be formed by laminating a plurality of layers. In general, a layer which easily generates electrons as a charge is called an n-type charge generation layer, and a layer which easily generates holes is called a p-type charge generation layer. The charge generation layer is preferably composed of a double layer. Specifically, it is preferable to use as a pn junction charge generation layer composed of an n-type charge generation layer and a p-type charge generation layer. The pn junction charge generation layer generates a charge when a voltage is applied in the light emitting element, or separates the charge into holes and electrons, and these holes and electrons are injected into the light emitting layer through the hole transporting layer and the electron transporting layer. Specifically, the charge generation layer functions as an intermediate layer in a light emitting element in which a plurality of light emitting layers are laminated. The n-type charge generation layer supplies electrons to the first light emitting layer existing on the anode side, and the p-type charge generation layer supplies holes to the second light emitting layer existing on the cathode side. Therefore, it is possible to improve the luminance efficiency in the light emitting element in which a plurality of light emitting layers are laminated and to reduce the driving voltage, leading to an improvement in durability of the element.

The n-type charge generation layer is composed of an n-type dopant and a host, and conventional materials can be used for them. The ratio of the host to the n-type dopant (host/n-type dopant) is preferably in the range of 99.5/0.5 to 50/50, and more preferably 99/1 to 90/10. As the n-type dopant, the above donor material is preferably used, and specifically, alkali metals, alkaline earth metals or rare earth metals can be used. Of these, alkali metals or salts thereof, or rare earth metals are preferable, and metallic lithium, lithium fluoride (LiF), lithium quinolinol (Liq) or metallic ytterbium is more preferable. As the host, the electron transporting material used for the above electron transporting layer is preferably used, and of these, triazine derivatives, phenanthroline derivatives and oligopyridine derivatives are preferably used, and phenanthroline derivatives represented by the general formula (30) are more preferable.

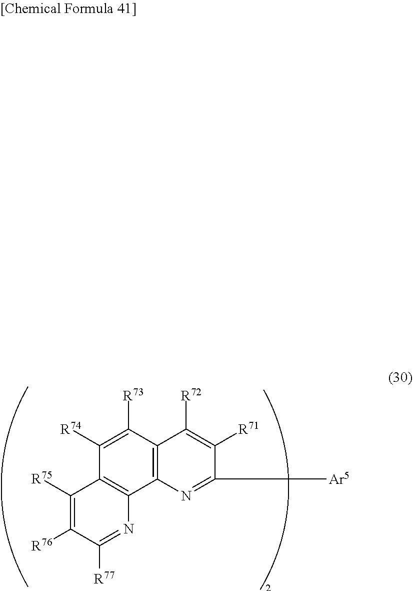

Ar⁵ is an aryl group substituted with two phenanthrolyl groups. The substitution position is any position. This aryl group may have another substituent at other positions. The aryl group is preferably selected from a phenyl group, a naphthyl group, a phenanthryl group, a pyrenyl group and a fluorenyl group from the viewpoint of ease of synthesis and sublimation.

R⁷¹ to R⁷⁷ each may be the same or different, and are selected from a hydrogen atom, an alkyl group, a cycloalkyl group, a heterocyclic group, an aryl group and a heteroaryl group. In particular, from the viewpoint of the compound stability and ease of charge transfer, they are preferably selected from a hydrogen atom, an alkyl group, an aryl group and a heteroaryl group.

Examples of the phenanthroline derivative represented by the general formula (30) include the following.

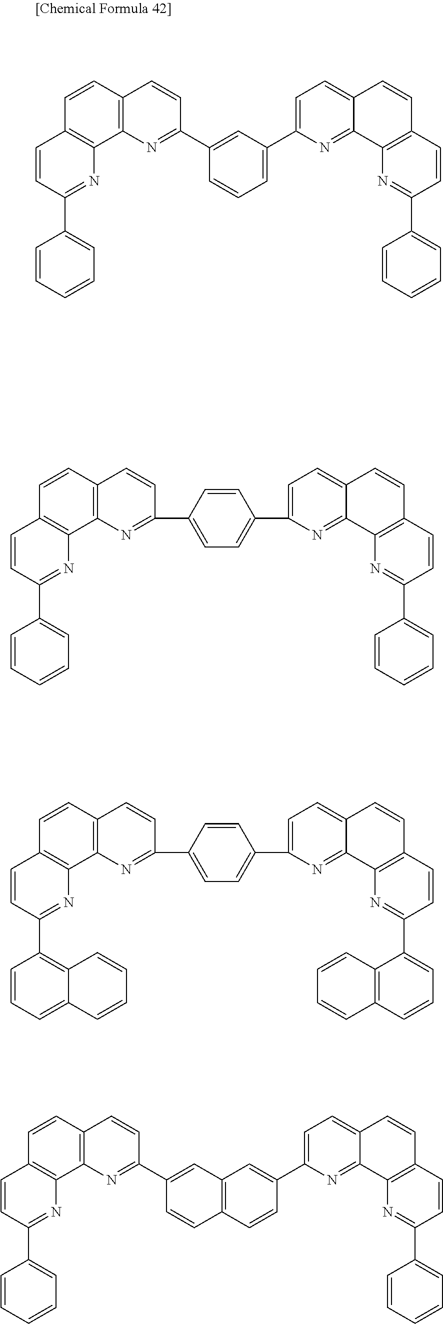

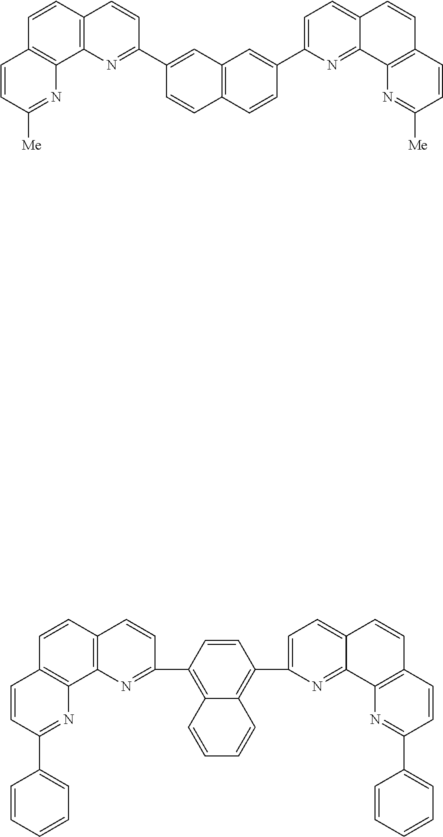

The p-type charge generation layer is composed of a p-type dopant and a host, and conventional materials can be used for them. For example, as the p-type dopant, the acceptor compound used in the above hole injection layer is preferably used. Specifically, 1,4,5,8,9,11-hexaazatriphenylene-hexacarbonitrile (HAT-CN6), tetrafluoro-7,7,8,8-tetracyanoquinodimethane (F4-TCNQ)), tetracyanoquinodimethane derivatives, radialene derivatives, iodine, FeCl₃, FeF₃, and SbCl₅ and the like can be used. Particularly preferred are 1,4,5,8,9,11-hexaazatriphenylene-hexacarbonitrile (HAT-CN6), or radialene derivatives such as (2E,2′E,2″E)-2,2′,2″-(cyclopropane-1,2,3-triylidene)tris(2-(perfluorophenyl)-acetonitrile) and (2E,2′E,2″E)-2,2′,2″-(cyclopropane-1,2,3-triylidene)tris(2-(4-cyanoperfluorophenyl)-acetonitrile). The acceptor compound may form a thin film alone. In this case, it is more preferable that the thin film of the acceptor compound has a thickness of 10 nm or less. The host is preferably an arylamine derivative.

### (Method for Forming Light Emitting Element)

The method of forming each of the above layers constituting the light emitting element may be either a dry process or a wet process, and it is possible to use resistance heating vapor deposition, electron beam vapor deposition, sputtering, molecular lamination, coating, ink jet method, printing method and the like. Usually, resistance heating vapor deposition is preferable in view of the element characteristics, although there is no particular limitation.

The thickness of the organic layer depends on the resistance value of the fluorescent substance and cannot be limited, but is preferably 1 to 1,000 nm. Each thicknesses of the light emitting layer, the electron transporting layer and the hole transporting layer is preferably 1 nm or more and 200 nm or less, and more preferably 5 nm or more and 100 nm or less.

### (Characteristics of Light Emitting Element)

The light emitting element according to the embodiment of the present invention has a function capable of converting electrical energy into light. For the electrical energy herein, the direct current is mainly used, but the pulse current and alternating current can also be used. The current value and voltage value are not particularly limited, but it is preferable to obtain high luminance with the low voltage from the viewpoint of the power consumption and life of the element.

The light emitting element according to the embodiment of the present invention preferably emits red light having a peak wavelength of 580 nm or more and 750 nm or less when energized. From the viewpoint of expanding the color gamut and improving the color reproducibility, the peak wavelength is preferably in the region of 600 nm or more and 650 nm or less, and more preferably 600 nm or more and 640 nm or less.

In the light emitting element according to the embodiment of the present invention, from the viewpoint of enhancing the color purity, the half width of the light emission spectrum by energization is preferably 60 nm or less, more preferably 50 nm or less, and still more preferably 45 nm or less.

Since the light emitting element of the present invention has narrow half width of the emission spectrum, it is more preferable to use it for the top-emission type light emitting element as mentioned above. Due to the resonance effect of the microcavity, the top-emission type light emitting element has higher luminance efficiency as the half width is narrower. Therefore, it becomes possible to achieve both high color purity and high luminance efficiency.

### (Applications of Light Emitting Element)

The light emitting element of the present invention is suitably used, for example, as display devices such as displays based on a matrix and/or segment system.

The light emitting element of the present invention is also preferably used as a backlight for various devices and the like. The backlight is mainly used for the purpose of improving the visibility of display devices which does not emit light by itself, such as displays, and is used in display devices such as liquid crystal displays, clocks, audio devices, automobile panels, display boards and signs. In particular, the light emitting element of the present invention is preferably used for a liquid crystal display, particularly for a backlight for personal computers which have been attempted to be thinner, and can provide a backlight which is thinner and lighter than the conventional one.

The light emitting element according to the embodiment of the present invention is also preferably used as various lighting devices. The light emitting element according to the embodiment of the present invention can achieve both high efficiency emission and high color purity, and can provide thinner and lighter devices. Therefore, an illumination device with low power consumption, bright emission colors and excellent designability can be realized.

### EXAMPLES

The present invention will be described below by way of Examples, but the present invention is not limited to these Examples.

### Synthesis Example 1

### Method for Synthesizing Compound D-A

After dissolving 2.5 g of pyrrole (20-1) and 0.64 g of 2,4,6-trimethylbenzaldehyde in 50 ml of dichloromethane, 10 drops of trifluoroacetic acid were added thereto, followed by stirring at 25° C. for 24 hours under a nitrogen gas stream stirring. After adding water, the organic layer was separated and washed with 50 ml of saturated saline, and then magnesium sulfate was added, followed by filtration. The solvent was removed from the filtrate using an evaporator to obtain pyrromethane (20-2) as the residue.

The pyrromethane (20-2) thus obtained was dissolved in 50 ml of 1,2-dichloroethane and 1.0 g of DDQ was added, followed by stirring at room temperature for 2 hours under a nitrogen gas stream. Subsequently, 5 ml of diisopropylethylamine and 3.5 ml of a boron trifluoride diethyl ether complex were added, followed by stirring at 80° C. for 1 hour. After cooling the reaction solution to room temperature, 50 ml of water was injected, followed by extraction with 50 ml of ethyl acetate. The organic layer was washed with 50 ml of water and magnesium sulfate was added, followed by filtration. The solvent was removed from the filtrate using an evaporator, and the residue was subsequently purified by silica gel column chromatography (heptane/toluene=½). Further, 50 ml of methanol was added to the concentrated purified product and, after heating and stirring at 60° C. for 10 minutes and allowing to cool, the precipitated solid was filtered and vacuum-dried to obtain 1.7 g of a reddish purple powder. The powder thus obtained was analyzed by a high performance liquid chromatograph NexeraX2/quadrupole mass spectrometer LCMS-2020 (manufactured by Shimadzu Corporation, the same applies hereinafter), thus confirming that the reddish purple powder is a compound D-1 which is a pyrromethene metal complex.

### Compound D-1:MS(m/z) Molecular Weight; 754

The emission characteristics of the compound D-1 in the solution were measured as follows. First, the compound D-1 was dissolved in toluene to prepare a diluted solution of 1.0×10⁻⁵ mol/L. Next, this diluted solution was injected into a 1 cm square quartz glass cell. Subsequently, a cell containing this diluted solution was placed at a predetermined site of each apparatus, and then the emission characteristics were evaluated. Specifically, the absorption spectrum of light in the wavelength range of 300 to 800 nm was measured using a spectrophotometer U-3010 (manufactured by Hitachi High-Tech Science Corporation) and the emission spectrum of excitation light at 450 nm was measured using a fluorescence phosphorescence spectrophotometer FluoroMax-4P (manufactured by HORIBA, Ltd.), and then the fluorescence quantum yield of excitation light at 540 nm was measured using a fluorescence quantum yield measuring device C11347-01 (manufactured by Hamamatsu Photonics K.K.).

Absorption spectrum (solvent: toluene): λmax 572 nm
Emission spectrum (solvent: toluene): λmax 606 nm, half width 36 nm
Fluorescence quantum yield (solvent: toluene, excitation light: 540 nm): 95%

To further enhance the purity, sublimation purification was performed by the following method. A metal container containing a compound D-1 was placed in a glass tube, followed by heating at 270° C. under reduced pressure of 1×10⁻³ Pa using an oil diffusion pump, leading to sublimation. The solid adhering to the glass tube wall was recovered, thus confirming that the purity by LC-MS analysis is 99%.

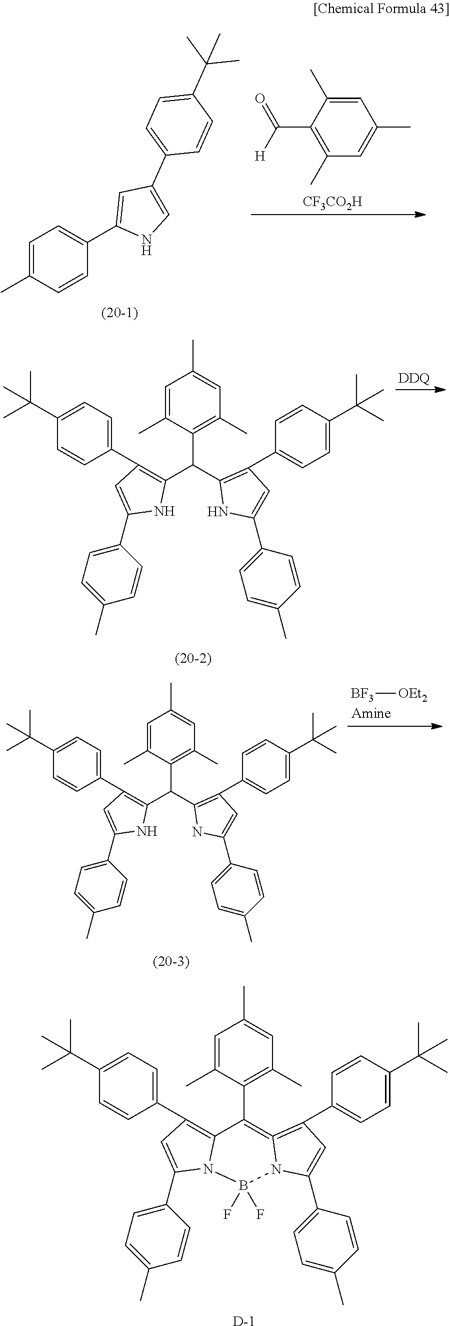

### Synthesis Example 2

### Method for Synthesizing Compound D-2

A mixed solution of 1.3 g of pyrrole (21-1), 0.71 g of 2,4,6-trimethylbenzoyl chloride and 70 ml of o-xylene was heated and stirred at 130° C. for 5 hours under a nitrogen gas stream. After cooling to room temperature, methanol was added, and then the precipitated solid was filtered and vacuum-dried to obtain 1.8 g of ketopyrrole (21-2).

Next, a mixed solution of 1.8 g of ketopyrrole (21-2), 1.1 g of pyrrole (21-3), 0.83 g of trifluoromethanesulfonic anhydride and 30 ml of toluene was heated and stirred at 110° C. for 6 hours under a nitrogen gas stream. After cooling to room temperature, 50 ml of water was injected, followed by extraction with 50 ml of ethyl acetate. The organic layer was washed with 50 ml of water and magnesium sulfate was added, followed by filtration. The solvent was removed from the filtrate using an evaporator to obtain a pyrromethene compound (21-4) as the residue.

Subsequently, 5 ml of diisopropylethylamine and 3.5 ml of a boron trifluoride diethyl ether complex were added to a mixed solution of the pyrromethene compound thus obtained and 60 ml of toluene under a nitrogen gas stream, followed by stirring at 80° C. for 1 hour. Subsequently, 50 ml of water was injected, followed by extraction with 50 ml of ethyl acetate. The organic layer was washed with 50 ml of water and magnesium sulfate was added, followed by filtration. The solvent was removed from the filtrate using an evaporator, and then the residue was subsequently purified by silica gel column chromatography (heptane/toluene=½). Further, 50 ml of methanol was added to the concentrated purified product and, after heating and stirring at 60° C. for 10 minutes and allowing to cool, the precipitated solid was filtered and vacuum-dried to obtain 1.6 g of a reddish purple powder. The powder thus obtained was analyzed by LC-MS, thus confirming that the reddish purple powder is a compound D-2 which is a pyrromethene metal complex.

### Compound D-2: MS(m/z) Molecular Weight; 813

The emission characteristics of the compound D-2 in the solution were measured in the same manner as in the method of the compound D-1.

Absorption spectrum (solvent: toluene): λmax 584 nm
Emission spectrum (solvent: toluene): λmax 619 nm, half width 38 nm
Fluorescence quantum yield (solvent: toluene, excitation light: 540 nm): 95%

For further purification, sublimation purification was performed in the same manner as in the compound D-1, thus confirming that the purity by LC-MS analysis is 99%.

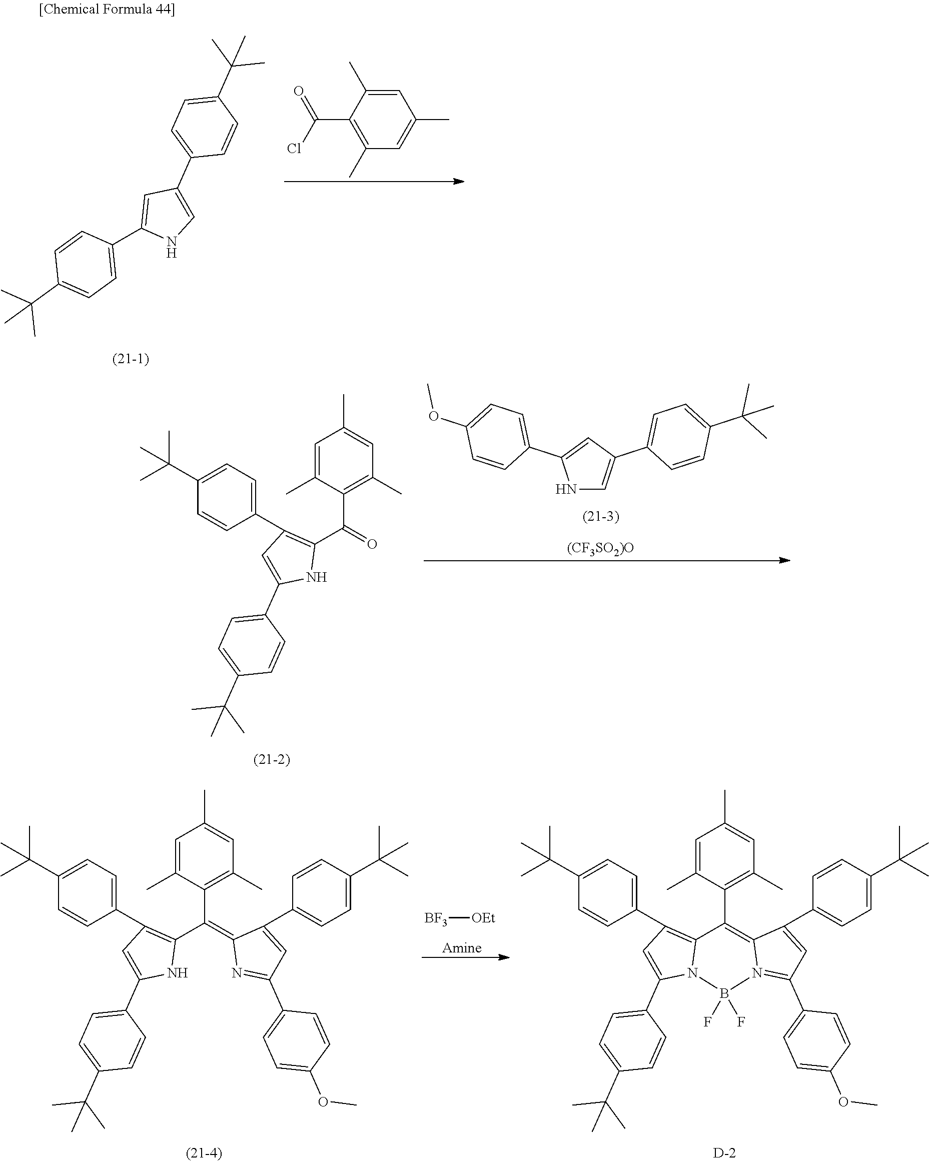

The pyrromethene metal complexes used in the following Examples and Comparative Examples are compounds shown below. The molecular weight and emission characteristics of these pyrromethene metal complex compounds in a toluene solution are shown in Table 1.

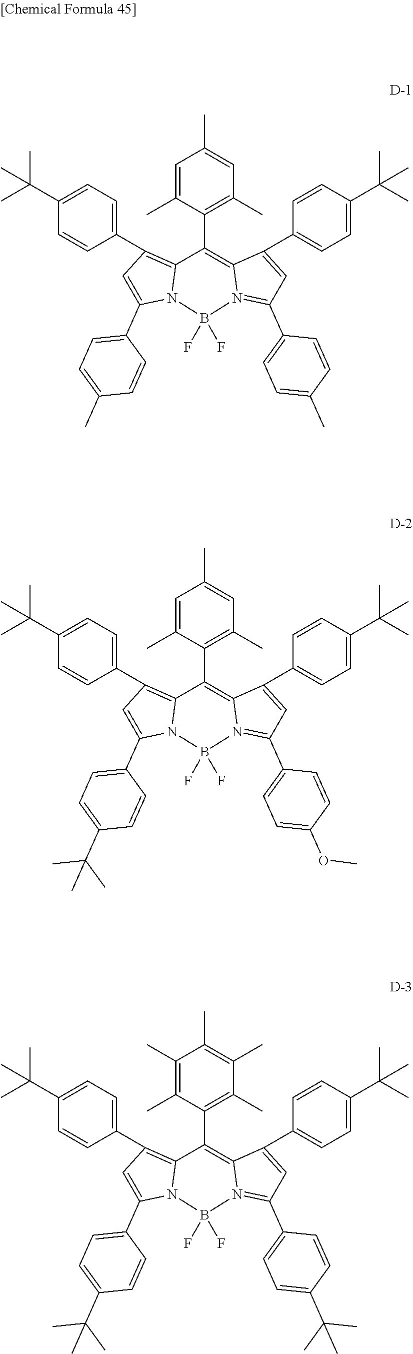

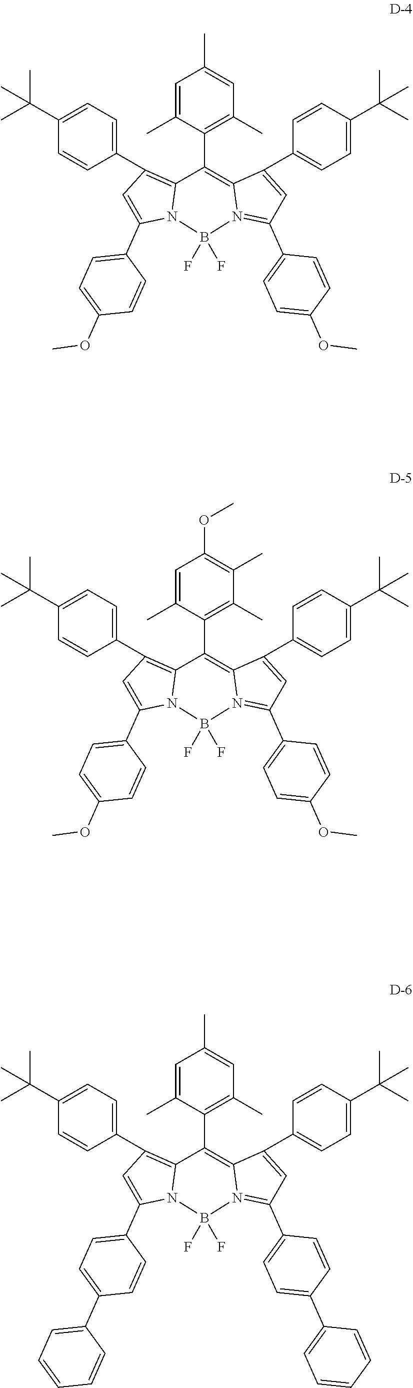

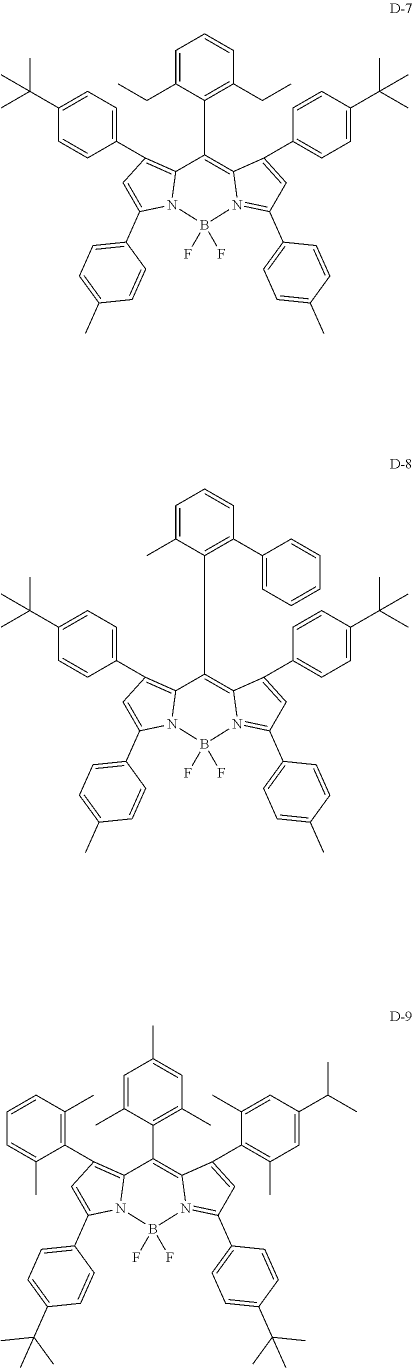

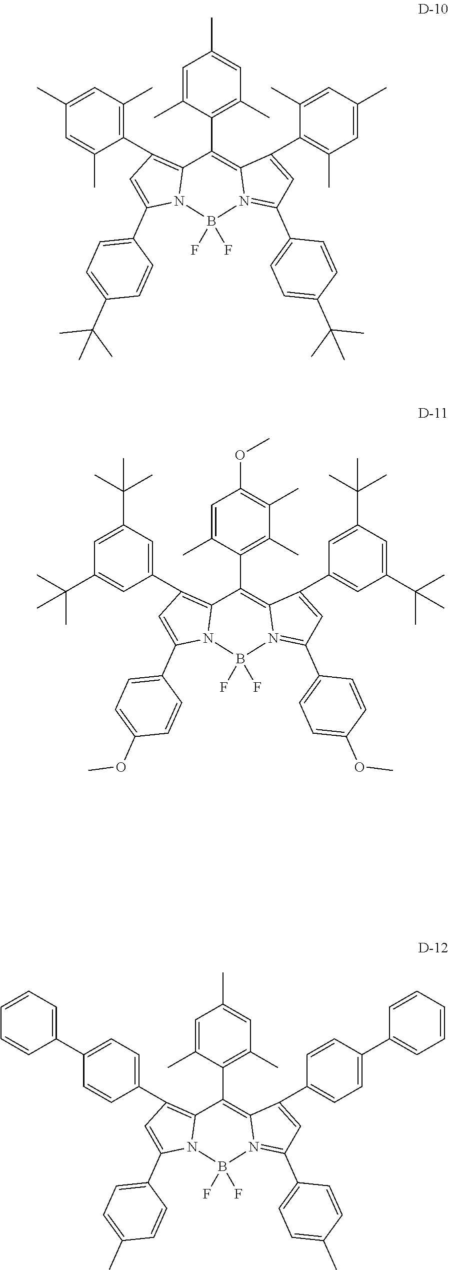

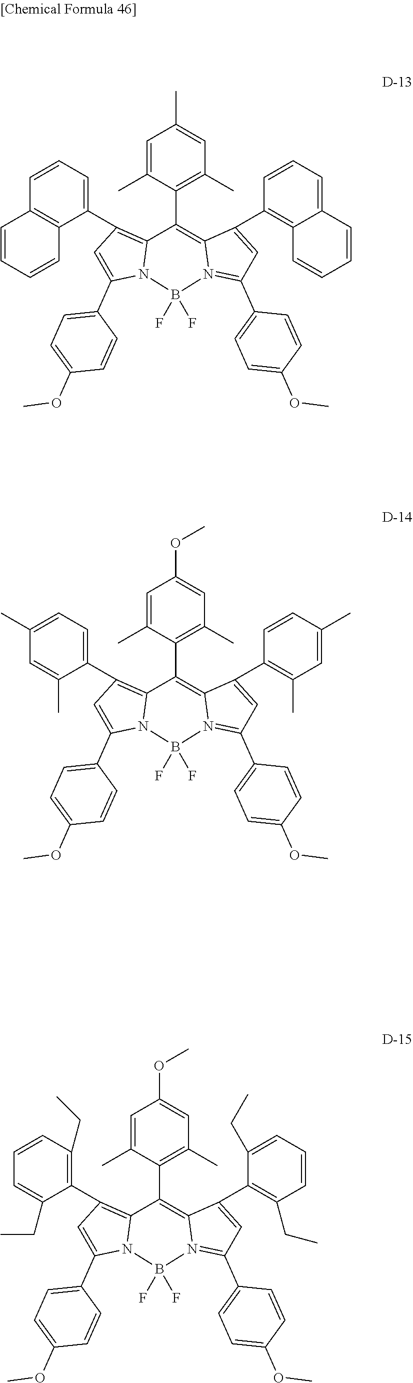

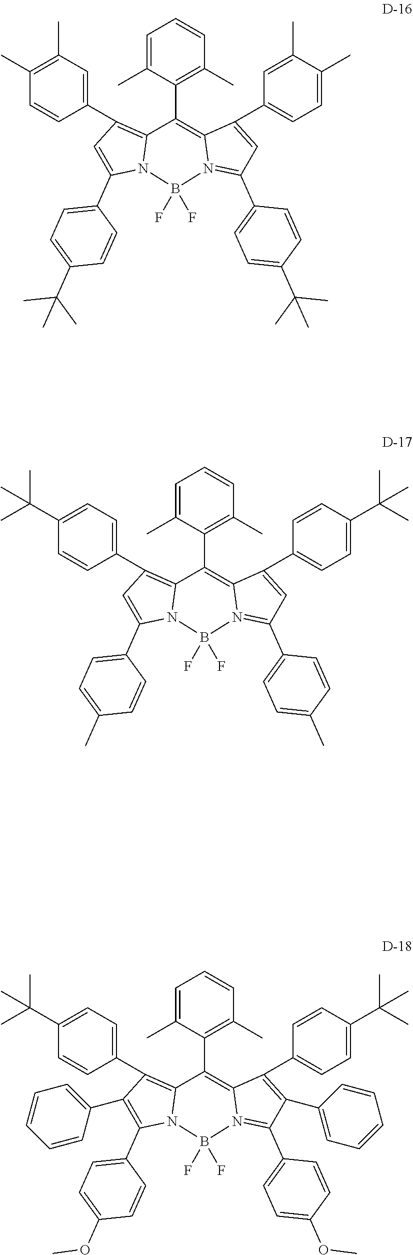

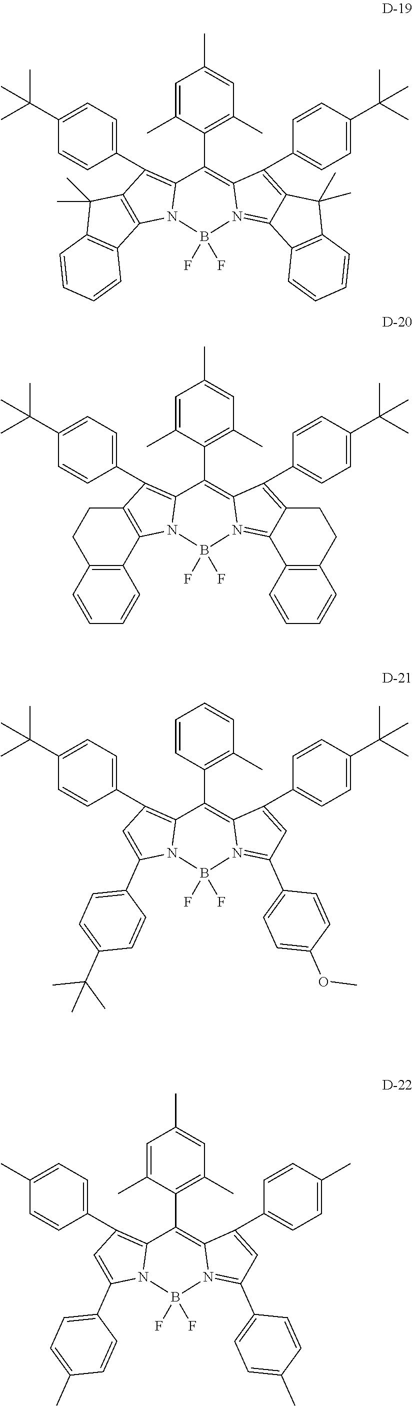

TABLE 1

| | | | | | Fluorescence |
|---|---|---|---|---|---|
| | Molecular | Absorption spectrum | Emission spectrum | | quantum yield |
| Compound | weight | λmax (nm) | λmax (nm) | Half width (nm) | QY (%) |
| D-1 | 754 | 572 | 606 | 36 | 95 |
| D-2 | 813 | 584 | 619 | 38 | 95 |
| D-3 | 867 | 585 | 610 | 36 | 96 |
| D-4 | 787 | 589 | 626 | 38 | 95 |
| D-5 | 817 | 588 | 622 | 37 | 96 |
| D-6 | 879 | 588 | 625 | 38 | 96 |
| D-7 | 769 | 575 | 609 | 42 | 95 |
| D-8 | 803 | 572 | 608 | 38 | 97 |
| D-9 | 783 | 576 | 610 | 37 | 95 |
| D-10 | 811 | 577 | 611 | 37 | 95 |
| D-11 | 929 | 587 | 622 | 36 | 96 |
| D-12 | 795 | 575 | 610 | 41 | 95 |
| D-13 | 775 | 589 | 625 | 42 | 95 |
| D-14 | 747 | 588 | 623 | 39 | 94 |
| D-15 | 803 | 585 | 620 | 42 | 93 |
| D-16 | 769 | 576 | 612 | 38 | 92 |
| D-17 | 769 | 560 | 598 | 36 | 96 |
| D-18 | 925 | 592 | 630 | 45 | 93 |
| D-19 | 807 | 631 | 645 | 25 | 95 |
| D-20 | 779 | 629 | 646 | 30 | 95 |
| D-21 | 727 | 572 | 608 | 41 | 89 |
| D-22 | 671 | 570 | 604 | 36 | 90 |

### Example 1

### (Measurement of Fluorescence Quantum Yield of Doped Thin Film)

A quartz glass plate (10×10 mm) was subjected to ultrasonic cleaning for 15 minutes using “Semico Clean 56” (trade name, manufactured by Furuuchi Chemical Corporation), washed with ultrapure water and then dried. This glass plate was subjected to a UV-ozone treatment for 1 hour immediately before the fabrication of the element, and placed in a vacuum vapor deposition apparatus, followed by air exhaustion until the degree of vacuum in the apparatus became 5×10⁻⁴ Pa or less. By the resistance heating method, mCBP as a host material and a compound D-1 as a dopant material were vapor-deposited a thickness of 500 nm so that the doping concentration became 1% by weight, thus obtaining a 1% by weight doped thin film. By the same method, a 2% by weight doped thin film and a 4% by weight doped thin film were obtained.

The emission spectrum of the 1% by weight doped thin film thus fabricated was determined as excitation light of 450 nm using a fluorescence phosphorescence spectrophotometer FluoroMax-4P (manufactured by HORIBA, Ltd.)

Emission Peak Wavelength: λmax 612 nm, half width 43 nm

For each of doped thin films with doping concentration of 1% by weight, 2% by weight and 4% by weight, the fluorescence quantum yield of excitation light at 540 nm was determined using a fluorescence quantum yield measuring device C11347-01 (manufactured by Hamamatsu Photonics K.K.). The ratio of the fluorescence quantum yield at each doping concentration, when the fluorescence quantum yield with the doping concentration of 1% was set at 1, was calculated by the following equation as the QY ratio:

ti QY ratio=(fluorescence quantum yield of thin film with doping concentration x% by weight)/(fluorescence quantum yield of thin film with doping concentration of 1% by weight)
where x=1, 2 or 4.

The results are shown below.

Doping concentration of 1% by weight; fluorescence quantum yield of 78%, QY ratio=1
Doping concentration of 2% by weight; fluorescence quantum yield of 77%, QY ratio=0.99
Doping concentration of 4% by weight; fluorescence quantum yield of 70%, QY ratio=0.90

### Examples 2 to 20, Comparative Examples 1 to 2

The emission spectrum, fluorescence quantum yield and QY ratio of the doped thin film were determined in the same manner as in Example 1, except that each compound shown in Table 2 was used in place of the compound D-1 as the dopant material. The results are shown in Table 2.

TABLE 2

| | | Emission spectrum | | Fluorescence quantum | | | | | |
|---|---|---|---|---|---|---|---|---|---|
| | | [1% doped thin film] | | yield [thin film] (%) | | | QY ratio | | |
| | | λmax | Half width | 1% | 2% | 4% | 1% | 2% | 4% |
| | Compound | (nm) | (nm) | doping | doping | doping | doping | doping | doping |
| Example 1 | D-1 | 612 | 43 | 78 | 77 | 70 | 1 | 0.99 | 0.90 |
| Example 2 | D-2 | 627 | 46 | 77 | 76 | 66 | 1 | 0.99 | 0.86 |
| Example 3 | D-3 | 618 | 45 | 80 | 79 | 74 | 1 | 0.99 | 0.93 |
| Example 4 | D-4 | 632 | 45 | 78 | 77 | 69 | 1 | 0.99 | 0.88 |
| Example 5 | D-5 | 630 | 44 | 79 | 78 | 73 | 1 | 0.99 | 0.92 |
| Example 6 | D-6 | 632 | 45 | 79 | 78 | 71 | 1 | 0.99 | 0.90 |
| Example 7 | D-7 | 619 | 49 | 76 | 75 | 66 | 1 | 0.99 | 0.87 |
| Example 8 | D-8 | 616 | 46 | 82 | 80 | 75 | 1 | 0.98 | 0.91 |
| Example 9 | D-9 | 617 | 45 | 77 | 76 | 68 | 1 | 0.99 | 0.88 |
| Example 10 | D-10 | 618 | 45 | 78 | 77 | 69 | 1 | 0.99 | 0.88 |
| Example 11 | D-11 | 630 | 45 | 79 | 78 | 73 | 1 | 0.99 | 0.92 |
| Example 12 | D-12 | 619 | 48 | 77 | 76 | 68 | 1 | 0.99 | 0.88 |
| Example 13 | D-13 | 631 | 49 | 77 | 76 | 69 | 1 | 0.99 | 0.90 |
| Example 14 | D-14 | 629 | 46 | 75 | 72 | 64 | 1 | 0.96 | 0.85 |
| Example 15 | D-15 | 626 | 49 | 74 | 72 | 63 | 1 | 0.97 | 0.85 |
| Example 16 | D-16 | 620 | 46 | 73 | 70 | 61 | 1 | 0.96 | 0.84 |
| Example 17 | D-17 | 606 | 44 | 79 | 78 | 69 | 1 | 0.99 | 0.87 |
| Example 18 | D-18 | 637 | 50 | 73 | 71 | 61 | 1 | 0.97 | 0.84 |
| Example 19 | D-19 | 652 | 29 | 77 | 75 | 66 | 1 | 0.97 | 0.86 |
| Example 20 | D-20 | 651 | 33 | 77 | 76 | 66 | 1 | 0.99 | 0.86 |
| Comparative | D-21 | 616 | 47 | 70 | 64 | 52 | 1 | 0.91 | 0.74 |
| Example 1 | | | | | | | | | |
| Comparative | D-22 | 612 | 43 | 70 | 68 | 57 | 1 | 0.97 | 0.81 |
| Example 2 | | | | | | | | | |

As is apparent from Table 2, the fluorescence quantum yields of the doped thin film all the Examples 1 to 20 are higher than those of Comparative Examples 1 and 2. It is also apparent that the QY ratios of all the Examples 1 to 20 are larger than those of Comparative Examples 1 and 2, and the fluorescence quantum yield is slightly reduced due to an increase in doping concentration, in other words, the dependence on the doping concentration decreases.

### Example 21

### (Evaluation of Fluorescent Emitting Element)

A glass substrate (manufactured by GEOMATEC Co., Ltd., 11 Ω/□, sputtered product) on which an ITO transparent conductive film was deposited in a thickness of 165 nm was cut into a size of 38×46 mm, followed by etching. The substrate thus obtained was subjected to ultrasonic cleaning for 15 minutes using “Semico Clean 56” (trade name, manufactured by Furuuchi Chemical Corporation), washed with ultrapure water and then dried. This substrate was subjected to a UV-ozone treatment for 1 hour immediately before the fabrication of the element, and placed in a vacuum vapor deposition apparatus, followed by air exhaustion until the degree of vacuum in the apparatus became 5×10⁻⁴ Pa or less. By the resistance heating method, HAT-CN6 was first vapor-deposited as a hole injection layer in a thickness of 5 nm, and then HT-1 was vapor-deposited as a hole transporting layer in a thickness of 50 nm. Next, as a light emitting layer, H-1 as a host material and a compound D-1 as a dopant material were vapor-deposited in a thickness of 20 nm so that the doping concentration became 1.0% by weight. Further, as an electron transporting layer, ET-1 and 2E-1 used as a donor material were laminated in a thickness of 35 nm so that the vapor deposition rate ratio of ET-1 to 2E-1 became 1:1. After 2E-1 was vapor-deposited as an electron injection layer in a thickness of 0.5 nm, magnesium and silver were co-deposited in a thickness of 1,000 nm to fabricate a 5×5 mm square element.

When this light emitting element was made to emit light at 1,000 cd/m², the emission characteristics were as follows: an emission peak wavelength of 613 nm, a half width of 43 nm and an external quantum efficiency of 6.8%. After continuously energizing with a current at which an initial luminance became 1,000 cd/m², the durability was evaluated by the time during which the luminance decreased to 90% of the initial luminance (hereinafter referred to as LT90). As a result, the LT90 of this light emitting element was 284 hours. HAT-CN6, HT-1, H-1, ET-1 and 2E-1 are compounds shown below.

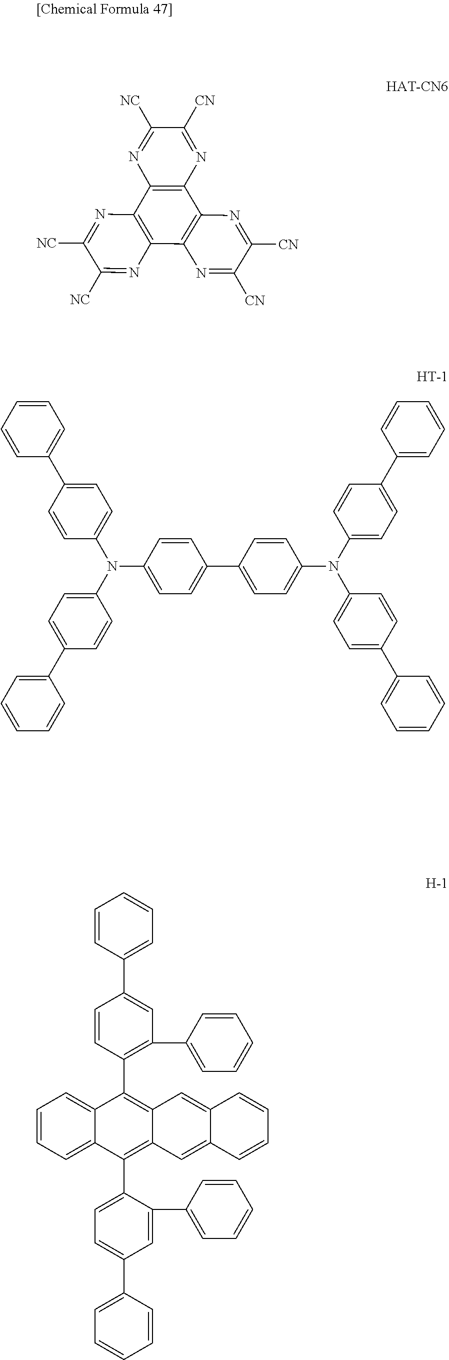

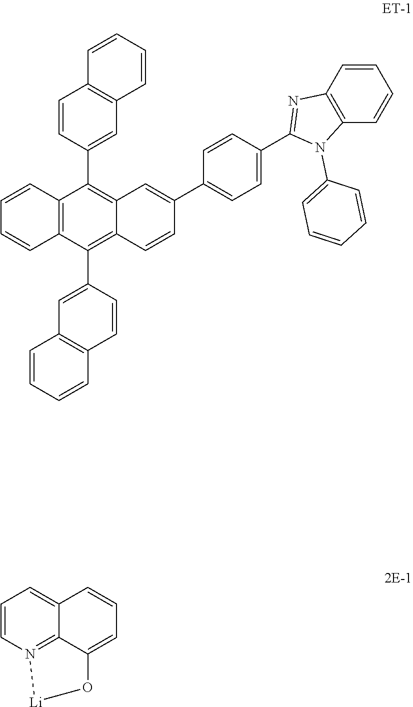

### Examples 22 to 40, Comparative Examples 3 to 4

Light emitting elements were fabricated and evaluated in the same manner as in Example 21, except that each compound shown in Table 3 was used as the dopant material. The results are shown in Table 3.

TABLE 3

| | | Emission peak | | External quantum | |
|---|---|---|---|---|---|
| | | wavelength | Half width | efficiency | LT90 |
| | Compound | (nm) | (nm) | (%) | (hour) |
| Example 21 | D-1 | 613 | 43 | 6.8 | 284 |
| Example 22 | D-2 | 627 | 47 | 6.5 | 273 |
| Example 23 | D-3 | 618 | 44 | 7.1 | 331 |
| Example 24 | D-4 | 631 | 44 | 6.9 | 295 |
| Example 25 | D-5 | 629 | 43 | 7.0 | 315 |
| Example 26 | D-6 | 632 | 45 | 7.0 | 301 |
| Example 27 | D-7 | 620 | 49 | 6.5 | 187 |
| Example 28 | D-8 | 617 | 47 | 7.4 | 194 |
| Example 29 | D-9 | 618 | 45 | 6.5 | 201 |
| Example 30 | D-10 | 619 | 45 | 6.5 | 234 |
| Example 31 | D-11 | 629 | 43 | 7.0 | 234 |
| Example 32 | D-12 | 619 | 48 | 6.6 | 274 |
| Example 33 | D-13 | 631 | 48 | 6.5 | 196 |
| Example 34 | D-14 | 629 | 46 | 6.1 | 221 |
| Example 35 | D-15 | 626 | 49 | 6.0 | 193 |
| Example 36 | D-16 | 619 | 45 | 5.7 | 212 |
| Example 37 | D-17 | 607 | 45 | 7.0 | 195 |
| Example 38 | D-18 | 637 | 51 | 5.6 | 154 |
| Example 39 | D-19 | 654 | 31 | 6.6 | 187 |
| Example 40 | D-20 | 653 | 36 | 6.5 | 206 |
| Comparative Example 3 | D-21 | 617 | 49 | 5.1 | 203 |
| Comparative Example 4 | D-22 | 613 | 45 | 5.1 | 223 |

As is apparent from Table 3, the quantum efficiencies of all the Examples 21 to 40 are higher than those of Comparative Examples 3 to 4.

### Example 41

### (Thermally Activated Delayed Fluorescence Light Emitting Element)

A glass substrate (manufactured by GEOMATEC Co., Ltd., 11 Ω/□, sputtered product) on which an ITO transparent conductive film was deposited in a thickness of 165 nm was cut into a size of 38×46 mm, followed by etching. The substrate thus obtained was subjected to ultrasonic cleaning for 15 minutes using “Semico Clean 56” (trade name, manufactured by Furuuchi Chemical Corporation), washed with ultrapure water and then dried. This substrate was subjected to a UV-ozone treatment for 1 hour immediately before the fabrication of the element, and placed in a vacuum vapor deposition apparatus, followed by air exhaustion until the degree of vacuum in the apparatus became 5×10⁻⁴ Pa or less. By the resistance heating method, HAT-CN6 was first vapor-deposited as a hole injection layer in a thickness of 10 nm, and then HT-1 was vapor-deposited as a hole transporting layer in a thickness of 180 nm. Next, as a light emitting layer, a host material H-2, a compound D-1 and a compound H-3 as a TADF material were vapor-deposited in a thickness of 40 nm so that the weight ratio became 80:1:19. Further, as an electron transporting layer, a compound ET-1 used as an electron transporting material and 2E-1 used as a donor material were laminated in a thickness of 35 nm so that the vapor deposition rate ratio became 1:1. After 2E-1 was vapor-deposited as an electron injection layer in a thickness of 0.5 nm, magnesium and silver were co-deposited in a thickness of 1,000 nm to fabricate a 5×5 mm square element.

When this light emitting element was made to emit light at 1,000 cd/m², the emission characteristics were as follows: an emission peak wavelength of 613 nm, a half width of 43 nm and an external quantum efficiency of 16.4%. The structures of H-2 to H-6 are shown below.

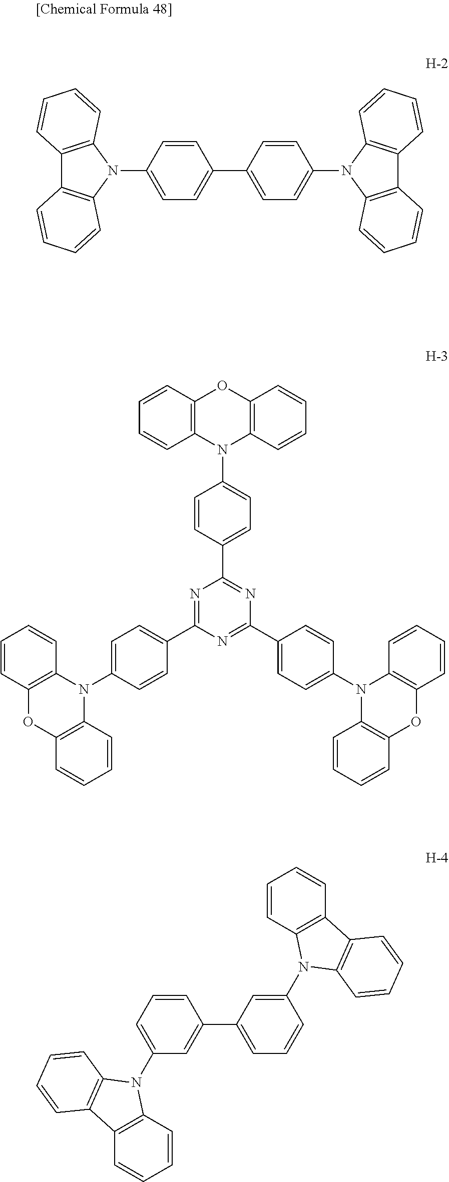 [SMILES: c1ccc2c(c1)c1ccccc1n2-c1ccc(-c2ccc(-n3c4ccccc4c4ccccc43)cc2)cc1 ; c1ccc2c(c1)Oc1ccccc1N2c1ccc(-c2nc(-c3ccc(N4c5ccccc5Oc5ccccc54)cc3)nc(-c3ccc(N4c5ccccc5Oc5ccccc54)cc3)n2)cc1 ; c1cc(-c2cccc(-n3c4ccccc4c4ccccc43)c2)cc(-n2c3ccccc3c3ccccc32)c1]

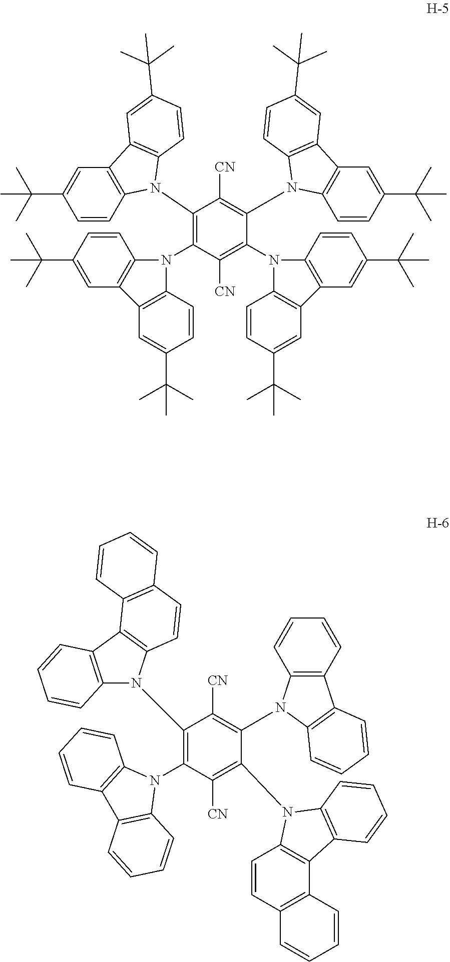 [SMILES: CC(C)(C)c1ccc2c(c1)c1cc(C(C)(C)C)ccc1n2-c1c(C#N)c(-n2c3ccc(C(C)(C)C)cc3c3cc(C(C)(C)C)ccc32)c(-n2c3ccc(C(C)(C)C)cc3c3cc(C(C)(C)C)ccc32)c(C#N)c1-n1c2ccc(C(C)(C)C)cc2c2cc(C(C)(C)C)ccc21 ; N#Cc1c(-n2c3ccccc3c3ccccc32)c(-n2c3ccccc3c3c4ccccc4ccc32)c(C#N)c(-n2c3ccccc3c3ccccc32)c1-n1c2ccccc2c2c3ccccc3ccc21]

### Examples 42 to 47, Comparative Examples 5 to 6

Light emitting elements were fabricated and evaluated in the same manner as in Example 41, except that each compound shown in Table 4 was used the dopant material. The results are shown in Table 4.

### Example 48

A light emitting element was fabricated and evaluated in the same manner as in Example 41, except that a host material H-4, a compound D-4 and a TADF material H-5 were vapor-deposited in a thickness of 40 nm so as that the weight ratio became 74:1:25. The results are shown in Table 4.

### Example 49

A light emitting element was fabricated and evaluated in the same manner as in Example 41, except that a host material H-4, a compound D-4 and a TADF material H-6 were vapor-deposited as the light emitting layer in a thickness of 40 nm so that the weight ratio became 74:1:25. The results are shown in Table 4.

TABLE 4

| | | Emission peak | | External quantum | |
|---|---|---|---|---|---|
| | | wavelength | Half width | efficiency | LT90 |
| | Compound | (nm) | (nm) | (%) | (hour) |
| Example 41 | D-1 | 613 | 43 | 16.4 | 209 |
| Example 42 | D-2 | 626 | 46 | 15.8 | 198 |
| Example 43 | D-4 | 631 | 44 | 16.6 | 215 |
| Example 44 | D-5 | 628 | 43 | 16.7 | 240 |
| Example 45 | D-8 | 617 | 47 | 16.9 | 141 |
| Example 46 | D-12 | 619 | 47 | 15.8 | 202 |
| Example 47 | D-20 | 653 | 35 | 15.1 | 155 |
| Example 48 | D-4 | 631 | 44 | 17.4 | 246 |
| Example 49 | D-4 | 631 | 44 | 18.0 | 238 |
| Comparative Example 5 | D-21 | 617 | 48 | 12.9 | 143 |
| Comparative Example 6 | D-22 | 613 | 45 | 13.0 | 161 |

As is apparent with reference to Table 4, since the TADF material was used for the light emitting layer in Examples 41 to 49 and Comparative Examples 5 to 6, the external quantum efficiency was improved significantly as compared with Examples 21 to 40 and Comparative Examples 3 to 4. Of these, highly efficient emission could be obtained in all the Examples 41 to 49 as compared with Comparative Examples 5 to 6.

### Example 50

(Evaluation of TADF Bottom-Emission Type Light Emitting Element using Two Types of Host Materials)

A glass substrate (manufactured by GEOMATEC Co., Ltd., 11 Ω/□, sputtered product) on which an ITO transparent conductive film was deposited in a thickness of 165 nm was cut into a size of 38×46 mm, followed by etching. The substrate thus obtained was subjected to ultrasonic cleaning for 15 minutes using “Semico Clean 56” (trade name, manufactured by Furuuchi Chemical Corporation), washed with ultrapure water and then dried. This substrate was subjected to a UV-ozone treatment for 1 hour immediately before the fabrication of the element, and placed in a vacuum vapor deposition apparatus, followed by air exhaustion until the degree of vacuum in the apparatus became 5×10⁻⁴ Pa or less. By the resistance heating method, HAT-CN6 was first vapor-deposited as a hole injection layer in a thickness of 10 nm, and then HT-1 was vapor-deposited as a hole transporting layer in a thickness of 180 nm. Next, as a light emitting layer, a first host material H-2 (hole transporting third compound), a second host material H-7 (electron transporting third compound), a compound D-1 (second compound) and a compound H-3 (first compound) as a TADF material were vapor-deposited in a thickness of 40 nm so that the weight ratio became 40:40:1:19. Further, as an electron transporting layer, a compound ET-1 used as an electron transporting material and 2E-1 used as a donor material were laminated in a thickness of 35 nm so that the vapor deposition rate ratio of the compound ET-1 to the compound 2E-1 became 1:1. After 2E-1 was vapor-deposited as an electron injection layer in a thickness of 0.5 nm, magnesium and silver were co-deposited in a thickness of 1,000 nm to fabricate a 5×5 mm square bottom-emission type light emitting element.

When this light emitting element was made to emit light at 1,000 cd/m², the emission characteristics were as follows: an emission peak wavelength of 613 nm, a half width of 43 nm an external quantum efficiency of 16.5% and LT90 of 312 hours. It was confirmed that, as compared with Example 41 using one type of a host material, the emission peak wavelength, half width and external quantum efficiency are the same, LT90 becomes about 1.5 times larger, and the durability is improved. H-7 is a compound shown below.

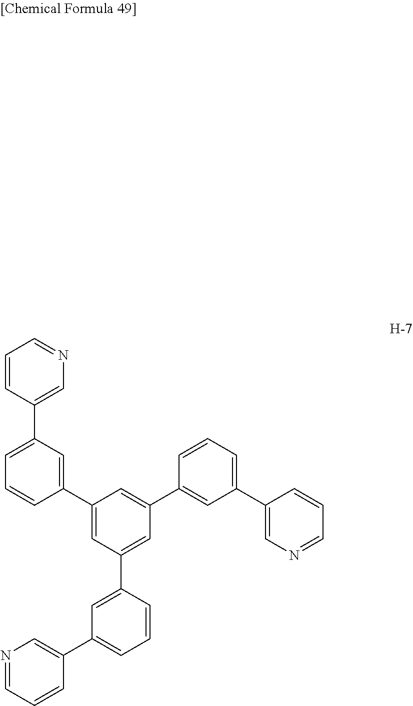 [SMILES: c1cncc(-c2cccc(-c3cc(-c4cccc(-c5cccnc5)c4)cc(-c4cccc(-c5cccnc5)c4)c3)c2)c1]

The lowest excited singlet energy level of H-2 and H-7: S₁, and the lowest excited triplet energy level: T₁ are as follows.

S₁(H-2): 3.4 eV

T₁(H-2): 2.6 eV

S₁ (H-7): 3.9 eV

T₁(H-7): 2.8 eV

### Example 51

### (Evaluation of Tandem Type Fluorescent Light Emitting Element)

A glass substrate (manufactured by GEOMATEC Co., Ltd., 11 Ω/□, sputtered product) on which an ITO transparent conductive film was deposited in a thickness of 165 nm was cut into a size of 38×46 mm, followed by etching. The substrate thus obtained was subjected to ultrasonic cleaning for 15 minutes using “Semico Clean 56” (trade name, manufactured by Furuuchi Chemical Corporation), washed with ultrapure water and then dried. This substrate was subjected to a UV-ozone treatment for 1 hour immediately before the fabrication of the element, and placed in a vacuum vapor deposition apparatus, followed by air exhaustion until the degree of vacuum in the apparatus became 5×10⁻⁴ Pa or less. By the resistance heating method, HAT-CN6 was first vapor-deposited as a hole injection layer in a thickness of 5 nm, and then HT-1 was vapor-deposited as a hole transporting layer in a thickness of 50 nm. Next, as a light emitting layer, H-1 (first compound) as a host material and a compound D-1 (second compound) as a dopant material were vapor-deposited in a thickness of 20 nm so that the doping concentration became 1.0% by weight. Further, as an electron transporting layer, a compound ET-1 used as an electron transporting material and 2E-1 used as a donor material were laminated in a thickness of 35 nm so that the vapor deposition rate ratio of compound ET-1 to the compound 2E-1 became 1:1. Subsequently, as an n-type charge generation layer, a compound ET-2 used as an n-type host and metallic lithium used as an n-type dopant were laminated in a thickness of 10 nm so that the vapor deposition rate ratio of the compound ET-2 to the metallic lithium became 99:1. Further, HAT-CN6 was laminated as a p-type charge light emitting layer in a thickness of 10 nm. In the same manner as mentioned above, a thin film having a thickness of 50 nm of HT-1 as a hole transporting layer, a thin film having a thickness of 20 nm obtained by doping a host material H-1 with 1.0% by weight of a compound D-1 as a light emitting layer, and a thin film having a thickness of 35 nm as an electron transporting layer so that the ratio of ET-1 to 2E-1 became 1:1 were vapor-deposited thereon in order. After 2E-1 was vapor-deposited as an electron injection layer in a thickness of 0.5 nm, magnesium and silver were co-deposited in a thickness of 1,000 nm to fabricate a 5×5 mm square element.

When this light emitting element was made to emit light at 1,000 cd/m², the emission characteristics were as follows: an emission peak wavelength of 613 nm, a half width of 43 nm an external quantum efficiency of 13.4% and LT90 of 561 hours. It was confirmed that, as compared with Example 21 having only one light emitting layer, both the external quantum efficiency and LT90 became about twice larger, and the luminance efficiency and durability are improved. ET-2 is a compound shown below.

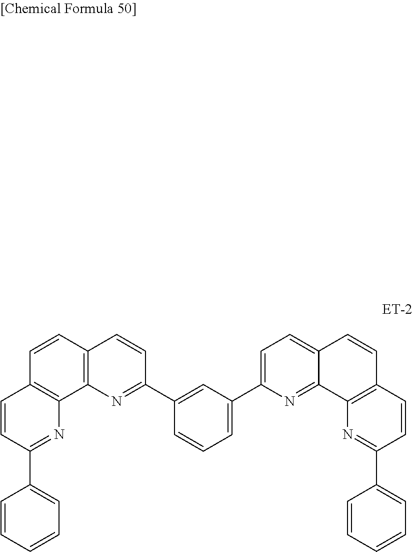 [SMILES: c1ccc(-c2ccc3ccc4ccc(-c5cccc(-c6ccc7ccc8ccc(-c9ccccc9)nc8c7n6)c5)nc4c3n2)cc1]

As mentioned above, it was shown that a light emitting element having high external quantum efficiency can be fabricated by the present invention. As a result, it was shown that the luminance efficiency can be enhanced in the production of display devices such as displays and illumination devices.

1. A light emitting element material comprising a pyrromethene boron complex represented by the following general formula (1): 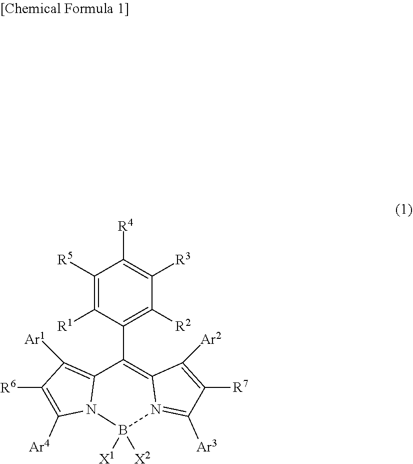
wherein X¹ and X² each may be the same or different, and are selected from the group consisting of an alkyl group, a cycloalkyl group, a heterocyclic group, an alkenyl group, a cycloalkenyl group, an alkynyl group, a hydroxyl group, a thiol group, an alkoxy group, a cycloalkoxy group, an alkylthio group, an aryl ether group, an aryl thioether group, an aryl group, a heteroaryl group, halogen and a cyano group, and these functional groups may further have a substituent;
Ar¹ to Ar⁴ each may be the same or different, and are a substituted or unsubstituted aryl group, or a substituted or unsubstituted heteroaryl group; the aryl group and the heteroaryl group may be either a monocyclic ring or a fused ring; in which, when one or both of Ar¹ and Ar² is/are monocyclic ring(s), the monocyclic ring has one or more secondary alkyl groups, one or more tertiary alkyl groups, one or more aryl groups, or one or more heteroaryl groups as substituents, or has a methyl group and a primary alkyl group as two or more substituents in total;
R¹ and R² each may be the same or different, and are a substituted or unsubstituted alkyl group, a substituted or unsubstituted aryl group, or a substituted or unsubstituted heteroaryl group;
R³ to R⁵ each may be the same or different, and are selected from the group consisting of a hydrogen atom, an alkyl group, a cycloalkyl group, a heterocyclic group, an alkenyl group, a cycloalkenyl group, an alkynyl group, an aryl group, a heteroaryl group, a hydroxyl group, a thiol group, an alkoxy group, an alkylthio group, an aryl ether group, an aryl thioether group, halogen, a cyano group, an aldehyde group, an acyl group, a carboxyl group, an ester group, an amide group, a sulfonyl group, a sulfonic acid ester group, a sulfonamide group, an amino group, a nitro group, a silyl group, and a ring structure with an adjacent group; and these functional groups may further have a substituent; and
R⁶ and R⁷ each may be the same or different, and are selected from the group consisting of a hydrogen atom, an alkyl group, a cycloalkyl group, a heterocyclic group, an alkenyl group, a cycloalkenyl group, an alkynyl group, an aryl group, a heteroaryl group, a hydroxyl group, a thiol group, an alkoxy group, an alkylthio group, an aryl ether group, an aryl thioether group, halogen, a cyano group, an aldehyde group, an acyl group, a carboxyl group, an ester group, an amide group, a sulfonyl group, a sulfonic acid ester group, a sulfonamide group, an amino group, a nitro group and a silyl group; in which R⁶ may be a bridging structure formed by covalent bond via one or two atoms with Ar⁴, and R⁷ may be a bridging structure formed by covalent bond via one or two atoms with Ar³; and these functional groups may further have a substituent.

2. The light emitting element material according to claim 1, wherein at least one of R⁶ and R⁷ is a hydrogen atom, or a substituted or unsubstituted alkyl group.

3. The light emitting element material according to claim 1, wherein the pyrromethene boron complex represented by the general formula (1) is a pyrromethene boron complex represented by any one of the general formulas (3) to (5): 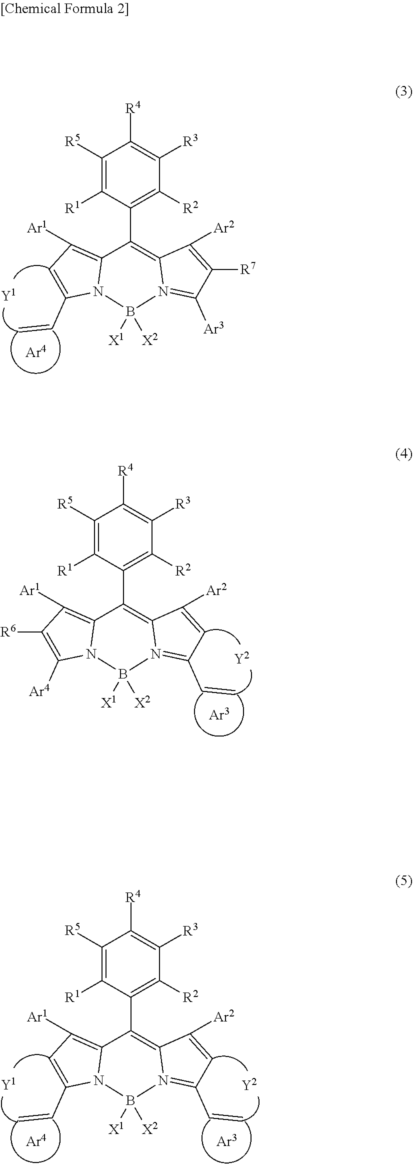
wherein X¹ and X², Ar¹ to A⁴ and R¹ to R⁷ are the same as those in the general formula (1); Y¹ and Y² are a bridging structure composed of one atom or two atoms arranged in series, and the atom is selected from the group consisting of a substituted or unsubstituted carbon atom, a substituted or unsubstituted silicon atom, a substituted or unsubstituted nitrogen atom, a substituted or unsubstituted phosphorus atom, an oxygen atom and a sulfur atom; and the bridging structure is composed of two atoms arranged in series, two atoms may be connected by a double bond.

4. The light emitting element material according to claim 1, wherein Ar¹ and Ar² are selected from the group consisting of a phenyl group having one or more tertiary alkyl groups as substituents, a phenyl group having one or more aryl groups as substituents, a phenyl group having one or more heteroaryl groups as substituents, a phenyl group having a methyl group and a primary alkyl group as two or more substituents in total, at least one of which is substituted at the 2-position with respect to a bonding site to a pyrrole ring, and a fused-ring aromatic hydrocarbon group.

5. The light emitting element material according to claim 1, wherein R¹ and R² are a substituted or unsubstituted alkyl group.

6. The light emitting element material according to claim 1, wherein at least one of R¹ and R² is a substituted or unsubstituted aryl group, or a substituted or unsubstituted heteroaryl group.

7. The light emitting element material according to claim 1, wherein X¹ and X² are a fluorine atom.

8. A light emitting element comprising an anode, a cathode and a light emitting layer existing between the anode and the cathode, wherein the light emitting layer emits light by electric energy, and the light emitting layer contains the light emitting element material according to claim 1.

9. The light emitting element wherein the light emitting layer contains a first compound selected from a host material and a thermally activated delayed fluorescent material, and a second compound which is a dopant, and the second compound is the light emitting element material according to claim 1.

10. The light emitting element according to claim 8, wherein the first compound is a thermally activated delayed fluorescent material.

11. The light emitting element according to claim 10, wherein the light emitting layer further contains a third compound, and lowest singlet excitation energy of the third compound is larger than that of the first compound.

12. The light emitting element according to claim 11, wherein the third compound is composed of two or more types of materials.

13. The light emitting element material according to claim 8, which has at least two light emitting layers between the anode and the cathode, and has at least one charge generation layer between two or more light emitting layers wherein the charge generation layer contains a phenanthroline derivative represented by the general formula (30); 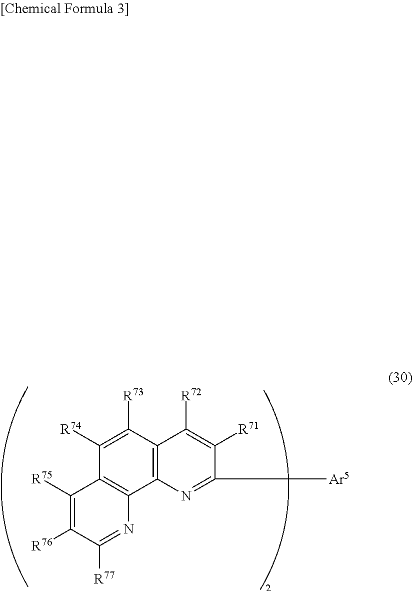
wherein Ar⁵ is an aryl group substituted with two phenanthrolyl groups; and
R⁷¹ to R⁷⁷ each may be the same or different, and are selected from among a hydrogen atom, an alkyl group, a cycloalkyl group, a heterocyclic group, an aryl group and a heteroaryl group.

14. (canceled)

15. The light emitting element material according to claim 8, wherein the light emitting element is a top-emission type electroluminescence element.

16. (canceled)

17. (canceled)

18. The light emitting element material according to claim 2, wherein Ar¹ and Ar² are selected from the group consisting of a phenyl group having one or more tertiary alkyl groups as substituents, a phenyl group having one or more aryl groups as substituents, a phenyl group having one or more heteroaryl groups as substituents, a phenyl group having a methyl group and a primary alkyl group as two or more substituents in total, at least one of which is substituted at the 2-position with respect to a bonding site to a pyrrole ring, and a fused-ring aromatic hydrocarbon group.

19. The light emitting element material according to claim 3, wherein Ar¹ and Ar² are selected from the group consisting of a phenyl group having one or more tertiary alkyl groups as substituents, a phenyl group having one or more aryl groups as substituents, a phenyl group having one or more heteroaryl groups as substituents, a phenyl group having a methyl group and a primary alkyl group as two or more substituents in total, at least one of which is substituted at the 2-position with respect to a bonding site to a pyrrole ring, and a fused-ring aromatic hydrocarbon group.
